(19) United States
(12) Patent Application Publication
(10) Pub. No.: US 2020/0227561 A1
(43) Pub. Date: Jul. 16, 2020

(54) SEMICONDUCTOR DEVICE AND METHOD FOR MANUFACTURING THE SAME

(71) Applicant: Semiconductor Energy Laboratory Co., Ltd., Atsugi-shi, Kanagawa-ken (JP)

(72) Inventor: Shunpei YAMAZAKI, Setagaya (JP)

(21) Appl. No.: 16/606,910

(22) PCT Filed: May 1, 2018
(86) PCT No.: PCT/IB2018/053004

§ 371 Date: Oct. 21, 2019

(30) Foreign Application Priority Data
May 12, 2017 (JP) 2017-096084

(51) Int. Cl. H01L 29/786; H01L 29/66; H01L 29/24

(52) U.S. Cl. CPC H01L 29/7869; H01L 29/24; H01L 29/66969; H01L 29/78648

(57) ABSTRACT

A semiconductor device having favorable electrical characteristics is provided. One embodiment of the present invention is a semiconductor device including a transistor. The transistor includes an oxide, a first insulator over the oxide, a conductor over the first insulator, and a second insulator on the side surface of the first insulator and the side surface of the conductor. The oxide includes a first region, a second region, and a third region between the first region and the second region. The first insulator is over the first region. The third region includes a region overlapping with the second insulator. Oxygen concentration of the second region is lower than oxygen concentration of the first region and oxygen concentration of the third region. The third region includes a region having oxygen concentration between the oxygen concentration of the first region and the oxygen concentration of the second region.

### TECHNICAL FIELD

One embodiment of the present invention relates to a semiconductor device and a manufacturing method thereof. Another embodiment of the present invention relates to a semiconductor wafer, a module, and an electronic device.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

Note that one embodiment of the present invention is not limited to the above technical field. One embodiment of the invention disclosed in this specification and the like relates to an object, a method, or a manufacturing method. Furthermore, one embodiment of the present invention relates to a process, a machine, manufacture, or a composition of matter.

### BACKGROUND ART

In recent years, semiconductor devices have been developed to be used mainly for an LSI, a CPU, or a memory. A CPU is an aggregation of semiconductor elements each provided with an electrode which is a connection terminal, which includes a semiconductor integrated circuit (including at least a transistor and a memory) separated from a semiconductor wafer.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). A silicon-based semiconductor material is widely known as a material for a semiconductor thin film applicable to the transistor; in addition, an oxide semiconductor has attracted attention as another material.

It is known that a transistor including an oxide semiconductor has an extremely low leakage current in an off state. For example, a low-power-consumption CPU utilizing a characteristic of a low leakage current of the transistor including an oxide semiconductor has been disclosed (see Patent Document 1).

A self-aligned transistor has been proposed as the transistor including an oxide semiconductor. A method for manufacturing the self-aligned transistor in which a metal film is formed over source and drain regions and heat treatment is performed on the metal film so that the resistance of the metal film is increased and the resistance of the source and drain regions is reduced is disclosed (see Patent Document 2).

A method for manufacturing the transistor including an oxide semiconductor in which a metal film is formed over source and drain regions, heat treatment is performed on the metal film, and a dopant is introduced through the metal film so that the resistance of the source and drain regions is reduced is disclosed (see Patent Document 3).

In recent years, demand for an integrated circuit in which transistors and the like are integrated with high density has risen with reductions in the size and weight of an electronic device. In addition, the productivity of a semiconductor device including an integrated circuit is required to be improved.

### REFERENCE

### Patent Document

[Patent Document 1] Japanese Published Patent Application No. 2012-257187 [Patent Document 2] Japanese Published Patent Application No. 2011-228622

[Patent Document 3] Japanese Published Patent Application No. 2013-016782

### DISCLOSURE OF INVENTION

In Patent Document 2, to reduce the resistance of the source and drain regions, the metal film is formed over the source and drain regions and heat treatment is performed on the metal film in an oxygen atmosphere. By the heat treatment, a constituent element of the metal film enters the source and drain regions of an oxide semiconductor film as a dopant, whereby the resistance of the source and drain regions is reduced. The heat treatment in an oxygen atmosphere causes oxidization of a conductive film, whereby the resistance of the conductive film is increased. However, since the heat treatment is performed in an oxygen atmosphere, oxygen is less likely to be extracted from the oxide semiconductor film by the metal film.

Patent Document 2 discloses the oxygen concentration in a channel formation region, and does not refer to the concentration of impurities such as water or hydrogen. That is, purification of the channel formation region (reduction in impurities such as water or hydrogen, typically, dehydration or dehydrogenation) is not performed; thus, a transistor tends to have normally-on characteristics. Note that “normally-on characteristics of a transistor” means a state where a channel exists and current flows through a transistor even when no voltage is applied to a gate. In contrast, “normally-off characteristics of a transistor” means a state where current does not flow through a transistor without application of voltage to a gate.

In view of the above problems, an object of one embodiment of the present invention is to provide a semiconductor device having favorable electrical characteristics by stably reducing the resistance of source and drain regions of a transistor and purifying a channel formation region.

Another object of one embodiment of the present invention is to provide a semiconductor device that can be miniaturized or highly integrated. Another object of one embodiment of the present invention is to provide a semiconductor device having favorable electrical characteristics. Another object of one embodiment of the present invention is to provide a semiconductor device that can be manufactured with high productivity.

Another object of one embodiment of the present invention is to provide a semiconductor device capable of retaining data for a long time. Another object of one embodiment of the present invention is to provide a semiconductor device capable of high-speed data writing. Another object of one embodiment of the present invention is to provide a semiconductor device with high design flexibility. Another object of one embodiment of the present invention is to provide a low-power semiconductor device. Another object of one embodiment of the present invention is to provide a novel semiconductor device.

Note that the descriptions of these objects do not disturb the existence of other objects. In one embodiment of the present invention, there is no need to achieve all the objects listed above. Other objects will be apparent from and can be derived from the description of the specification, the drawings, the claims, and the like.

One embodiment of the present invention is a semiconductor device including a transistor. The transistor includes an oxide, a first insulator over the oxide, a conductor over the first insulator, and a second insulator on the side surface of the first insulator and the side surface of the conductor. The oxide includes a first region, a second region, and a third region between the first region and the second region. The first insulator is over the first region. The third region includes a region overlapping with the second insulator. Oxygen concentration of the second region is lower than oxygen concentration of the first region and oxygen concentration of the third region. The third region includes a region having oxygen concentration between the oxygen concentration of the first region and the oxygen concentration of the second region.

One embodiment of the present invention is a semiconductor device including a transistor. The transistor includes an oxide, a first insulator and a first film over the oxide, a conductor over the first insulator, and a second insulator on the side surface of the first insulator and the side surface of the conductor. The oxide includes a first region, a second region, and a third region between the first region and the second region. The first film is in contact with the second region. The first insulator is over the first region. The third region includes a region overlapping with the second insulator. Oxygen concentration of the second region is lower than oxygen concentration of the first region and oxygen concentration of the third region. The third region includes a region having oxygen concentration between the oxygen concentration of the first region and the oxygen concentration of the second region.

In the above embodiment, the metal oxide preferably contains In, an element M (M is Al, Ga, Y, or Sn), and Zn.

In the above embodiment, an atomic proportion of the In is preferably higher than an atomic proportion of the element M.

In the above embodiment, the second region preferably contains at least one of aluminum, ruthenium, titanium, tantalum, chromium, and tungsten.

In the above embodiment, the second region preferably contains nitrogen.

In the above embodiment, hydrogen concentration of the first region is preferably lower than hydrogen concentration of the second region.

In the above embodiment, hydrogen concentration of the first region is preferably lower than hydrogen concentration of the second region and the third region.

In the above embodiment, the transistor is preferably a normally-off transistor.

In the above embodiment, the first film is preferably partly mixed with the second region.

In the above embodiment, the first film preferably contains at least one of aluminum, ruthenium, titanium, tantalum, chromium, and tungsten.

In the above embodiment, the first film preferably further contains nitrogen.

In the above embodiment, the thickness of the first film is preferably greater than or equal to 0.5 nm and less than 5 nm.

One embodiment of the present invention is a manufacturing method of a semiconductor device including a transistor that includes an oxide having a first region, a second region, and a third region between the first region and the second region, a first insulator over the oxide, a conductor over the first insulator, and a second insulator on the side surface of the first insulator and the side surface of the conductor. A first film containing a metal is formed to cover the oxide, the first insulator, the conductor, and the second insulator and to be in contact with the second region. First heat treatment is performed on the oxide and the first film in an atmosphere containing nitrogen to make oxygen in the second region extracted by the first film.

In the above embodiment, the first film is preferably formed by a sputtering method using one or both of an argon gas and a nitrogen gas.

In the above embodiment, the first film may be removed after the first heat treatment.

In the above embodiment, second heat treatment may be performed after the first heat treatment.

In the above embodiment, a second film covering at least the oxide, the first insulator, the conductor, and the second insulator may be formed after the first heat treatment.

One embodiment of the present invention can provide a semiconductor device having favorable electrical characteristics. Another embodiment of the present invention can provide a semiconductor device that can be miniaturized or highly integrated. Another embodiment of the present invention can provide a semiconductor device that can be manufactured with high productivity.

Another embodiment of the present invention can provide a semiconductor device capable of retaining data for a long time. Another embodiment of the present invention can provide a semiconductor device capable of high-speed data writing. Another embodiment of the present invention can provide a semiconductor device with high design flexibility. Another embodiment of the present invention can provide a low-power semiconductor device. Another embodiment of the present invention can provide A novel semiconductor device.

Note that the descriptions of these effects do not preclude the existence of other effects. One embodiment of the present invention does not have to have all the effects listed above. Other effects will be apparent from and can be derived from the description of the specification, the drawings, the claims, and the like.

### BRIEF DESCRIPTION OF DRAWINGS

In the accompanying drawings:

FIGS. 1A to 1D are a top view and cross-sectional views of a semiconductor device of one embodiment of the present invention;

FIGS. 2A and 2B are cross-sectional views of a semiconductor device of one embodiment of the present invention;

FIGS. 3A to 3D are a top view and cross-sectional views illustrating a method for manufacturing a semiconductor device of one embodiment of the present invention;

FIGS. 4A to 4D are a top view and cross-sectional views illustrating a method for manufacturing a semiconductor device of one embodiment of the present invention;

FIGS. 5A to 5D are a top view and cross-sectional views illustrating a method for manufacturing a semiconductor device of one embodiment of the present invention;

FIGS. 6A to 6D are a top view and cross-sectional views illustrating a method for manufacturing a semiconductor device of one embodiment of the present invention;

FIGS. 7A to 7D are a top view and cross-sectional views illustrating a method for manufacturing a semiconductor device of one embodiment of the present invention;

FIGS. 8A to 8D are a top view and cross-sectional views illustrating a method for manufacturing a semiconductor device of one embodiment of the present invention;

FIGS. 9A to 9D are a top view and cross-sectional views illustrating a method for manufacturing a semiconductor device of one embodiment of the present invention;

FIGS. 10A to 10D are a top view and cross-sectional views illustrating a method for manufacturing a semiconductor device of one embodiment of the present invention;

FIGS. 11A to 11D are a top view and cross-sectional views illustrating a method for manufacturing a semiconductor device of one embodiment of the present invention;

FIGS. 12A to 12D are a top view and cross-sectional views illustrating a method for manufacturing a semiconductor device of one embodiment of the present invention;

FIGS. 13A to 13D are a top view and cross-sectional views illustrating a method for manufacturing a semiconductor device of one embodiment of the present invention;

FIGS. 14A to 14D are a top view and cross-sectional views illustrating a method for manufacturing a semiconductor device of one embodiment of the present invention;

FIGS. 15A to 15D are a top view and cross-sectional views of a semiconductor device of one embodiment of the present invention;

FIG. 16 is a schematic view showing different areas in an InGaZnO₄ crystal;

FIGS. 17A to 17D show transfer paths of a hydrogen atom in a region between an InO₂ plane and a (Ga, Zn)O plane, and activation barriers along the paths;

FIGS. 18A and 18B show a transfer path of a hydrogen atom in a (Ga, Zn)O region and an activation barrier along the path;

FIGS. 19A and 19B show a transfer path of a hydrogen atom in a region between an InO₂ layer and a (Ga, Zn)O layer, and activation barriers along the path;

FIGS. 20A and 20B show a transfer path of a hydrogen atom in the c-axis direction and activation barriers along the path;

FIG. 21 shows a model of calculation;

FIG. 22 shows relative values of total energies in an oxygen vacancy model;

FIGS. 23A and 23B show models in the initial state and the final state;

FIG. 24 shows an activation barrier;

FIGS. 25A to 25C are a top view and cross-sectional views of a semiconductor device of one embodiment of the present invention;

FIGS. 26A and 26B are a circuit diagram and a cross-sectional view of a semiconductor device of one embodiment of the present invention;

FIGS. 27A and 27B are a circuit diagram and a cross-sectional view of a semiconductor device of one embodiment of the present invention;

FIG. 28 is a cross-sectional view illustrating a structure of a memory device of one embodiment of the present invention;

FIG. 29 is a cross-sectional view illustrating a structure of a memory device of one embodiment of the present invention;

FIG. 30 is a cross-sectional view illustrating a structure of a memory device of one embodiment of the present invention;

FIG. 31 is a cross-sectional view illustrating a structure of a memory device of one embodiment of the present invention;

FIGS. 32A and 32B are a circuit diagram and a cross-sectional view of a memory device of one embodiment of the present invention;

FIG. 33 is a cross-sectional view illustrating a structure of a memory device of one embodiment of the present invention;

FIG. 34 is a cross-sectional view illustrating a structure of a memory device of one embodiment of the present invention;

FIG. 35 is a block diagram showing a configuration example of a memory device of one embodiment of the present invention;

FIGS. 36A to 36E are circuit diagrams illustrating a configuration example of a memory device of one embodiment of the present invention;

FIG. 37 is a circuit diagram illustrating a configuration example of a memory device of one embodiment of the present invention;

FIG. 38 is a block diagram illustrating a configuration example of a memory device of one embodiment of the present invention;

FIGS. 39A and 39B are a block diagram and a circuit diagram showing a configuration example of a memory device of one embodiment of the present invention;

FIGS. 40A to 40C are block diagrams illustrating a configuration example of a semiconductor device of one embodiment of the present invention;

FIGS. 41A and 41B are a block diagram and a circuit diagram showing a configuration example of a semiconductor device of one embodiment of the present invention, and FIG. 41C is a timing chart showing an operation example of the semiconductor device;

FIG. 42 is a block diagram illustrating a configuration example of a semiconductor device of one embodiment of the present invention;

FIGS. 43A and 43B are a circuit diagram showing a configuration example of a semiconductor device of one embodiment of the present invention and a timing chart showing an operation example of the semiconductor device;

FIG. 44 is a block diagram illustrating a structure example of an AI system of one embodiment of the present invention;

FIGS. 45A and 45B are block diagrams each illustrating an application example of an AI system of one embodiment of the present invention;

FIG. 46 is a schematic perspective view illustrating a structure example of an IC including an AI system of one embodiment of the present invention;

FIGS. 47A to 47D each illustrate an electronic device of one embodiment of the present invention;

FIGS. 48A and 48B each illustrate an electronic device of one embodiment of the present invention;

FIG. 49 illustrates an electronic device of one embodiment of the present invention;

FIGS. 50A and 50B show cross-sectional STEM images of samples in an example; and

FIG. 51 shows sheet resistance of each sample in an example.

### BEST MODE FOR CARRYING OUT THE INVENTION

Hereinafter, embodiments will be described with reference to drawings. Note that the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings, and explanation thereof will not be repeated in some cases. Furthermore, the same hatching pattern is applied to portions having similar functions, and the portions are not especially denoted by reference numerals in some cases.

Especially in a top view (also referred to as a “plan view”), a perspective view, or the like, some components might not be illustrated for easy understanding of the invention. In addition, some hidden lines and the like might not be shown.

Note that the ordinal numbers such as “first”, “second”, and the like in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

In this specification, terms for describing arrangement, such as “over”, “above”, “under”, and “below”, are used for convenience in describing a positional relation between components with reference to drawings. Furthermore, the positional relationship between components is changed as appropriate in accordance with the direction in which each component is described. Thus, there is no limitation on terms used in this specification, and description can be made appropriately depending on the situation.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y positioned therebetween.

For example, in the case where X and Y are electrically connected, one or more elements that allow an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that allow a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. The transistor has a region where a channel is formed between the drain (a drain terminal, a drain region, or a drain electrode) and the source (a source terminal, a source region, or a source electrode), and current can flow between the source and the drain through the region where a channel is formed. Note that in this specification and the like, a region where a channel is formed refers to a region through which current mainly flows.

Furthermore, functions of a source and a drain might be switched when a transistor of opposite polarity is employed or the direction of current flow is changed in circuit operation, for example. Therefore, the terms “source” and “drain” can be switched in some cases in this specification and the like.

Note that the channel length refers to, for example, the distance between a source (a source region or a source electrode) and a drain (a drain region or a drain electrode) in a region where a semiconductor (or a portion where current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

The channel width refers to, for example, the length of a portion where a source and a drain face each other in a region where a semiconductor (or a portion where current flows in a semiconductor when a transistor is on) and a gate electrode overlap with each other, or a region where a channel is formed. In one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter referred to as an “effective channel width”) is different from a channel width shown in a top view of a transistor (hereinafter referred to as an “apparent channel width”) in some cases. For example, in a transistor having a gate electrode covering the side surface of a semiconductor, an effective channel width is greater than an apparent channel width, and its influence cannot be ignored in some cases. For example, in a miniaturized transistor having a gate electrode covering the side surface of a semiconductor, the proportion of a channel formation region formed in the side surface of a semiconductor is increased. In that case, an effective channel width is greater than an apparent channel width.

In such a case, an effective channel width is difficult to measure in some cases. For example, to estimate an effective channel width from a design value, it is necessary to assume that the shape of a semiconductor is known as an assumption condition. Accordingly, in the case where the shape of a semiconductor is not known accurately, it is difficult to measure an effective channel width accurately.

Thus, in this specification, an apparent channel width is referred to as a surrounded channel width (SCW) in some cases. Furthermore, in this specification, in the case where the term “channel width” is simply used, it may represent a surrounded channel width or an apparent channel width. Alternatively, in this specification, in the case where the term “channel width” is simply used, it may represent an effective channel width. Note that a channel length, a channel width, an effective channel width, an apparent channel width, a surrounded channel width, and the like can be determined by analyzing a cross-sectional TEM image and the like.

Note that an impurity in a semiconductor refers to, for example, elements other than the main components of a semiconductor. For example, an element with a concentration lower than 0.1 atomic % can be regarded as an impurity. When an impurity is contained, the density of states (DOS) in a semiconductor may be increased, or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; there are hydrogen, lithium, sodium, silicon, boron, phosphorus, carbon, and nitrogen, for example. For an oxide semiconductor, water also serves as an impurity in some cases. For an oxide semiconductor, entry of impurities may lead to formation of oxygen vacancies, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

In this specification and the like, a silicon oxynitride film contains more oxygen than nitrogen. A silicon oxynitride film preferably contains, for example, oxygen, nitrogen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively. A silicon nitride oxide film contains more nitrogen than oxygen. A silicon nitride oxide film preferably contains nitrogen, oxygen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively.

In this specification and the like, the terms “film” and “layer” can be interchanged with each other. For example, the term “conductive layer” can be changed into the term “conductive film” in some cases. Also, the term “insulating film” can be changed into the term “insulating layer” in some cases.

In addition, in this specification and the like, the term “insulator” can be replaced with the term “insulating film” or “insulating layer”. Moreover, the term “conductor” can be replaced with the term “conductive film” or “conductive layer”. Furthermore, the term “semiconductor” can be replaced with the term “semiconductor film” or “semiconductor layer”.

Furthermore, unless otherwise specified, transistors described in this specification and the like are field effect transistors. Unless otherwise specified, transistors described in this specification and the like are n-channel transistors. Thus, unless otherwise specified, the threshold voltage (also referred to as “Vₜₕ”) is higher than 0 V.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly also includes the case where the angle is greater than or equal to 85° and less than or equal to 95°. In addition, the term “substantially perpendicular” indicates that the angle formed between two straight lines is greater than or equal to 60° and less than or equal to 120°.

In this specification, trigonal and rhombohedral crystal systems are included in a hexagonal crystal system.

Note that in this specification, a barrier film refers to a film having a function of inhibiting the penetration of oxygen and impurities such as hydrogen. The barrier film that has conductivity may be referred to as a conductive barrier film.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. In other words, an OS FET is a transistor including an oxide or an oxide semiconductor.

In this specification and the like, the term “normally off” means that current per micrometer of channel width flowing in a transistor when voltage is not applied to a gate or the gate is supplied with the potential GND is 1×10⁻²⁰ A or lower at room temperature, 1×10⁻¹⁸ A or lower at 85° C., or 1×10⁻¹⁶ A or lower at 125° C.

### Embodiment 1

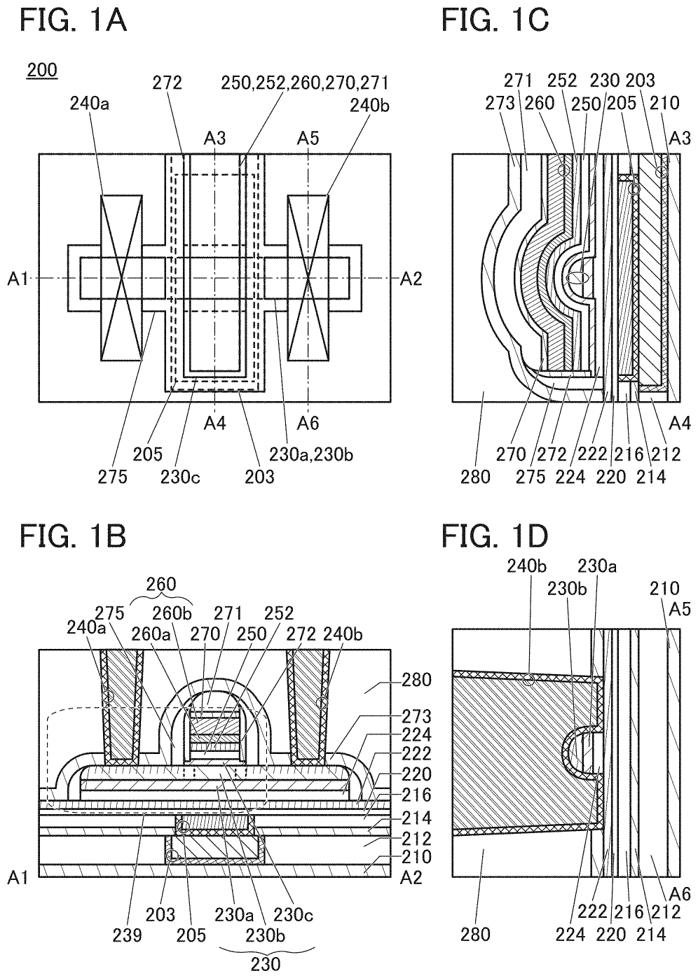

An example of a semiconductor device including a transistor 200 of one embodiment of the present invention will be described below.

<Structure example of semiconductor device> FIGS. 1A to 1D are a top view and cross-sectional views of the transistor 200 of one embodiment of the present invention and the periphery of the transistor 200.

FIG. 1A is a top view of the semiconductor device including the transistor 200. FIGS. 1B and 1C are cross-sectional views of the semiconductor device. FIG. 1B is a cross-sectional view taken along dashed-dotted line A1-A2 in FIG. 1A, which corresponds to a cross-sectional view in the channel length direction of the transistor 200. FIG. 1C is a cross-sectional view taken along dashed-dotted line A3-A4 in FIG. 1A, which corresponds to a cross-sectional view in the channel width direction of the transistor 200. FIG. 1D is a cross-sectional view taken along dashed-dotted line A5-A6 in FIG. 1A, which corresponds to a cross-sectional view of a source region or a drain region of the transistor 200. Note that for simplification of the drawing, some components are not illustrated in the top view in FIG. 1A.

The semiconductor device of one embodiment of the present invention includes the transistor 200 and insulators 210, 212, and 280 that function as interlayer films. The semiconductor device further includes a conductor 203 functioning as a wiring and a conductor 240 functioning as a plug. The conductor 203 and the conductor 240 are electrically connected to the transistor 200.

The conductor 203 includes a first conductor of the conductor 203 that is in contact with an inner wall of an opening of the insulator 212 and a second conductor of the conductor 203 that is located inward from the first conductor. Here, the top surface of the conductor 203 can be at substantially the same level as the top surface of the insulator 212. Although the first conductor and the second conductor of the conductor 203 are stacked in the transistor 200, the present invention is not limited thereto. For example, the conductor 203 may have a single-layer structure or a stacked-layer structure of three or more layers. Note that in the case where a stacked-layer structure is used, the layers may be distinguished by numbers corresponding to the formation order.

The conductor 240 is formed in contact with an inner wall of an opening of the insulator 280. Here, the top surface of the conductor 240 can be at substantially the same level as the top surface of the insulator 280. Although the conductor 240 in the transistor 200 has a two-layer structure, the present invention is not limited thereto. For example, the conductor 240 may have a single-layer structure or a stacked-layer structure of three or more layers.

[Transistor 200] As illustrated in FIGS. 1A to 1D, the transistor 200 includes insulators 214 and 216 provided over a substrate (not illustrated), a conductor 205 provided so as to be embedded in the insulators 214 and 216, an insulator 220 provided over the insulator 216 and the conductor 205, an insulator 222 provided over the insulator 220, an insulator 224 provided over the insulator 222, an oxide 230 (an oxide 230a, an oxide 230b, and an oxide 230c) provided over the insulator 224, an insulator 250 provided over the oxide 230, a metal oxide 252 provided over the insulator 250, a conductor 260 (a conductor 260a and a conductor 260b) provided over the metal oxide 252, an insulator 270 provided over the conductor 260, an insulator 271 provided over the insulator 270, an insulator 272 provided in contact with part of the top surface of the oxide 230c and at least the side surfaces of the insulator 250 and the conductor 260, an insulator 275 provided on the side surface of the conductor 260 with the insulator 272 positioned therebetween and provided on the side surfaces of the insulator 224, and the oxides 230a and 230b, and an insulator 273 provided on the side surface of the insulator 275 and over the oxide 230.

Although the transistor 200 has a structure in which the oxide 230a, the oxide 230b, and the oxide 230c are stacked, the present invention is not limited thereto. For example, the transistor 200 may have a single-layer structure of the oxide 230b, a two-layer structure of the oxide 230b and the oxide 230a or 230c, or a stacked-layer structure of four or more layers. Although the transistor 200 has a structure in which the conductor 260a and the conductor 260b are stacked, the present invention is not limited thereto.

In the transistor 200, the oxide 230 (the oxide 230a, the oxide 230b, and the oxide 230c), which includes a region where a channel is formed (hereinafter also referred to as a channel formation region) is preferably formed using a metal oxide functioning as an oxide semiconductor (hereinafter also referred to as an oxide semiconductor).

The transistor 200 including an oxide semiconductor in a channel formation region has an extremely low leakage current in an off state; thus, a semiconductor device with low power consumption can be provided. An oxide semiconductor can be formed by a sputtering method or the like and thus can be used in the transistor 200 included in a highly integrated semiconductor device.

For example, as the oxide 230, a metal oxide such as an In-M-Zn oxide (M is one or more of aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is used. An In—Ga oxide or an In—Zn oxide may be used as the oxide 230.

Here, in addition to the constituent element of the oxide semiconductor, the oxide semiconductor contains a metal element such as aluminum, ruthenium, titanium, tantalum, chromium, or tungsten, whereby the oxide semiconductor becomes a metal compound to have reduced resistance. Note that aluminum, titanium, tantalum, tungsten, or the like is preferably used. In order to add the metal element to the oxide semiconductor, for example, a metal film containing the metal element, a nitride film containing the metal element, or an oxide film containing the metal element is provided over the oxide semiconductor. By provision of such a film, some oxygen in the oxide semiconductor at and near an interface between the film and the oxide semiconductor may be absorbed by the film or the like and an oxygen vacancy may be formed, so that the resistance of the oxide semiconductor at and near the interface may be reduced.

After the metal film, the nitride film containing the metal element, or the oxide film containing the metal element is provided over the oxide semiconductor, heat treatment is preferably performed in an atmosphere containing nitrogen. By the heat treatment in an atmosphere containing nitrogen, the metal element is diffused from the metal film, the nitride film containing the metal element, or the oxide film containing the metal element into the oxide semiconductor; thus, the metal element can be added to the oxide semiconductor. At this time, the oxide semiconductor may be alloyed with the metal element. When the oxide semiconductor is alloyed with the metal element, the metal element added to the oxide semiconductor becomes relatively stable; therefore, a highly-reliable semiconductor device can be provided.

If hydrogen in the oxide semiconductor diffuses into a low-resistance region of the oxide semiconductor and enters an oxygen vacancy in the low-resistance region, the hydrogen becomes relatively stable. Hydrogen in an oxygen vacancy in an oxide semiconductor is released from the oxygen vacancy by heat treatment at 250° C. or higher, diffuses into a low-resistance region of the oxide semiconductor, enters an oxygen vacancy in the low-resistance region, and becomes relatively stable. Thus, by the heat treatment, the resistance of the low-resistance region or a region where the metal compound is formed of the oxide semiconductor tends to be further reduced, and the other region of the oxide semiconductor tends to be purified (impurities such as water or hydrogen therein tend to be reduced) and the resistance of the region tends to be increased.

An oxide semiconductor containing an impurity element such as hydrogen or nitrogen has a high carrier density. Hydrogen contained in the oxide semiconductor reacts with oxygen bonded to a metal atom to be water, and thus causes an oxygen vacancy in some cases. Entry of hydrogen into the oxygen vacancy increases carrier density. Furthermore, in some cases, bonding of part of hydrogen to oxygen bonded to a metal atom causes generation of an electron functioning as a carrier. That is, the resistance of an oxide semiconductor containing nitrogen or hydrogen is reduced.

Thus, selective addition of a metal element and an impurity element such as hydrogen and nitrogen to the oxide semiconductor can form a high-resistance region and a low-resistance region in the oxide semiconductor. In other words, when the resistance of the oxide 230 is selectively reduced, a region functioning as a semiconductor having a low carrier density and low-resistance regions functioning as the source region or the drain region can be formed in the island-shaped oxide 230.

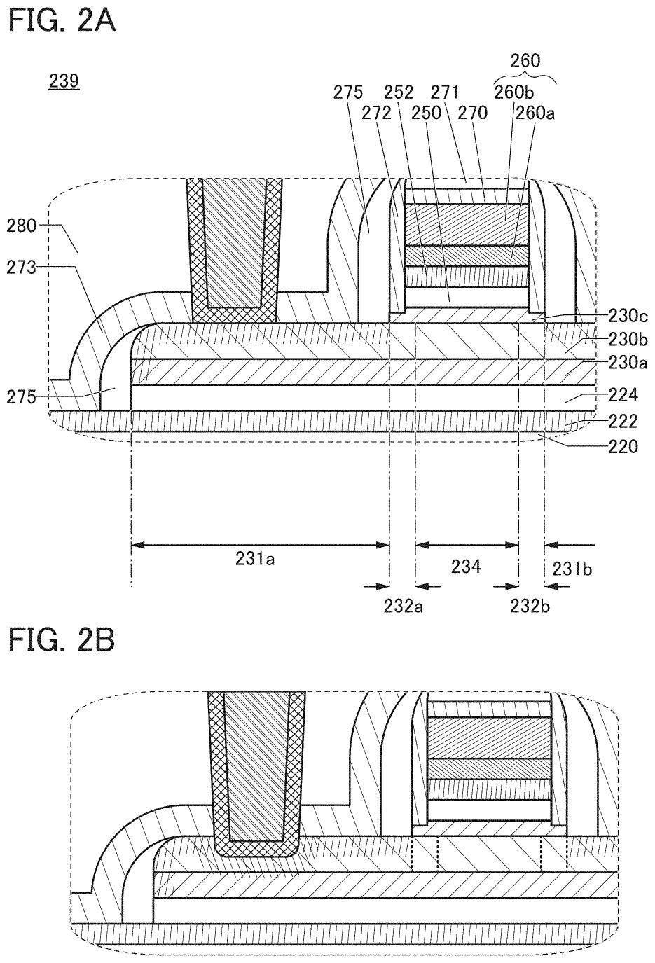

FIGS. 2A and 2B are enlarged views illustrating a region 239 surrounded by a dashed line in FIG. 1B.

As illustrated in FIG. 2A, the oxide 230 includes a region 234 functioning as a channel formation region of the transistor, a region 231 (a region 231a and a region 231b) functioning as a source region and a drain region, and a region 232 (a region 232a and a region 232b) provided between the region 234 and the region 231.

The region 231 functioning as the source region or the drain region has a low oxygen concentration and reduced resistance. The region 234 functioning as the channel formation region has a higher oxygen concentration and a lower carrier density than the region 231 functioning as the source region or the drain region. The region 232 has a higher oxygen concentration and a lower carrier density than the region 231 functioning as the source region or the drain region and has a lower oxygen concentration and a higher carrier density than the region 234 functioning as the channel formation region.

The concentration of at least one of a metal element and an impurity element such as hydrogen and nitrogen in the region 231 is preferably higher than that in each of the region 232 and the region 234.

In addition to the metal elements in the oxide 230, the region 231 preferably contains one or more of metal elements such as aluminum, ruthenium, titanium, tantalum, tungsten, and chromium. Addition of the metal element to the oxide 230 can reduce the resistance of the region 231. The region 231 may include a region where the metal element in the oxide 230 is alloyed with the added metal element.

The region 232 includes a region overlapping with the insulator 272. The concentration of at least one of metal elements such as aluminum, ruthenium, titanium, tantalum, tungsten, and chromium and impurity elements such as hydrogen and nitrogen in the region 232 is preferably higher than that in the region 234. In order to form the region 232, for example, a metal film, an oxide film containing a metal element, or a nitride film containing a metal element may be formed in contact with the region 231 of the oxide 230. Accordingly, the metal element in the film is added to the oxide semiconductor and a metal compound is formed in the oxide semiconductor in some cases. The metal compound attracts hydrogen in the oxide 230 in some cases. In this case, the hydrogen concentration of the region 232 in the vicinity of the region 231 may be increased.

One or both of the region 232a and the region 232b may have a region overlapping with the conductor 260.

Although the regions 234, 231, and 232 are formed in the oxide 230b in FIGS. 1A to 1D and FIGS. 2A and 2B, the present invention is not limited thereto. For example, these regions may be formed also in the oxide 230a and the oxide 230c. Although boundaries between the regions are indicated substantially perpendicularly to the top surface of the oxide 230 in FIGS. 1A to 1D and FIGS. 2A and 2B, this embodiment is not limited thereto. For example, the region 232 may project to the conductor 260 side in the vicinity of the surface of the oxide 230b, and the region 232 may recede to the conductor 240a or 240b side in the vicinity of the bottom surface of the oxide 230b.

In the oxide 230, a boundary between the regions cannot be observed clearly in some cases. The concentration of a metal element and an impurity element such as hydrogen and nitrogen, which is detected in each region, may be gradually changed (such a change is also referred to as gradation) not only between the regions but also in each region. That is, the region closer to the channel formation region preferably has a lower concentration of a metal element and impurity elements such as hydrogen and nitrogen.

In order to selectively reduce the resistance of the oxide 230, at least one of metal elements that increase conductivity such as aluminum, ruthenium, titanium, tantalum, tungsten, and chromium and an impurity is added to a desired region. As the impurity, the element that forms an oxygen vacancy, the element trapped by an oxygen vacancy, or the like may be used. Typical examples of the element are hydrogen, boron, carbon, nitrogen, fluorine, phosphorus, sulfur, chlorine, titanium, and a rare gas element. Typical examples of the rare gas element include helium, neon, argon, krypton, and xenon.

As described above, when the content of the metal element that increases conductivity, the element that forms an oxygen vacancy, and the element trapped by an oxygen vacancy in the region 231 is increased, the carrier density is increased and the resistance can be reduced.

In order to reduce the resistance of the region 231, for example, a metal film, an oxide film containing a metal element, a nitride film containing a metal element, or the like is formed in contact with the region 231 of the oxide 230. The metal film, the oxide film containing a metal element, or the nitride film containing a metal element is preferably formed over the oxide 230 with at least the insulator 250, the metal oxide 252, the conductor 260, the insulator 270, the insulator 271, the insulator 272, and the insulator 275 positioned therebetween.

When the metal film, the oxide film containing a metal element, or the nitride film containing a metal element is formed in contact with the region 231 of the oxide 230, a metal element is diffused from the film into the region 231 of the oxide 230 and a metal compound is formed in the region 231, whereby the resistance of the region 231 is reduced. Some oxygen in the oxide 230 at and near an interface between the region 231 and the metal film, the oxide film containing a metal element, or the nitride film containing a metal element may be absorbed by the film and an oxygen vacancy may be formed in the region 231, so that the resistance of the region 231 may be reduced.

An example of the low-resistance region of the oxide 230 is marked with diagonal lines in FIG. 2A. In this specification and the like, the area marked with diagonal lines is not limited to the areas illustrated in FIG. 2A. As illustrated in FIG. 2B, the low-resistance region (area) may be formed at and near an interface between the oxide 230 and the conductor 240 or in a region from the top surface to the bottom surface of the oxide 230 in the region 231, for example. The same applies to the other drawings.

Heat treatment is preferably performed in an atmosphere containing nitrogen in a state where the region 231 and the metal film, the oxide film containing a metal element, or the nitride film containing a metal element is in contact with each other. By the heat treatment, the metal element is diffused from the metal film, the nitride film containing the metal element, or the oxide film containing the metal element into the region 231 of the oxide 230; thus, the metal element can be added to the region 231. At this time, the region 231 of the oxide 230 may be alloyed with the metal element. When the region 231 of the oxide 230 is alloyed with the metal element, the metal element added to the oxide semiconductor becomes relatively stable; therefore, a highly-reliable semiconductor device can be provided.

If hydrogen in the oxide 230 diffuses into a region 231 and enters an oxygen vacancy in the region 231, the hydrogen becomes relatively stable. Hydrogen in an oxygen vacancy in the region 234 is released from the oxygen vacancy by heat treatment at 250° C. or higher, diffuses into the region 231, enters an oxygen vacancy in the region 231, and becomes relatively stable. Thus, the resistance of the region 231 is further reduced, and the region 234 is purified (impurities such as water or hydrogen therein are reduced) and the resistance of the region 234 is increased.

In contrast, since some regions (the regions 234 and 232) of the oxide 230 overlap with the conductor 260 and the insulator 272, addition of a metal element to the regions is prevented. Furthermore, absorption of oxygen in the regions 234 and 232 of the oxide 230 by the metal film, the nitride film containing a metal element, or the oxide film containing a metal element is prevented.

An oxygen vacancy may be formed in the region 231 and the region 232 due to absorption of oxygen in the region 231 of the oxide 230 and the region 232 of the oxide 230 adjacent to the region 231 by the metal film, the nitride film containing a metal element, or the oxide film containing a metal element. Entry of hydrogen in the oxide 230 to the oxygen vacancy increases the carrier density of the regions 231 and 232. Therefore, the regions 231 and 232 of the oxide 230 become low-resistance regions.

In the case where the metal film, the nitride film containing a metal element, or the oxide film containing a metal element has a property of absorbing hydrogen, hydrogen in the oxide 230 is absorbed by the film. Accordingly, hydrogen, which is an impurity in the oxide 230, can be reduced. In a later step, the metal film, the nitride film containing a metal element, or the oxide film containing a metal element may be removed together with hydrogen absorbed from the oxide 230.

The metal film, the nitride film containing a metal element, or the oxide film containing a metal element is not necessarily removed. When the metal film, the nitride film containing a metal element, or the oxide film containing a metal element is oxidized by oxygen absorbed from the oxide 230 to be a high-resistant insulator, for example, the film may remain. In this case, the film may function as an interlayer film.

In the case where a region having conductivity remains in the metal film, the nitride film containing a metal element, or the oxide film containing a metal element, for example, the region having conductivity is oxidized by heat treatment in an oxidization atmosphere, so that the region becomes a high-resistant insulator. The metal film, the nitride film containing a metal element, or the oxide film containing a metal element can function as an interlayer film when the film remains as an insulator.

Thus, the metal film, the nitride film containing a metal element, or the oxide film containing a metal element is preferably formed to have a thickness of greater than or equal to 0.5 nm and less than or equal to 5 nm, further preferably greater than or equal to 1 nm and less than or equal to 2 nm. When aluminum having a thickness of greater than or equal to 0.5 nm and less than or equal to 5 nm is oxidized by heat treatment, for example, aluminum oxide having a thickness of greater than or equal to 0.7 nm and less than or equal to 8 nm may be formed.

A transistor formed using an oxide semiconductor is likely to have its electrical characteristics changed by impurities and oxygen vacancies in a channel formation region in the oxide semiconductor; as a result, the reliability is reduced, in some cases. Moreover, if the channel formation region in the oxide semiconductor includes oxygen vacancies, the transistor tends to have normally-on characteristics. Thus, oxygen vacancies in the region 234 where a channel is formed are preferably reduced as much as possible.

As illustrated in FIGS. 1A to 1D and FIG. 2A, the insulator 275 containing oxygen at a higher proportion than oxygen in the stoichiometric composition (also referred to as “excess oxygen”) is preferably provided in contact with the insulator 224, the insulator 272, and the oxide 230c. That is, excess oxygen contained in the insulator 275 is diffused into the region 234 of the oxide 230, whereby oxygen vacancies in the region 234 of the oxide 230 can be reduced.

For the insulator 275, silicon oxide, silicon oxynitride, silicon nitride oxide, or porous silicon oxide is preferably used. An excess-oxygen region is likely to be formed in a material such as silicon oxynitride. In contrast, an excess-oxygen region is less likely to be formed in the oxide 230 compared with in the material such as silicon oxynitride. Therefore, provision of the insulator 275 including an excess-oxygen region in the periphery of the region 234 of the oxide 230 makes it possible to supply excess oxygen from the insulator 275 to the region 234 of the oxide 230 effectively.

In order to provide an excess-oxygen region in the insulator 275, an oxide is preferably formed by a sputtering method for the insulator 273 in contact with the insulator 275. The oxide formed by a sputtering method can be an insulator containing few impurities such as water or hydrogen. Deposition by a sputtering method is preferably performed with the use of a facing-target sputtering apparatus, for example With the use of the facing-target sputtering apparatus, deposition can be performed without exposing a deposition surface to a high electric field region between facing targets; thus, the film-formation surface is less likely to be damaged due to plasma. Since deposition damage on the oxide 230 due to plasma during the deposition of the insulator to be the insulator 273 can be small, the sputtering apparatus is preferably used. A deposition method using a facing-target sputtering apparatus can be referred to as vapor deposition SP (VDSP), registered trademark.

During deposition by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E₂ between the target and the substrate. The potential relationship is E₂>E₁>E₀.

The ions in plasma are accelerated by a potential difference (E₂−E₀) and collide with the target; accordingly, the sputtered particles are ejected from the target. These sputtered particles are attached to a deposition surface and deposited thereover; as a result, a film is formed. Some ions recoil by the target and might pass through the formed film as recoil ions, and be taken into the insulator 275 in contact with the formation surface. The ions in the plasma are accelerated by the potential difference (E₂−E₁) and collide with the deposition surface. Some ions reach the inside of the insulator 275. The ions are taken into the insulator 275; accordingly, a region into which the ions are taken is formed in the insulator 275. That is, an excess-oxygen region is formed in the insulator 275 in the case where the ions contain oxygen.

Introduction of excess oxygen into the insulator 275 can form an excess-oxygen region in the insulator 275. The excess oxygen in the insulator 275 is supplied to the region 234 of the oxide 230 and can fill oxygen vacancies in the oxide 230.

For the insulator 273, aluminum oxide is preferably used. When heat treatment is performed in a state where aluminum oxide is in contact with the oxide 230, the aluminum oxide extracts hydrogen in the oxide 230 in some cases. Thus, the hydrogen concentration of the oxide 230 can be reduced.

When the above-described structures or the above-described steps are combined, the resistance of the oxide 230 can be selectively reduced.

In formation of a low-resistance region in the oxide 230, the resistance of the oxide 230 is reduced in a self-aligned manner with the use of the conductor 260 functioning as a gate electrode or the insulator 272 as a mask. Therefore, when the plurality of transistors 200 are formed simultaneously, variations in electric characteristics of the transistors can be reduced. The channel length of the transistor 200 depends on the width of the conductor 260 and the thickness of the insulator 272. The transistor 200 can be miniaturized when the conductor 260 with the minimum feature width is used.

Thus, by appropriately selecting the areas of the regions, a transistor having electrical characteristics necessary for the circuit design can be easily provided.

An oxide semiconductor can be formed by a sputtering method or the like and thus can be used in a transistor included in a highly integrated semiconductor device. A transistor including an oxide semiconductor in a channel formation region has an extremely low leakage current (off-state current) in an off state; thus, a semiconductor device with low power consumption can be provided.

Accordingly, a semiconductor device including a transistor having a high on-state current can be provided. Alternatively, a semiconductor device including a transistor having a low off-state current can be provided. Alternatively, a semiconductor device that has small variation in electrical characteristics, i.e., stable electrical characteristics, and has high reliability can be provided.

The structure of the semiconductor device including the transistor 200 of one embodiment of the present invention will be described in detail below.

The conductor 203 extends in the channel width direction as illustrated in FIGS. 1A and 1C and functions as a wiring that applies a potential to the conductor 205. The conductor 203 is preferably provided so as to be embedded in the insulator 212.

The conductor 205 is provided to overlap with the oxide 230 and the conductor 260.

Moreover, the conductor 205 may be provided over and in contact with the conductor 203. The conductor 205 is preferably provided so as to be embedded in the insulator 214 and the insulator 216.

Here, the conductor 260 functions as a first gate (also referred to as a top gate) electrode in some cases. The conductor 205 functions as a second gate (also referred to as a bottom gate) electrode in some cases. In that case, by changing a potential applied to the conductor 205 independently of a potential applied to the conductor 260, the threshold voltage of the transistor 200 can be controlled. In particular, by applying a negative potential to the conductor 205, the threshold voltage of the transistor 200 can be higher than 0 V, and the off-state current can be reduced. Thus, a drain current when a potential applied to the conductor 260 is 0 V can be smaller in the case where a negative potential is applied to the conductor 205 than in the case where the negative potential is not applied to the conductor 205.

When the conductor 205 is provided over the conductor 203, the distance between the conductor 203 and the conductor 260 functioning as the first gate electrode and the wiring can be set as appropriate. That is, the insulators 214 and 216 and the like are provided between the conductors 203 and 260, whereby a parasitic capacitance between the conductors 203 and 260 can be reduced, and the withstand voltage between the conductors 203 and 260 can be increased.

The reduction in the parasitic capacitance between the conductors 203 and 260 can improve the switching speed of the transistor 200, so that the transistor 200 can have high frequency characteristics. The increase in the withstand voltage between the conductors 203 and 260 can improve the reliability of the transistor 200. Therefore, the insulator 214 and the insulator 216 are preferably thick. Note that the extending direction of the conductor 203 is not limited to this example; for example, the conductor 203 may extend in the channel length direction of the transistor 200.

As illustrated in FIG. 1A, the conductor 205 is provided to overlap with the oxide 230 and the conductor 260. The conductor 205 is preferably larger than the region 234 of the oxide 230. As illustrated in FIG. 1C, it is particularly preferable that the conductor 205 extend beyond the end portion of the region 234 of the oxide 230 that intersects with the channel width direction. That is, the conductor 205 and the conductor 260 preferably overlap with each other with the insulator positioned therebetween to overlap with the side surface of the oxide 230 in the channel width direction.

With the above structure, in the case where potentials are applied to the conductor 260 and the conductor 205, an electric field generated from the conductor 260 and an electric field generated from the conductor 205 are connected, so that the channel formation region in the oxide 230 can be covered.

That is, the channel formation region in the region 234 can be electrically surrounded by the electric field of the conductor 260 functioning as the first gate electrode and the electric field of the conductor 205 functioning as the second gate electrode. In this specification, such a transistor structure in which the channel formation region is electrically surrounded by the electric fields of the first gate electrode and the second gate electrode is referred to as a surrounded channel (s-channel) structure.

In the conductor 205, a first conductor is formed in contact with an inner wall of an opening of the insulators 214 and 216 and a second conductor is formed on an inner side than the first conductor. Here, the top surfaces of the first and second conductors can be at substantially the same level as the top surface of the insulator 216. Although the first and second conductors are stacked in the transistor 200, the present invention is not limited thereto. For example, the conductor 205 may have a single-layer structure or a stacked-layer structure of three or more layers.

The first conductor of the conductor 205 or 203 is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, a conductive material through which the above impurities are less likely to pass. Alternatively, the first conductor of the conductor 205 or 203 is preferably formed using a conductive material having a function of inhibiting diffusion of oxygen (e.g., at least one of oxygen atoms, oxygen molecules, or the like), that is, a conductive material through which the above oxygen is less likely to pass. Note that in this specification, a function of inhibiting diffusion of impurities or oxygen means a function of inhibiting diffusion of any one or all of the above impurities and the above oxygen.

When the first conductor of the conductor 205 or 203 has a function of inhibiting diffusion of oxygen, the conductivity of the second conductor of the conductor 205 or 203 can be prevented from being lowered because of oxidization of the second conductor of the conductor 205 or 203. As a conductive material having a function of inhibiting diffusion of oxygen, for example, tantalum, tantalum nitride, ruthenium, ruthenium oxide, or the like is preferably used. Thus, the first conductor of the conductor 205 or 203 may be a single layer or a stacked layer of the above conductive materials. Thus, impurities such as water or hydrogen can be inhibited from being diffused into the transistor 200 side through the conductors 203 and 205.

A conductive material containing tungsten, copper, or aluminum as its main component is preferably used for the second conductor of the conductor 205. Note that the second conductor of the conductor 205 is a single layer in the drawing but may have a stacked-layer structure, for example, a stacked layer of titanium, titanium nitride, and any of the above conductive materials.

The second conductor of the conductor 203 functions as a wiring and thus is preferably a conductor having higher conductivity than the second conductor of the conductor 205. For example, a conductive material containing copper or aluminum as its main component can be used. The second conductor of the conductor 203 may have a stacked-layer structure, for example, a stacked layer of titanium, titanium nitride, and any of the above conductive materials.

It is particularly preferable to use copper for the conductor 203. Copper is preferably used for the wiring and the like because of its small resistance. However, copper is easily diffused. Copper may deteriorate the electrical characteristics of the transistor 200 when diffused into the oxide 230. In view of the above, for example, the insulator 214 is formed using a material such as aluminum oxide or hafnium oxide having low copper-transmitting property, whereby diffusion of copper can be inhibited.

The conductor 205, the insulator 214, and the insulator 216 are unnecessary. In this case, part of the conductor 203 can function as the second gate electrode.

Accordingly, each of the insulators 210 and 214 preferably functions as a barrier insulating film for inhibiting impurities such as water or hydrogen from entering the transistor 200 from the substrate side. Accordingly, each of the insulators 210 and 214 is preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, an insulating material through which the above impurities are less likely to pass. Alternatively, each of the insulators 210 and 214 is preferably formed using an insulating material having a function of inhibiting diffusion of oxygen (e.g., at least one of oxygen atoms, oxygen molecules, or the like), that is, an insulating material through which the above oxygen is less likely to pass.

For example, it is preferable that aluminum oxide or the like be used for the insulator 210 and that silicon nitride or the like be used for the insulator 214. Accordingly, impurities such as water or hydrogen can be inhibited from being diffused into the transistor 200 side from the substrate side from the insulators 210 and 214. In addition, oxygen contained in the insulator 224 and the like can be inhibited from being diffused into the substrate side from the insulators 210 and 214.

Furthermore, with the structure in which the conductor 205 is stacked over the conductor 203, the insulator 214 can be provided between the conductor 203 and the conductor 205. Here, even when a metal that is easily diffused, such as copper, is used as the second conductor of the conductor 203, silicon nitride or the like provided as the insulator 214 can inhibit diffusion of the metal to a layer positioned above the insulator 214.

The permittivity of each of the insulators 212, 216, and 280 functioning as an interlayer film is preferably lower than that of the insulator 210 or 214. When a material with a low permittivity is used as an interlayer film, the parasitic capacitance between wirings can be reduced.

For example, the insulators 212, 216, and 280 can be formed to have a single-layer structure or a stacked-layer structure using any of insulators such as silicon oxide, silicon oxynitride, silicon nitride oxide, aluminum oxide, hafnium oxide, tantalum oxide, zirconium oxide, lead zirconate titanate (PZT), strontium titanate (SrTiO₃), and (Ba,Sr)TiO₃ (BST). Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

The insulators 220, 222, and 224 function as gate insulators.

Here, as the insulator 224 in contact with the oxide 230, an insulator containing more oxygen than that in the stoichiometric composition is preferably used. That is, an excess-oxygen region is preferably formed in the insulator 224. When such an insulator containing excess oxygen is provided in contact with the oxide 230, oxygen vacancies in the oxide 230 can be reduced, leading to an improvement in reliability of the transistor 200.

As the insulator including the excess-oxygen region, specifically, an oxide material that releases part of oxygen by heating is preferably used. An oxide that releases oxygen by heating is an oxide film in which the amount of released oxygen converted into oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in thermal desorption spectroscopy (TDS) analysis. In the TDS analysis, the film surface temperature is preferably higher than or equal to 100° C. and lower than or equal to 700° C., or higher than or equal to 100° C. and lower than or equal to 400° C.

In the case where the insulator 224 includes an excess-oxygen region, the insulator 222 preferably has a function of inhibiting diffusion of oxygen (e.g., at least one of oxygen atoms or oxygen molecules). That is, it is preferable that the above oxygen be less likely to pass through the insulator 222.

When the insulator 222 has a function of inhibiting diffusion of oxygen, oxygen in the excess-oxygen region of the insulator 224 is not diffused into the insulator 220 side and thus can be supplied to the oxide 230 efficiently. The conductor 205 can be inhibited from reacting with oxygen in the excess-oxygen region of the insulator 224.

The insulator 222 preferably has a single-layer structure or a stacked-layer structure using an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST). With miniaturization and high integration of a transistor, a problem such as generation of leakage current may arises because of a thin gate insulator. When a high-k material is used for an insulator functioning as the gate insulator, a gate potential at the time of operating the transistor can be reduced while keeping the physical thickness of the gate insulator.

It is particularly preferable to use an insulator containing an oxide of one or both of aluminum and hafnium, that is an insulating material having a function of inhibiting diffusion of impurities, oxygen, and the like, that is an insulating material through which oxygen is less likely to pass. Aluminum oxide, hafnium oxide, an oxide containing aluminum and hafnium (hafnium aluminate), or the like is preferably used for the insulator containing an oxide of one or both of aluminum and hafnium. The insulator 222 formed of such a material serves as a layer that prevents release of oxygen from the oxide 230 and entry of impurities such as hydrogen from the periphery of the transistor 200 into the oxide 230.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 220 be thermally stable. Because silicon oxide and silicon oxynitride have thermal stability, combination of silicon oxide or silicon oxynitride with an insulator which is a high-k material allows a gate insulator to have a stacked-layer structure that is thermally stable and has a high relative permittivity, for example.

Note that the insulators 220, 222, and 224 each may have a stacked-layer structure of two or more layers. In this case, the stacked layers are not necessarily formed of the same material but may be formed of different materials.

The oxide 230 includes the oxide 230a, the oxide 230b over the oxide 230a, and the oxide 230c over the oxide 230b. When the oxide 230a is provided below the oxide 230b, impurities can be inhibited from being diffused into the oxide 230b from the components formed below the oxide 230a. When the oxide 230c is provided over the oxide 230b, impurities can be inhibited from being diffused into the oxide 230b from the components formed over the oxide 230c.

The oxide 230 preferably has a stacked-layer structure of oxides which differ in the atomic ratio of metal elements. Specifically, the atomic ratio of the element M to constituent elements in the metal oxide used as the oxide 230a is preferably greater than that in the metal oxide used as the oxide 230b. Moreover, the atomic ratio of the element M to In in the metal oxide used as the oxide 230a is preferably greater than that in the metal oxide used as the oxide 230b. Moreover, the atomic ratio of In to the element M in the metal oxide used as the oxide 230b is preferably greater than that in the metal oxide used as the oxide 230a. The oxide 230c can be formed using a metal oxide which can be used as the oxide 230a or 230b.

The energy of the conduction band minimum of each of the oxides 230a and 230c is preferably higher than that of the oxide 230b. In other words, the electron affinity of each of the oxides 230a and 230c is preferably smaller than that of the oxide 230b.

Here, the energy level of the conduction band minimum is gradually varied at a junction portion of each of the oxides 230a, 230b, and 230c. In other words, the energy level of the conduction band minimum at a junction portion of each of the oxides 230a, 230b, and 230c is continuously varied or continuously connected. To vary the energy level gradually, the density of defect states in a mixed layer formed at the interface between the oxides 230a and 230b and the interface between the oxides 230b and 230c is decreased.

Specifically, when the oxides 230a and 230b or the oxides 230b and 230c contain the same element (as a main component) in addition to oxygen, a mixed layer with a low density of defect states can be formed. For example, in the case where the oxide 230b is an In—Ga—Zn oxide, it is preferable to use an In—Ga—Zn oxide, a Ga—Zn oxide, gallium oxide, or the like as each of the oxides 230a and 230c.

At this time, the oxide 230b serves as a main carrier path. When the oxides 230a and 230c have the above structure, the density of defect states at the interface between the oxides 230a and 230b and the interface between the oxides 230b and 230c can be made low. Thus, the influence of interface scattering on carrier conduction is small, and the transistor 200 can have a high on-state current.

The oxide 230 includes the regions 231, 232, and 234. Note that at least part of the region 231 is in contact with the insulator 273. The region 232 has a region overlapping with at least the insulator 272.

When the transistor 200 is turned on, the region 231a or 231b functions as the source region or the drain region. At least part of the region 234 functions as a channel formation region. Since the region 232 is provided between the region 234 and the region 231, the transistor 200 can have a high on-state current and a low leakage current (off-state current) in an off state.

When the region 232 is provided in the transistor 200, high-resistance regions are not formed between the region 231 functioning as the source region and the drain region and the region 234 where a channel is formed, so that the on-state current and the carrier mobility of the transistor can be increased. Since the first gate electrode (the conductor 260) does not overlap with the source and drain regions in the channel length direction owing to the region 232, formation of unnecessary capacitance between the first gate electrode (the conductor 260) and the source and drain regions can be suppressed. Leakage current in an off state can be reduced owing to the region 232.

Thus, by appropriately selecting the areas of the regions, a transistor having electrical characteristics necessary for the circuit design can be easily provided.

The oxide 230 is preferably formed using a metal oxide functioning as an oxide semiconductor (hereinafter, the metal oxide is also referred to as an oxide semiconductor). For example, the metal oxide to be the region 234 preferably has a band gap of 2 eV or more, preferably 2.5 eV or more. In this manner, off-state current of a transistor can be reduced by using a metal oxide having a wide band gap.

A transistor including an oxide semiconductor has an extremely low leakage current in an off state; thus, a semiconductor device with low power consumption can be provided. An oxide semiconductor can be formed by a sputtering method or the like and thus can be used in a transistor included in a highly integrated semiconductor device.

The insulator 250 functions as a gate insulator. The insulator 250 is preferably provided in contact with the top surface of the oxide 230c. The insulator 250 is preferably formed using an insulator from which oxygen is released by heating. The insulator 250 is an insulating film of which the amount of released oxygen converted into oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in thermal desorption spectroscopy (TDS) analysis. In the TDS analysis, the film surface temperature is preferably higher than or equal to 100° C. and lower than or equal to 700° C.

Specifically, any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide, each of which containing excess oxygen, can be used. In particular, silicon oxide and silicon oxynitride, which have thermal stability, are preferable.

When as the insulator 250, an insulator from which oxygen is released by heating is provided in contact with the top surface of the oxide 230c, oxygen can be effectively supplied from the insulator 250 to the region 234 of the oxide 230b. Furthermore, like the insulator 224, the concentration of impurities such as water or hydrogen in the insulator 250 is preferably lowered. The thickness of the insulator 250 is preferably greater than or equal to 1 nm and less than or equal to 20 nm.

Furthermore, in order that oxygen of the insulator 250 can be efficiently supplied to the oxide 230, the metal oxide 252 may be provided. Therefore, the metal oxide 252 preferably inhibits diffusion of oxygen from the insulator 250. Provision of the metal oxide 252 that inhibits diffusion of oxygen inhibits diffusion of excess oxygen from the insulator 250 to the conductor 260. That is, reduction in the amount of excess oxygen supplied to the oxide 230 can be suppressed. Moreover, oxidization of the conductor 260 due to excess oxygen can be suppressed.

Note that the metal oxide 252 functions as the part of the gate insulator in some cases. Therefore, when silicon oxide or silicon oxynitride is used for the insulator 250, a metal oxide that is a high-k material with a high relative permittivity is preferably used as the metal oxide 252. Such a stacked-layer structure can be thermally stable and can have a high relative permittivity. Accordingly, a gate potential applied during operation of the transistor can be reduced while keeping the physical thickness of the gate insulator. In addition, an equivalent oxide thickness (EOT) of an insulator functioning as the gate insulator can be reduced.

The metal oxide 252 may function as part of a first gate. For example, an oxide semiconductor that can be used as the oxide 230 can be used as the metal oxide 252. In this case, if the conductor 260 is formed by a sputtering method, the metal oxide 252 can have reduced electric resistance and become a conductor. Such a conductor can be called an oxide conductor (OC) electrode.

With the metal oxide 252, the on-state current of the transistor 200 can be increased without a reduction in the influence of the electric field applied from the conductor 260. Since the distance between the conductor 260 and the oxide 230 is kept by the physical thicknesses of the insulator 250 and the metal oxide 252, leakage current between the conductor 260 and the oxide 230 can be reduced. Moreover, with the stacked-layer structure of the insulator 250 and the metal oxide 252, the physical distance between the conductor 260 and the oxide 230 and the electric field intensity applied from the conductor 260 to the oxide 230 can be easily adjusted as appropriate.

Specifically, a metal oxide containing one or more of hafnium, aluminum, gallium, yttrium, zirconium, tungsten, titanium, tantalum, nickel, germanium, magnesium, and the like can be used as the metal oxide 252. The oxide semiconductor that can be used for the oxide 230 can also be used for the metal oxide 252 as long as the resistance thereof is reduced.

It is particularly preferable to use an insulator containing an oxide of one or both of aluminum and hafnium, for example, aluminum oxide, hafnium oxide, or an oxide containing aluminum and hafnium (hafnium aluminate). In particular, hafnium aluminate has higher heat resistance than a hafnium oxide film. Thus, hafnium aluminate is less likely to be crystallized in a thermal budget in a later step, so that hafnium aluminate is preferable.

The conductor 260 functioning as the first gate electrode includes the conductor 260a and the conductor 260b over the conductor 260a. Like the first conductor of the conductor 205, the conductor 260a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 260a is preferably formed using a conductive material having a function of inhibiting diffusion of oxygen (e.g., at least one of oxygen atoms, oxygen molecules, or the like).

When the conductor 260a has a function of inhibiting diffusion of oxygen, the conductivity of the conductor 260b can be prevented from being lowered because of oxidization due to excess oxygen in the insulator 250 and the metal oxide 252. As a conductive material having a function of inhibiting diffusion of oxygen, for example, tantalum, tantalum nitride, ruthenium, ruthenium oxide, or the like is preferably used.

The conductor 260 functions as a wiring and thus is preferably a conductor having high conductivity. For example, a conductive material containing tungsten, copper, or aluminum as its main component can be used as the conductor 260b. The conductor 260b may have a stacked-layer structure, for example, a stacked layer of titanium, titanium nitride, and any of the above conductive materials.

In the case where the conductor 205 extends beyond the end portions of the oxide 230 that intersect with the channel width direction as illustrated in FIG. 1C, the conductor 260 preferably overlaps with the conductor 205 with the insulator 250 positioned therebetween. That is, a stacked-layer structure of the conductor 205, the insulator 250, and the conductor 260 is preferably formed outside the side surface of the oxide 230.

With the above structure, in the case where potentials are applied to the conductor 260 and the conductor 205, an electric field generated from the conductor 260 and an electric field generated from the conductor 205 are connected, so that the channel formation region in the oxide 230 can be covered.

That is, the channel formation region in the region 234 can be electrically surrounded by the electric field of the conductor 260 functioning as the first gate electrode and the electric field of the conductor 205 functioning as the second gate electrode.

Furthermore, the insulator 270 functioning as a barrier film may be provided over the conductor 260b. Here, the insulator 270 is preferably formed using an insulating material having a function of inhibiting the penetration of oxygen and impurities such as water or hydrogen. For example, aluminum oxide or hafnium oxide is preferably used. Therefore, oxidization of the conductor 260 due to oxygen from above the insulator 270 can be inhibited. Moreover, entry of impurities such as water or hydrogen from above the insulator 270 into the oxide 230 through the conductor 260 and the insulator 250 can be inhibited.

Furthermore, the insulator 271 functioning as a hard mask is preferably provided over the insulator 270. By provision of the insulator 271, the conductor 260 can be processed to have the side surface that is substantially perpendicular. Specifically, an angle formed by the side surface of the conductor 260 and a surface of the substrate can be greater than or equal to 75° and less than or equal to 100°, preferably greater than or equal to 80° and less than or equal to 95°. When the conductor 260 is processed into such a shape, the insulator 272 that is subsequently formed can be formed into a desired shape.

The insulator 271 may be formed using an insulating material having a function of inhibiting the penetration of oxygen and impurities such as water or hydrogen so that the insulator 271 also functions as a barrier film. In this case, the insulator 270 is unnecessary.

The insulator 272 functioning as a barrier film and a buffer film is provided in contact with the side surface of the insulator 250, the side surface of the metal oxide 252, the side surface of the conductor 260, and the side surface of the insulator 270.

The insulator 272 functioning as a buffer film is provided in contact with the side surface of the oxide 230c, the side surface of the insulator 250, the side surface of the metal oxide 252, the side surface of the conductor 260, and the side surface of the insulator 270. The insulator 272 may be formed using an insulating material having a function of inhibiting the penetration of oxygen and impurities such as water or hydrogen. In this case, the insulator 272 also functions as a barrier film.

For example, the insulator 272 is preferably formed by an ALD method. A dense thin film can be formed by an ALD method. For example, aluminum oxide or hafnium oxide is preferably used for the insulator 272. When aluminum oxide is formed by an ALD method as the insulator 272, the insulator 272 preferably has a thickness of greater than or equal to 0.5 nm and less than or equal to 3.0 nm.

By provision of the insulator 272, the side surfaces of the insulator 250, the metal oxide 252, and the conductor 260 can be covered with an insulator that has a function of inhibiting the penetration of oxygen and impurities such as water or hydrogen. Thus, impurities such as water or hydrogen can be inhibited from entering the oxide 230 through the end portion or the like of the insulator 250 and the metal oxide 252. Thus, the formation of an oxygen vacancy at the interface between the oxide 230 and the insulator 250 can be inhibited, leading to an improvement in the reliability of the transistor 200. That is, the insulator 272 functions as a side barrier for protecting the side surfaces of the gate electrode and the gate insulator.

With this structure, oxidization of the conductor 260 can be prevented, and excess oxygen can be supplied from the insulator 275 to the insulator 250.

The insulator 275 is provided on the side surfaces of the metal oxide 252, the insulator 250, and the conductor 260 with the insulator 272 positioned therebetween. The insulator 275 preferably includes an excess-oxygen region. In the case where the insulator 224 has an island shape, the insulator 224 and the insulator 275 may be in contact with each other at an end portion of the insulator 224. With this structure, excess oxygen in the insulator 275 can be supplied to the oxide 230 through the insulator 224.

The insulator 273 is provided at least over the region 231 of the oxide 230 and over the insulator 275. When the insulator 273 is formed by a sputtering method, the insulator 275 can include an excess-oxygen region. Therefore, oxygen can be supplied from the excess-oxygen region to the oxide 230. Since the insulator 273 is provided over the region 231 of the oxide 230, hydrogen in the oxide 230 can be extracted to the insulator 273.

For example, a metal oxide containing one or more of hafnium, aluminum, gallium, yttrium, zirconium, tungsten, titanium, tantalum, nickel, germanium, magnesium, and the like can be used as the insulator 273.

In particular, aluminum oxide has high barrier property, so that even a thin aluminum oxide film having a thickness of greater than or equal to 0.5 nm and less than or equal to 3.0 nm can inhibit diffusion of hydrogen and nitrogen.

The insulator 280 functioning as an interlayer film is preferably provided over the insulator 273. Like the insulator 224 or the like, the concentration of impurities such as water or hydrogen in the insulator 280 is preferably lowered. Note that an insulator similar to the insulator 210 may be provided over the insulator 280.

The conductor 240a and the conductor 240b are provided in the openings formed in the insulator 280 and the insulator 273. The conductors 240a and 240b are provided to face each other with the conductor 260 positioned therebetween. Note that the top surfaces of the conductors 240a and 240b may be at the same level as the top surface of the insulator 280.

The conductor 240a is in contact with the region 231a functioning as one of a source region and a drain region of the transistor 200, and the conductor 240b is in contact with the region 231b functioning as the other of the source region and the drain region of the transistor 200. Thus, the conductor 240a can function as one of a source electrode and a drain electrode, and the conductor 240b can function as the other of the source electrode and the drain electrode.

The conductor 240 is formed in contact with the inner wall of the opening in the insulator 280 and the insulator 273. At least part of the region 231a of the oxide 230 is positioned at the bottom of the opening, and thus the conductor 240a is in contact with the region 231a. Similarly, the conductor 240b is formed in contact with the inner wall of the opening in the insulator 280 and the insulator 273. At least part of the region 231b of the oxide 230 is positioned at the bottom of the opening, and thus the conductor 240b is in contact with the region 231b.

As illustrated in FIG. 1D, the conductors 240a and 240b are at least in contact with the top surface of the oxide 230, preferably further in contact with the side surface of the oxide 230. It is particularly preferable that the conductors 240a and 240b be in contact with one or both of the side surface of the oxide 230 on the A5 side and the side surface of the oxide 230 on the A6 side, which intersect with the channel width direction of the oxide 230. The conductors 240a and 240b may be in contact with the side surface of the oxide 230 on the A1 side (the A2 side), which intersects with the channel length direction of the oxide 230. When the conductors 240a and 240b are in contact with not only the top surface of the oxide 230 but also the side surface of the oxide 230, the area where the conductors 240a and 240b and the oxide 230 are in contact with each other can be increased without an increase in the area of the top surface of the contact portion, so that the contact resistance between the conductors 240a and 240b and the oxide 230 can be reduced. Accordingly, miniaturization of the source electrode and the drain electrode of the transistor can be achieved and, in addition, the on-state current can be increased.

The conductors 240a and 240b are each preferably formed using a conductive material containing tungsten, copper, or aluminum as its main component. The conductors 240a and 240b may have a stacked-layer structure.

When the opening is formed in the insulator 280 and the insulator 273, for example, a low-resistance region of the region 231 of the oxide 230 may be removed as illustrated in FIG. 2B. In this case, a conductor used for a first conductor of the conductor 240 may be formed using a metal film, a nitride film containing a metal element, or an oxide film containing a metal element. When the oxide 230 and the first conductor of the conductor 240 are in contact with each other, a metal compound or an oxygen vacancy is formed, whereby the resistance of the region 231 of the oxide 230 is reduced. The reduction in the resistance of the oxide 230 that is in contact with the first conductor of the conductor 240 can reduce contact resistance between the oxide 230 and the conductor 240. The first conductor of the conductor 240 preferably contains a metal element such as aluminum, ruthenium, titanium, tantalum, or tungsten.

In the case where the conductor 240 has a stacked-layer structure, a conductive material having a function of inhibiting the penetration of impurities such as water or hydrogen is preferably used for a conductor in contact with the insulators 273 and 280, as in the first conductor of the conductor 205, for example. For example, tantalum, tantalum nitride, titanium, titanium nitride, ruthenium, ruthenium oxide, or the like is preferably used. The conductive material having a function of inhibiting the penetration of impurities such as water or hydrogen may have a single-layer structure or a stacked-layer structure. With the use of the conductive material, impurities such as water or hydrogen can be inhibited from entering the oxide 230 through the conductors 240a and 240b from a layer above the insulator 280.

Although not illustrated, conductors functioning as wirings may be provided in contact with the top surfaces of the conductors 240a and 240b. The conductor functioning as a wiring is preferably formed using a conductive material containing tungsten, copper, or aluminum as its main component. The conductor may have a stacked-layer structure, for example, a stacked layer of titanium, titanium nitride, and any of the above conductive materials. Note that like the conductor 203 or the like, the conductor may be formed so as to be embedded in an opening provided in an insulator.

<Material for semiconductor device> Materials that can be used for a semiconductor device will be described below.

<<Substrate>> As a substrate over which the transistor 200 is formed, for example, an insulator substrate, a semiconductor substrate, or a conductor substrate may be used. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a semiconductor substrate of silicon, germanium, or the like, or a compound semiconductor substrate of silicon carbide, silicon germanium, gallium arsenide, indium phosphide, zinc oxide, or gallium oxide can be used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate. As a method for providing a transistor over a flexible substrate, there is a method in which the transistor is formed over a non-flexible substrate and then the transistor is separated and transferred to the substrate which is a flexible substrate. In that case, a separation layer is preferably provided between the non-flexible substrate and the transistor. The substrate may have elasticity. The substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. When the substrate has a small thickness, even in the case of using glass or the like, the substrate may have elasticity or a property of returning to its original shape when bending or pulling is stopped. Therefore, an impact applied to the semiconductor device over the substrate due to dropping or the like can be reduced. That is, a durable semiconductor device can be provided.

For the substrate which is a flexible substrate, metal, an alloy, resin, glass, or fiber thereof can be used, for example. As the substrate, a sheet, a film, or a foil containing a fiber may be used. The flexible substrate preferably has a lower coefficient of linear expansion because deformation due to an environment is suppressed. The flexible substrate is formed using, for example, a material whose coefficient of linear expansion is lower than or equal to 1×10′/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate because of its low coefficient of linear expansion.

<<Insulator>> Examples of an insulator include an insulating oxide, an insulating nitride, an insulating oxynitride, an insulating nitride oxide, an insulating metal oxide, an insulating metal oxynitride, and an insulating metal nitride oxide.

With miniaturization and high integration of a transistor, for example, a problem such as generation of leakage current may arises because a thin gate insulator. When a high-k material is used for an insulator functioning as the gate insulator, driving voltage of the transistor can be reduced while keeping the physical thickness of the gate insulator. In contrast, when a material with a low relative permittivity is used for the insulator functioning as an interlayer film, the parasitic capacitance between wirings can be reduced. Accordingly, a material is preferably selected depending on the function of an insulator.

As the insulator having a high relative permittivity, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like can be given.

As the insulator having a low relative permittivity, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be given.

In particular, silicon oxide and silicon oxynitride are thermally stable. Accordingly, a stacked-layer structure which is thermally stable and has a low relative permittivity can be obtained by combination with a resin, for example Examples of the resin include polyester, polyolefin, polyamide (e.g., nylon or aramid), polyimide, polycarbonate, and acrylic. Furthermore, combination of silicon oxide or silicon oxynitride with an insulator with a high relative permittivity allows the stacked-layer structure to be thermally stable and have a high relative permittivity, for example.

Note that when the transistor including an oxide semiconductor is surrounded by an insulator that has a function of inhibiting the penetration of oxygen and impurities such as hydrogen, the electrical characteristics of the transistor can be stabilized.

The insulator that has a function of inhibiting the penetration of oxygen and impurities such as hydrogen can have, for example, a single-layer structure or a stacked-layer structure of an insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the penetration of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide, silicon nitride oxide, silicon nitride, or the like can be used.

For example, a metal oxide containing one or more of hafnium, aluminum, gallium, yttrium, zirconium, tungsten, titanium, tantalum, nickel, germanium, magnesium, and the like can be used as the insulator 273.

In particular, aluminum oxide has high barrier property, so that even a thin aluminum oxide film having a thickness of greater than or equal to 0.5 nm and less than or equal to 3.0 nm can inhibit diffusion of hydrogen and nitrogen. Although hafnium oxide has lower barrier property than aluminum oxide, hafnium oxide having a large thickness can have high barrier property. Therefore, the appropriate addition amount of hydrogen and nitrogen can be adjusted by adjustment of the thickness of hafnium oxide.

For example, the insulator 224 and the insulator 250 functioning as part of the gate insulator are each preferably an insulator including an excess-oxygen region. When a structure in which silicon oxide or silicon oxynitride including an excess-oxygen region is in contact with the oxide 230 is employed, oxygen vacancies in the oxide 230 can be filled.

An insulator containing an oxide of one or more of aluminum, hafnium, and gallium can be used for each of the insulator 222 and the metal oxide 252, which function as part of the gate insulator, for example. It is particularly preferable to use an insulator containing an oxide of one or both of aluminum and hafnium, for example, aluminum oxide, hafnium oxide, or an oxide containing aluminum and hafnium (hafnium aluminate).

The insulator 220 is preferably formed using silicon oxide or silicon oxynitride, which is thermally stable, for example. When the gate insulator has a stacked-layer structure of a thermally-stable film and a film with a high relative permittivity, an equivalent oxide thickness (EOT) of the gate insulator can be reduced while keeping the physical thickness of the gate insulator.

With the above stacked-layer structure, on-state current can be increased without a reduction in the influence of the electric field applied from the gate electrode. Since the distance between the gate electrode and the channel formation region is kept by the physical thickness of the gate insulator, leakage current between the gate electrode and the channel formation region can be suppressed.

The insulators 212, 216, 271, 275, and 280 preferably include an insulator with a low relative permittivity. For example, the insulators 212, 216, 271, 275, and 280 preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, each of the insulators 212, 216, 271, 275, and 280 preferably has a stacked-layer structure of a resin and one of the following materials: silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide. When silicon oxide or silicon oxynitride, which is thermally stable, is combined with resin, the stacked-layer structure can have thermal stability and low relative permittivity. Examples of the resin include polyester, polyolefin, polyamide (e.g., nylon or aramid), polyimide, polycarbonate, and acrylic.

As the insulators 210, 214, 270, and 273, an insulator having a function of inhibiting the penetration of impurities such as hydrogen and oxygen may be used. For the insulators 210, 214, 270, and 273, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example.

<<Conductor>> The conductors can be formed using a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

A stack of a plurality of conductive layers formed with the above materials may be used. For example, a stacked-layer structure formed using a combination of a material containing any of the metal elements listed above and a conductive material containing oxygen may be used. Alternatively, a stacked-layer structure formed using a combination of a material containing any of the metal elements listed above and a conductive material containing nitrogen may be used. Alternatively, a stacked-layer structure formed using a combination of a material containing any of the metal elements listed above, a conductive material containing oxygen, and a conductive material containing nitrogen may be used.

When oxide is used for the channel formation region of the transistor, a stacked-layer structure formed using a material containing the above-described metal element and a conductive material containing oxygen is preferably used for the conductor functioning as the gate electrode. In this case, the conductive material containing oxygen is preferably formed on the channel formation region side. In that case, the conductive material containing oxygen is preferably provided on the channel formation region side so that oxygen released from the conductive material is easily supplied to the channel formation region.

It is particularly preferable to use, for the conductor functioning as the gate electrode, a conductive material containing oxygen and a metal element contained in a metal oxide in which a channel is formed. A conductive material containing the above metal element and nitrogen may be used. For example, a conductive material containing nitrogen such as titanium nitride or tantalum nitride may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide in which a channel is formed can be captured in some cases. Alternatively, hydrogen entering from an external insulator or the like can be captured in some cases.

The conductors 260, 203, 205, and 240 can be each formed using a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

<<Metal oxide>> The oxide 230 is preferably formed using a metal oxide functioning as an oxide semiconductor (hereinafter, the metal oxide is also referred to as an oxide semiconductor). A metal oxide that can be used for the oxide 230 of one embodiment of the present invention will be described below.

The metal oxide preferably contains at least indium or zinc. In particular, indium and zinc are preferably contained. In addition, aluminum, gallium, yttrium, tin, or the like is preferably contained. Furthermore, one or more elements selected from boron, titanium, iron, nickel, germanium, zirconium, molybdenum, lanthanum, cerium, neodymium, hafnium, tantalum, tungsten, magnesium, or the like may be contained.

Here, the case where the metal oxide is an In-M-Zn oxide that contains indium, an element M, and zinc is considered. The element M is aluminum, gallium, yttrium, tin, or the like. Other elements that can be used as the element M include boron, titanium, iron, nickel, germanium, zirconium, molybdenum, lanthanum, cerium, neodymium, hafnium, tantalum, tungsten, and magnesium. Note that two or more of the above elements may be used in combination as the element M.

Note that in this specification and the like, a metal oxide containing nitrogen is also called a metal oxide in some cases. Moreover, a metal oxide containing nitrogen may be called a metal oxynitride.

[Composition of metal oxide] Described below is the composition of a cloud-aligned composite oxide semiconductor (CAC-OS) applicable to a transistor disclosed in one embodiment of the present invention.

In this specification and the like, “c-axis aligned crystal (CAAC)” or “cloud-aligned composite (CAC)” might be stated. Note that CAAC refers to an example of a crystal structure, and CAC refers to an example of a function or a material composition.

A CAC-OS or a CAC metal oxide has a conducting function in a part of the material and has an insulating function in another part of the material; as a whole, the CAC-OS or the CAC metal oxide has a function of a semiconductor. In the case where the CAC-OS or the CAC metal oxide is used in an active layer of a transistor, the conducting function is to allow electrons (or holes) functioning as carriers to flow, and the insulating function is to not allow electrons functioning as carriers to flow. By the complementary action of the conducting function and the insulating function, the CAC-OS or the CAC metal oxide can have a switching function (on/off function). In the CAC-OS or the CAC metal oxide, separation of the functions can maximize each function.

The CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC metal oxide, the conductive regions and the insulating regions each have a size greater than or equal to 0.5 nm and less than or equal to 10 nm, preferably greater than or equal to 0.5 nm and less than or equal to 3 nm and are dispersed in the material, in some cases.

The CAC-OS or the CAC metal oxide includes components having different bandgaps. For example, the CAC-OS or the CAC metal oxide contains a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel formation region of a transistor, high current drive capability in the on state of the transistor, that is, a high on-state current and high field-effect mobility, can be obtained.

In other words, the CAC-OS or the CAC metal oxide can be called a matrix composite or a metal matrix composite.

[Structure of metal oxide] An oxide semiconductor (metal oxide) is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

The CAAC-OS has c-axis alignment, its nanocrystals are connected in the a-b plane direction, and its crystal structure has distortion. Note that distortion refers to a portion where the direction of a lattice arrangement changes between a region with a uniform lattice arrangement and another region with a uniform lattice arrangement in a region where the nanocrystals are connected.

The shape of the nanocrystal is basically a hexagon but is not always a regular hexagon and is a non-regular hexagon in some cases. A pentagonal lattice arrangement, a heptagonal lattice arrangement, and the like are included in the distortion in some cases. Note that it is difficult to observe a clear crystal grain boundary even in the vicinity of distortion in the CAAC-OS. That is, a lattice arrangement is distorted and thus formation of a grain boundary is inhibited. This is because the CAAC-OS can tolerate distortion owing to a low density of oxygen atom arrangement in the a-b plane direction, a change in interatomic bond distance by substitution of a metal element, and the like.

The CAAC-OS tends to have a layered crystal structure (also referred to as a stacked-layer structure) in which a layer containing indium and oxygen (hereinafter, In layer) and a layer containing the element M, zinc, and oxygen (hereinafter, (M, Zn) layer) are stacked. Note that indium and the element M can be replaced with each other, and when the element M of the (M, Zn) layer is replaced by indium, the layer can also be referred to as an (In, M, Zn) layer. When indium of the In layer is replaced by the element M, the layer can also be referred to as an (In, M) layer.

The CAAC-OS is a metal oxide with high crystallinity. By contrast, in the CAAC-OS, a reduction in electron mobility due to the grain boundary is less likely to occur because it is difficult to observe a clear grain boundary. Entry of impurities, formation of defects, or the like might decrease the crystallinity of a metal oxide. This means that the CAAC-OS has small amounts of impurities and defects (e.g., oxygen vacancies). Thus, a metal oxide containing a CAAC-OS is physically stable. Therefore, the metal oxide containing a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different nanocrystals in the nc-OS. Thus, the orientation of the whole film is not observed. Accordingly, in some cases, the nc-OS cannot be distinguished from an a-like OS or an amorphous oxide semiconductor, depending on an analysis method.

The a-like OS is a metal oxide having a structure between those of the nc-OS and the amorphous oxide semiconductor. The a-like OS has a void or a low-density region. That is, the a-like OS has low crystallinity as compared with the nc-OS and the CAAC-OS.

An oxide semiconductor (metal oxide) can have any of various structures which show various different properties. Two or more of the amorphous oxide semiconductor, the polycrystalline oxide semiconductor, the a-like OS, the nc-OS, and the CAAC-OS may be included in an oxide semiconductor of one embodiment of the present invention.

[Transistor including metal oxide] Next, the case where the metal oxide is used for a channel formation region of a transistor will be described.

When the metal oxide is used for a channel formation region of a transistor, the transistor can have high field-effect mobility. In addition, the transistor can have high reliability.

Moreover, a metal oxide with low carrier density is preferably used for the transistor. In order to reduce the carrier density of the metal oxide film, the concentration of impurities in the metal oxide film is reduced so that the density of defect states can be reduced. In this specification and the like, a state with a low impurity concentration and a low density of defect states is referred to as a highly purified intrinsic or substantially highly purified intrinsic state. The metal oxide has, for example, a carrier density lower than 8×10¹¹/cm³, preferably lower than 1×10¹¹/cm³, and further preferably lower than 1×10¹⁰/cm³, and higher than or equal to 1×10⁻⁹/cm³.

A highly purified intrinsic or substantially highly purified intrinsic metal oxide film has a low density of defect states and accordingly has a low density of trap states in some cases.

Charges trapped by the trap states in the metal oxide take a long time to be released and may behave like fixed charges. Thus, a transistor whose channel formation region is formed in a metal oxide having a high density of trap states has unstable electrical characteristics in some cases.

In order to obtain stable electrical characteristics of the transistor, it is effective to reduce the concentration of impurities in the metal oxide. In addition, in order to reduce the concentration of impurities in the metal oxide, the concentration of impurities in a film that is adjacent to the metal oxide is preferably reduced. As examples of the impurities, hydrogen, nitrogen, alkali metal, alkaline earth metal, iron, nickel, silicon, and the like are given.

[Impurity] Here, the influence of impurities in the metal oxide is described.

When silicon or carbon that is one of Group 14 elements is contained in the metal oxide, defect states are formed. Thus, the concentration of silicon or carbon (the concentration is measured by SIMS) in the metal oxide and the concentration of silicon or carbon in the vicinity of an interface with the metal oxide (the concentration is measured by secondary ion mass spectrometry, SIMS) is set to be lower than or equal to 2×10¹⁸ atoms/cm³, preferably lower than or equal to 2×10¹⁷ atoms/cm³.

When the metal oxide contains an alkali metal or an alkaline earth metal, defect states are formed and carriers are generated, in some cases. Thus, a transistor including a metal oxide that contains an alkali metal or an alkaline earth metal for a channel formation region is likely to be a normally-on transistor. Therefore, it is preferable to reduce the concentration of an alkali metal or an alkaline earth metal in the metal oxide. Specifically, the concentration of alkali metal or alkaline earth metal in the metal oxide, which is measured by SIMS, is lower than or equal to 1×10¹⁸ atoms/cm³, preferably lower than or equal to 2×10¹⁶ atoms/cm³.

When the metal oxide contains nitrogen, the metal oxide easily becomes n-type by generation of electrons functioning as carriers and an increase of carrier density. Thus, a transistor whose channel formation region includes a metal oxide that contains nitrogen is likely to be a normally-on transistor. For this reason, nitrogen in the metal oxide is preferably reduced as much as possible; for example, the concentration of nitrogen in the metal oxide measured by SIMS is set to lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in a metal oxide reacts with oxygen bonded to a metal atom to be water, and thus causes an oxygen vacancy, in some cases. Entry of hydrogen into the oxygen vacancy generates an electron functioning as a carrier in some cases. Furthermore, in some cases, bonding of part of hydrogen to oxygen bonded to a metal atom causes generation of an electron functioning as a carrier. Thus, a transistor including a metal oxide that contains hydrogen for a channel formation region is likely to be normally-on. For this reason, hydrogen in the metal oxide is preferably reduced as much as possible. Specifically, the hydrogen concentration of the metal oxide measured by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

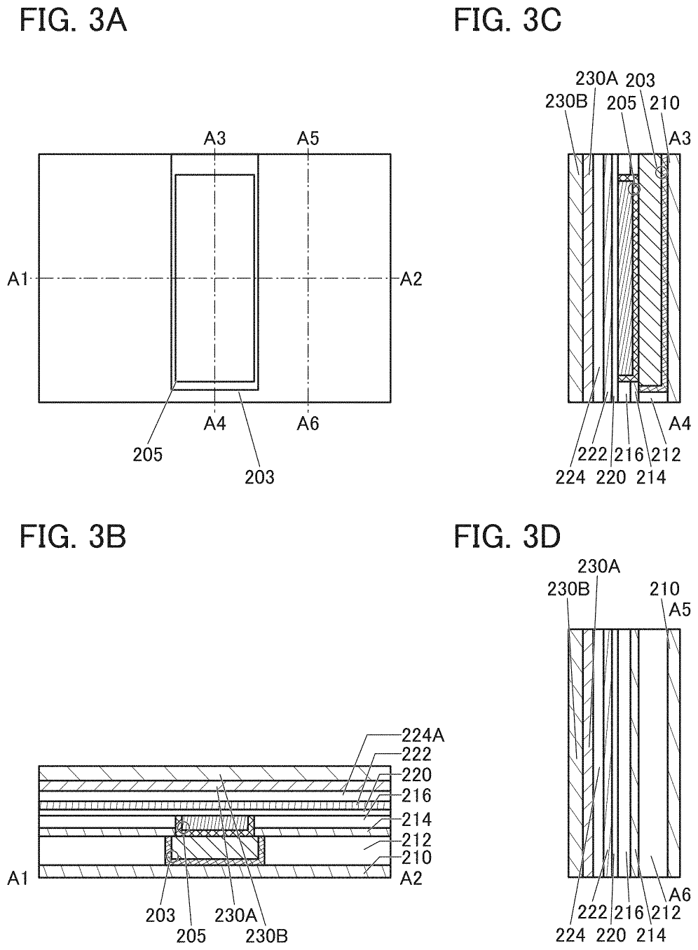

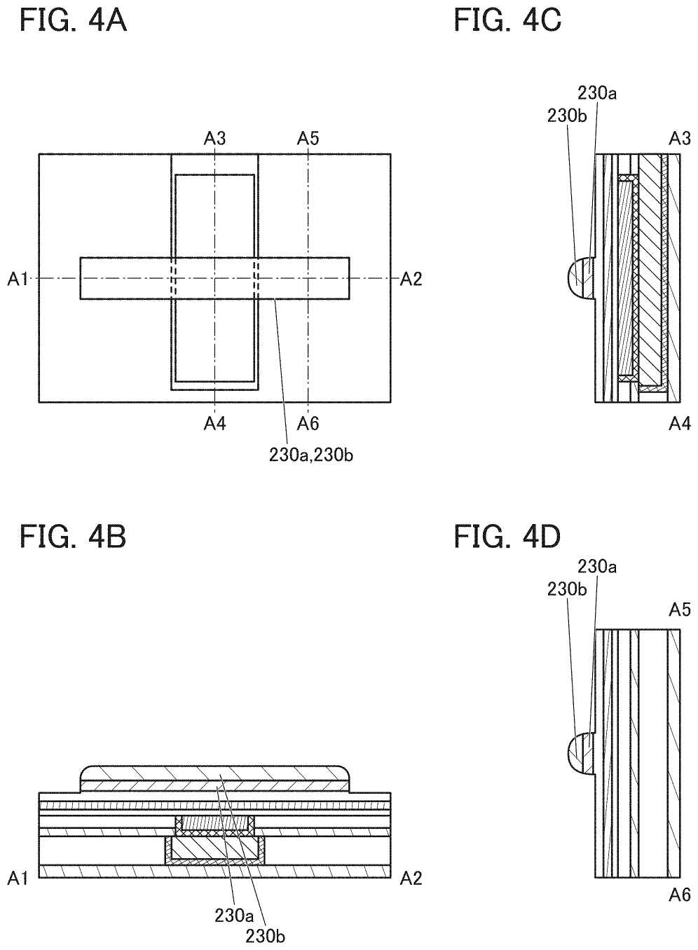

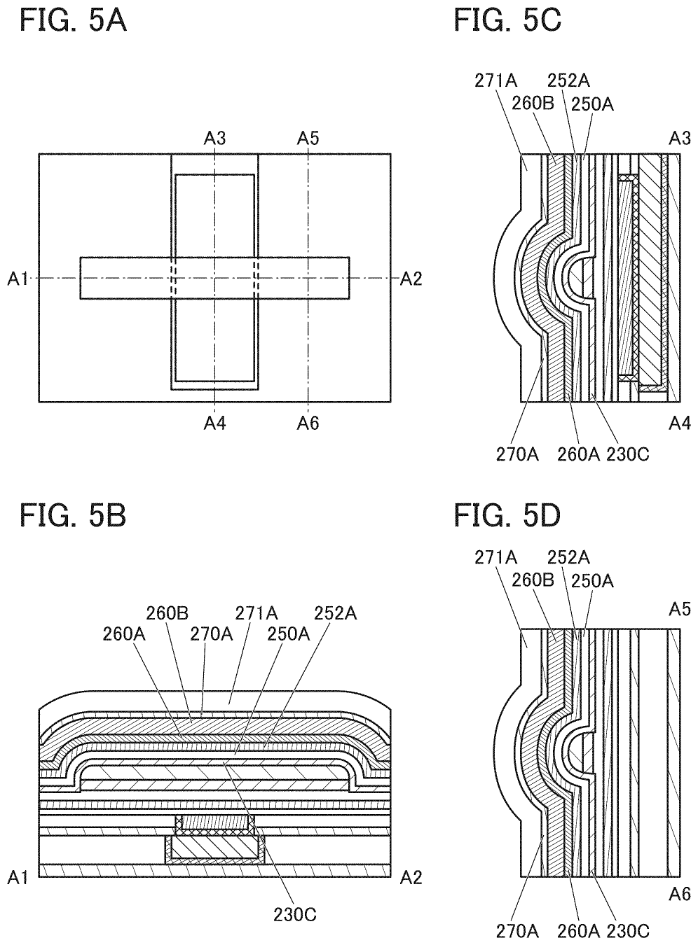

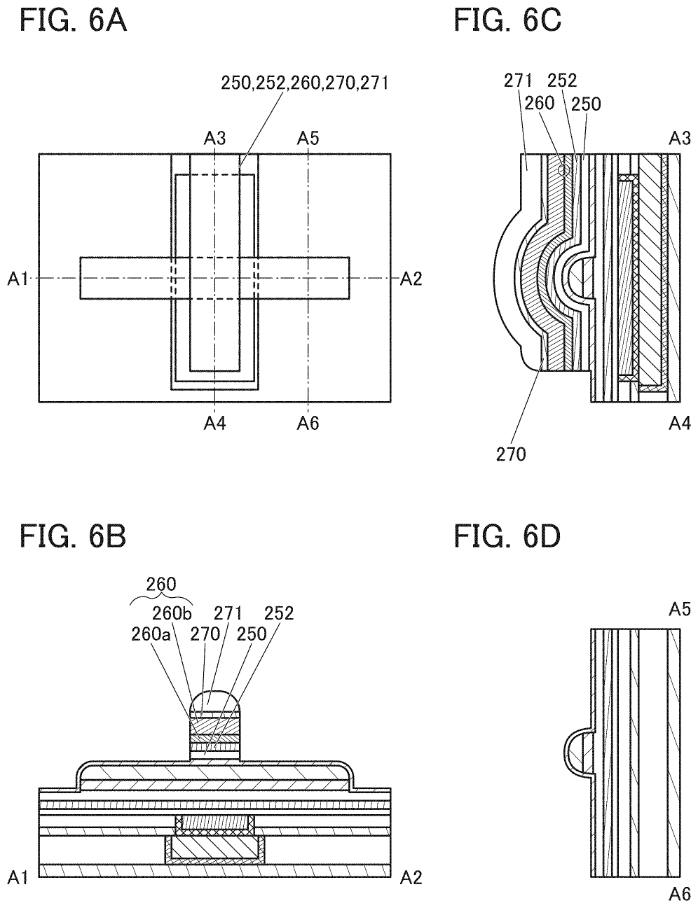

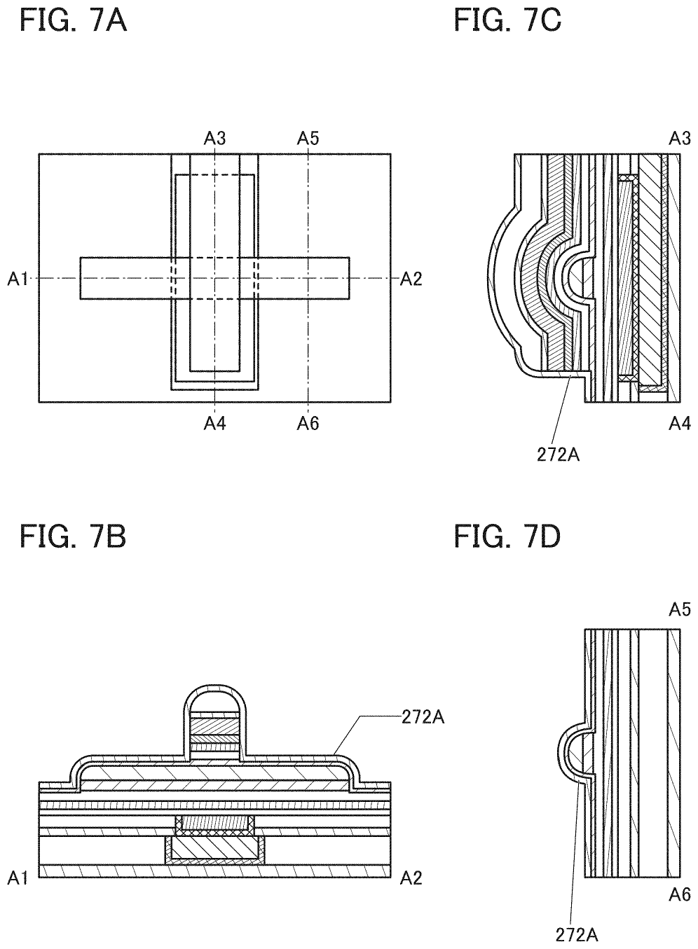

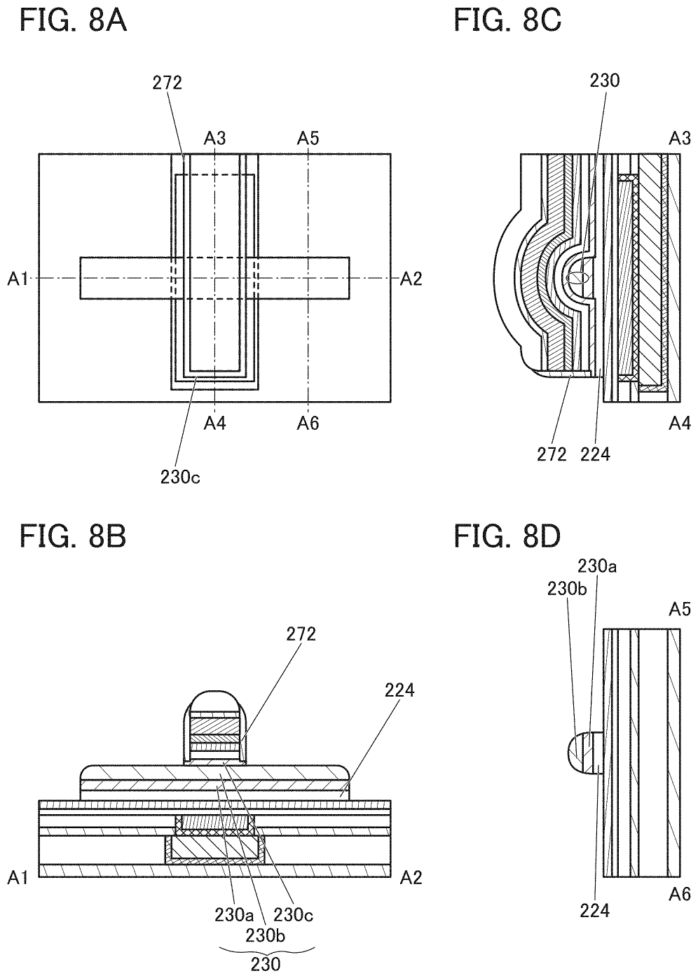

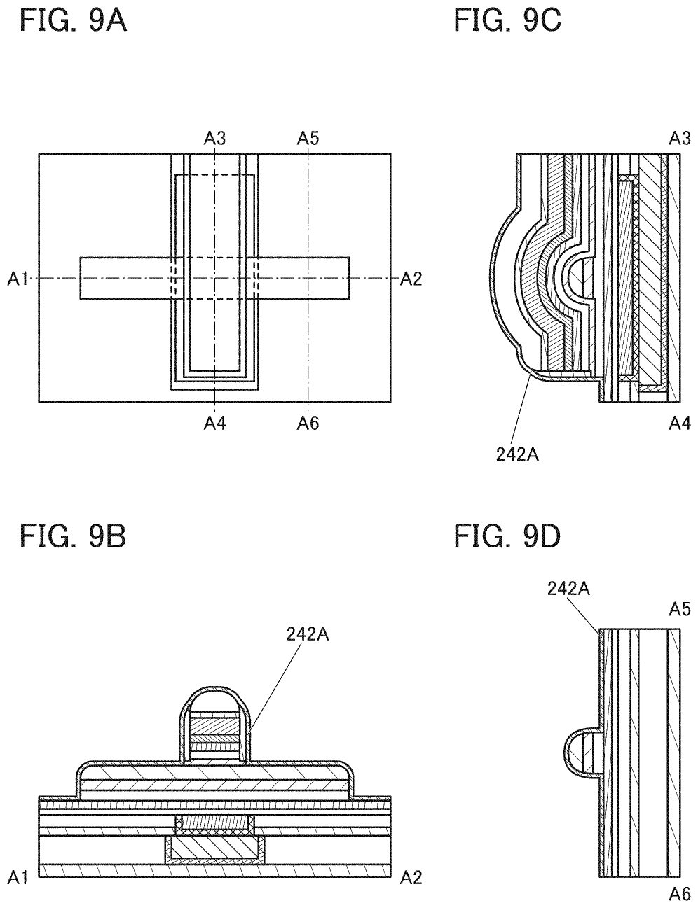

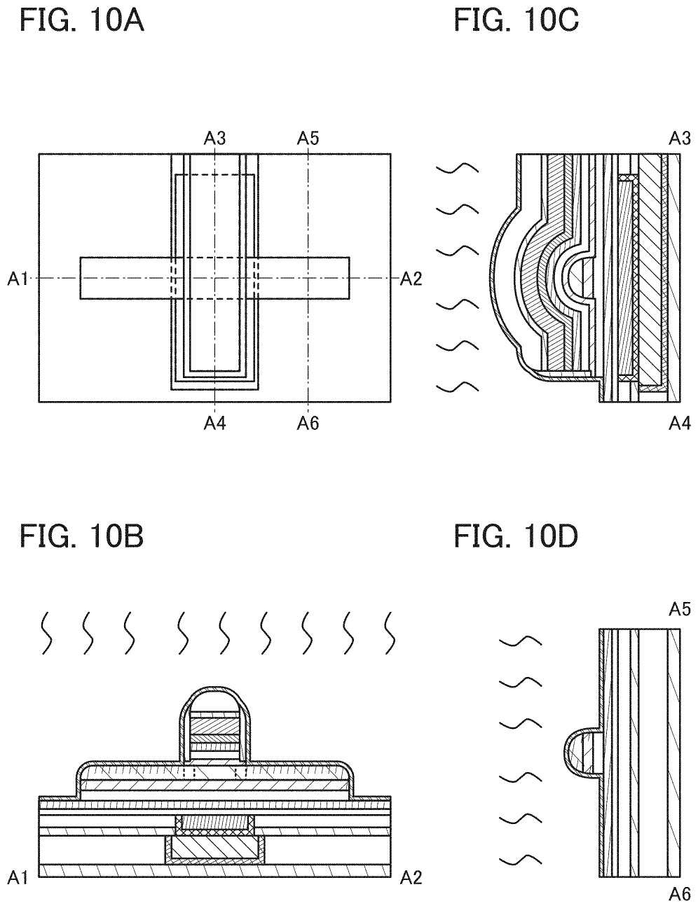

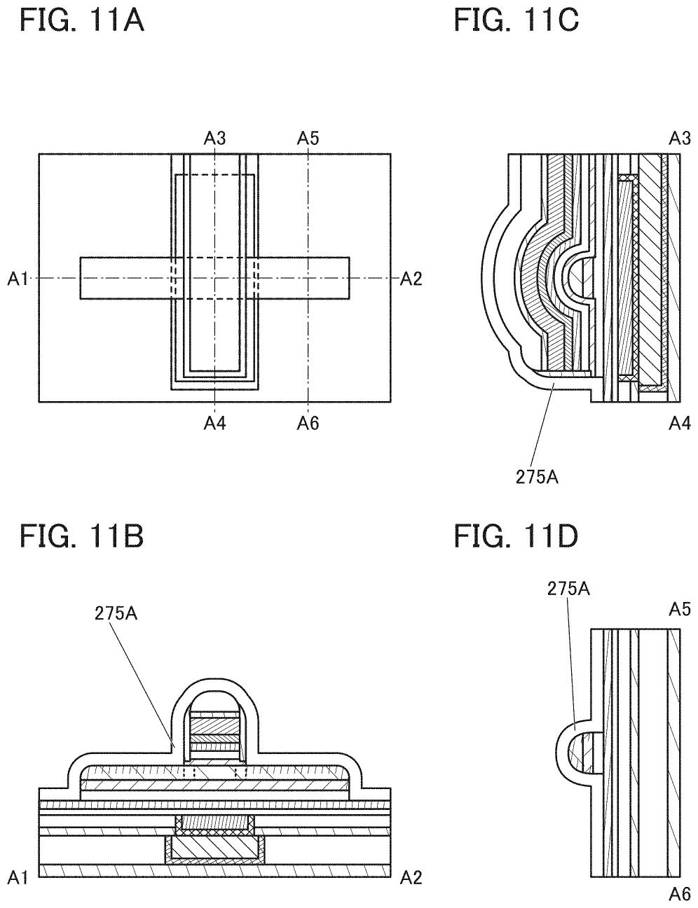

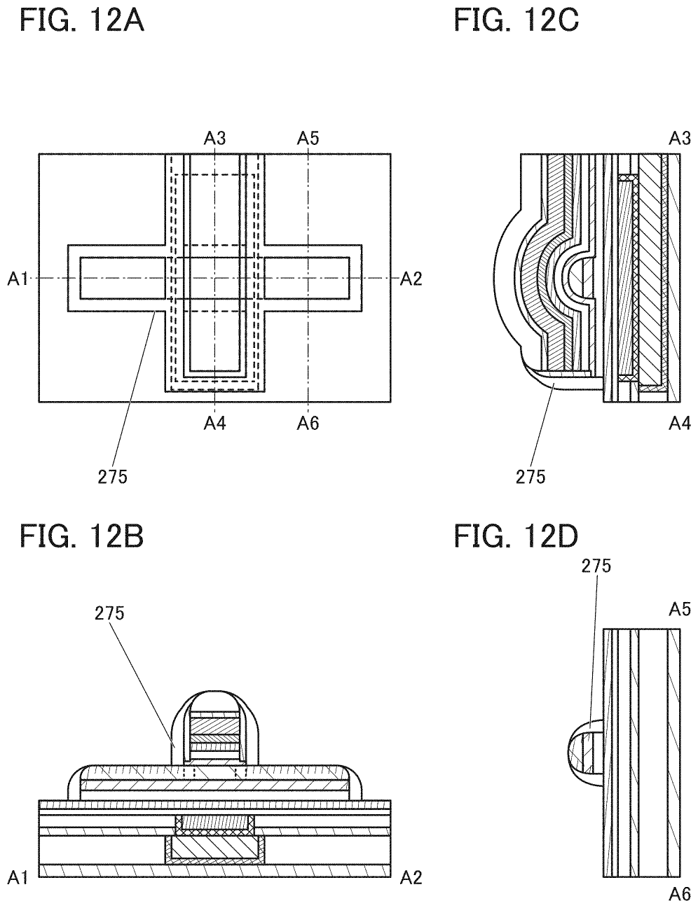

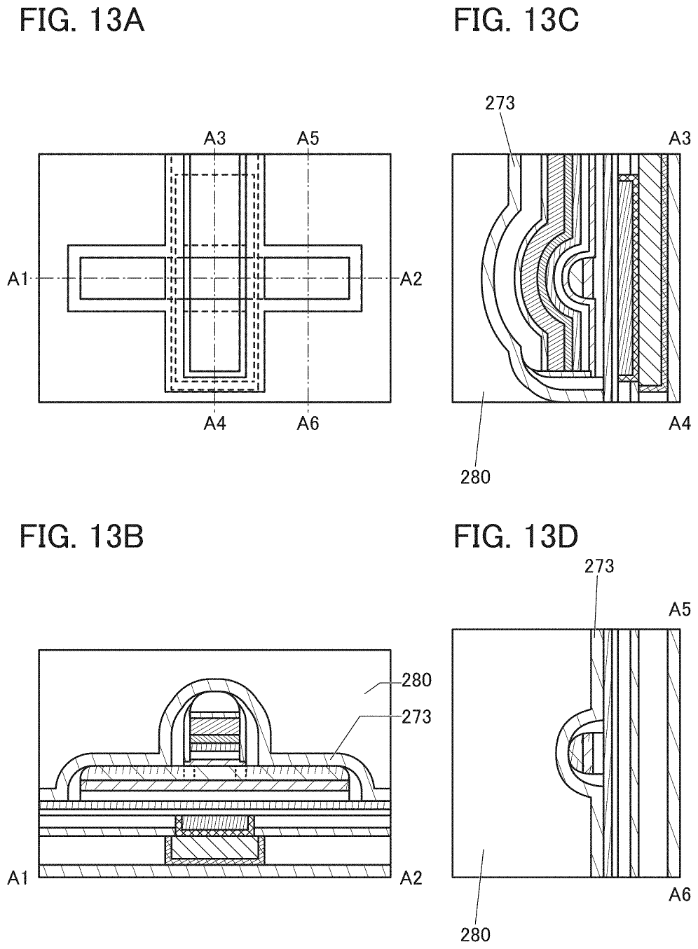

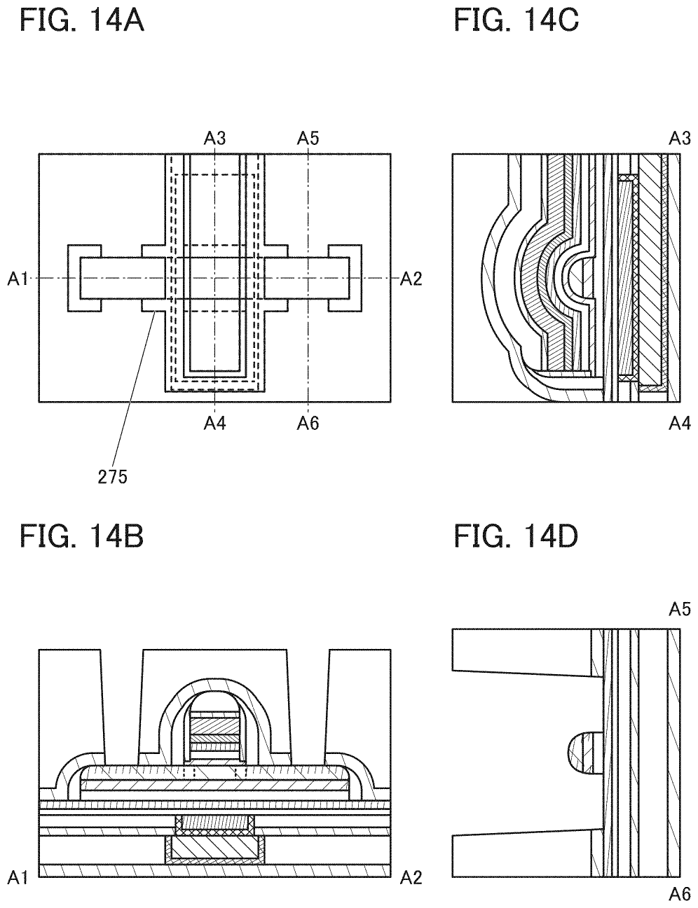

When a metal oxide with sufficiently reduced impurity concentration is used for a channel formation region in a transistor, the transistor can have stable electrical characteristics.

<Method for manufacturing semiconductor device> Next, a method for manufacturing a semiconductor device including the transistor 200 of the present invention will be described with reference to FIGS. 3A to 3D to FIGS. 14A to 14D. FIG. 3A, FIG. 4A, FIG. 5A, FIG. 6A, FIG. 7A, FIG. 8A, FIG. 9A, FIG. 10A, FIG. 11A, FIG. 12A, FIG. 13A, and FIG. 14A are top views. FIG. 3B, FIG. 4B, FIG. 5B, FIG. 6B, FIG. 7B, FIG. 8B, FIG. 9B, FIG. 10B, FIG. 11B, FIG. 12B, FIG. 13B, and FIG. 14B are cross-sectional views taken along dashed-dotted lines A1-A2 in FIG. 3A, FIG. 4A, FIG. 5A, FIG. 6A, FIG. 7A, FIG. 8A, FIG. 9A, FIG. 10A, FIG. 11A, FIG. 12A, FIG. 13A, and FIG. 14A, which correspond to cross-sectional views in the channel length direction of the transistor 200. FIG. 3C, FIG. 4C, FIG. 5C, FIG. 6C, FIG. 7C, FIG. 8C, FIG. 9C, FIG. 10C, FIG. 11C, FIG. 12C, FIG. 13C, and FIG. 14C are cross-sectional views taken along dashed-dotted lines A3-A4 in FIG. 3A, FIG. 4A, FIG. 5A, FIG. 6A, FIG. 7A, FIG. 8A, FIG. 9A, FIG. 10A, FIG. 11A, FIG. 12A, FIG. 13A, and FIG. 14A, which correspond to cross-sectional views in the channel width direction of the transistor 200. FIG. 3D, FIG. 4D, FIG. 5D, FIG. 6D, FIG. 7D, FIG. 8D, FIG. 9D, FIG. 10D, FIG. 11D, FIG. 12D, FIG. 13D, and FIG. 14D are cross-sectional views taken along dashed-dotted lines A5-A6 in FIG. 3A, FIG. 4A, FIG. 5A, FIG. 6A, FIG. 7A, FIG. 8A, FIG. 9A, FIG. 10A, FIG. 11A, FIG. 12A, FIG. 13A, and FIG. 14A, which correspond to cross-sectional views of a source region or a drain region of the transistor 200. Note that in the top views in FIG. 3A, FIG. 4A, FIG. 5A, FIG. 6A, FIG. 7A, FIG. 8A, FIG. 9A, FIG. 10A, FIG. 11A, FIG. 12A, FIG. 13A, and FIG. 14A, some components are not illustrated for simplification of the drawings.

First, a substrate (not illustrated) is prepared, and the insulator 210 is formed over the substrate. The insulator 210 can be formed by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

The use of a PECVD method can provide a high-quality film at a relatively low temperature. Furthermore, a thermal CVD method does not use plasma and thus causes less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, when a thermal CVD method not using plasma is employed, such plasma damage is not caused and the yield of the semiconductor device can be increased. A thermal CVD method does not cause plasma damage during deposition, so that a film with few defects can be obtained.

An ALD method also causes less plasma damage to an object. An ALD method does not cause plasma damage during deposition, so that a film with few defects can be obtained. Note that a precursor used in the ALD method sometimes contains impurities such as carbon. Thus, a film formed by the ALD method may contain impurities such as carbon in a larger amount than a film formed by another deposition method. Note that impurities can be quantified by X-ray photoelectron spectroscopy (XPS).

Unlike in a deposition method in which particles ejected from a target or the like are deposited, in a CVD method and an ALD method, a film is formed by reaction at a surface of an object. Thus, a CVD method and an ALD method enable favorable step coverage almost regardless of the shape of an object. In particular, an ALD method enables excellent step coverage and excellent thickness uniformity and can be favorably used for covering a surface of an opening with a high aspect ratio, for example. On the other hand, an ALD method has a relatively low deposition rate; thus, it is sometimes preferable to combine an ALD method with another deposition method with a high deposition rate such as a CVD method.

When a CVD method or an ALD method is used, composition of a film to be formed can be controlled with a flow rate ratio of the source gases. For example, by a CVD method or an ALD method, a film with a certain composition can be formed depending on a flow rate ratio of the source gases. Moreover, with a CVD method or an ALD method, by changing the flow rate ratio of the source gases while forming the film, a film whose composition is continuously changed can be formed. In the case where the film is formed while changing the flow rate ratio of the source gases, as compared to the case where the film is formed using a plurality of deposition chambers, time taken for the film formation can be reduced because time taken for transfer and pressure adjustment is omitted. Thus, semiconductor devices can be manufactured with improved productivity in some cases.

In this embodiment, aluminum oxide is formed as the insulator 210 by a sputtering method. The insulator 210 may have a multilayer structure. For example, the multilayer structure may be formed in such a manner that an aluminum oxide is formed by a sputtering method and an aluminum oxide is formed over the aluminum oxide by an ALD method. Alternatively, the multilayer structure may be formed in such a manner that an aluminum oxide is formed by an ALD method and an aluminum oxide is formed over the aluminum oxide by a sputtering method.

Then, the insulator 212 is formed over the insulator 210. The insulator 212 can be formed by a sputtering method, a CVD method, an MBE method, a PLD method, an ALD method, or the like. In this embodiment, as the insulator 212, silicon oxide is formed by a CVD method.

Then, openings are formed in the insulator 212 to reach the insulator 210. Examples of the openings include grooves and slits. A region where the opening is formed may be referred to as an opening portion. The opening can be formed by a wet etching method; however, a dry etching method is suitable for microfabrication. The insulator 210 is preferably an insulator that serves as an etching stopper film used in forming the opening by etching the insulator 212. For example, in the case where a silicon oxide film is used for the insulator 212 in which the opening is to be formed, the insulator 210 is preferably formed using a silicon nitride film, an aluminum oxide film, or a hafnium oxide film. The insulator 210 formed using a film whose etching rate is different from that of the silicon oxide film can be used as an etching stopper film.

After the formation of the openings, a conductive film to be the first conductor of the conductor 203 is formed. The conductive film preferably includes a conductor that has a function of inhibiting the penetration of oxygen. For example, tantalum nitride, tungsten nitride, or titanium nitride can be used. Alternatively, a stacked-layer film formed using the conductor and tantalum, tungsten, titanium, molybdenum, aluminum, copper, or a molybdenum-tungsten alloy can be used. The conductive film to be the first conductor of the conductor 203 can be formed by a sputtering method, a CVD method, an MBE method, a PLD method, an ALD method, or the like.

In this embodiment, as the conductive film to be the first conductor of the conductor 203, tantalum nitride or a stacked film of tantalum nitride and titanium nitride formed over the tantalum nitride is formed by a sputtering method. Even when a metal that is easily diffused, such as copper, is used for the second conductor of the conductor 203 to be described later, the use of such a metal nitride as the first conductor of the conductor 203 can inhibit diffusion of the metal to the outside of the first conductor of the conductor 203.

Next, a conductive film to be the second conductor of the conductor 203 is formed over the conductive film to be the first conductor of the conductor 203. The conductive film can be formed by a sputtering method, a CVD method, an MBE method, a PLD method, an ALD method, or the like. In this embodiment, as the conductive film to be the second conductor of the conductor 203, a low-resistant conductive material such as copper is formed.

Next, by CMP treatment, the conductive film to be the first conductor of the conductor 203 and the conductive film to be the second conductor of the conductor 203 are partly removed to expose the insulator 212. As a result, the conductive film to be the first conductor of the conductor 203 and the conductive film to be the second conductor of the conductor 203 remain only in the openings. Thus, the conductor 203 including the first and second conductors, which has a flat top surface, can be formed (see FIGS. 3A to 3D). Note that the insulator 212 is partly removed by the CMP treatment in some cases.

Next, the insulator 214 is formed over the insulator 212 and the conductor 203. The insulator 214 can be formed by a sputtering method, a CVD method, an MBE method, a PLD method, an ALD method, or the like. In this embodiment, as the insulator 214, silicon nitride is formed by a CVD method. Even when metal that is likely to be diffused, such as copper, is used for the second conductor of the conductor 203, the use of an insulator through which copper is less likely to pass, such as silicon nitride, as the insulator 214 can inhibit diffusion of the metal into the layers above the insulator 214.

Next, the insulator 216 is formed over the insulator 214. The insulator 216 can be formed by a sputtering method, a CVD method, an MBE method, a PLD method, an ALD method, or the like. In this embodiment, silicon oxide is formed as the insulator 216 by a CVD method.

Next, an opening reaching the conductor 203 is formed in the insulators 214 and 216. The opening can be formed by a wet etching method; however, a dry etching method is suitable for microfabrication.

After the formation of the opening, a conductive film to be the first conductor of the conductor 205 is formed. The conductive film to be the first conductor of the conductor 205 preferably includes a conductive material having a function of inhibiting the penetration of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductive film to be the first conductor of the conductor 205 can be formed by a sputtering method, a CVD method, an MBE method, a PLD method, an ALD method, or the like.

In this embodiment, tantalum nitride is formed as a conductive film to be the first conductor of the conductor 205 by a sputtering method.

Next, a conductive film to be the second conductor of the conductor 205 is formed over the conductive film to be the first conductor of the conductor 205. The conductive film can be formed by a sputtering method, a CVD method, an MBE method, a PLD method, an ALD method, or the like.

In this embodiment, as the conductive film to be the second conductor of the conductor 205, titanium nitride is formed by a CVD method and tungsten is formed by a CVD method over the titanium nitride.

Next, by CMP treatment, the conductive film to be the first conductor of the conductor 205 and the conductive film to be the second conductor of the conductor 205 are partly removed to expose the insulator 216. As a result, the conductive film to be the first conductor of the conductor 205 and the conductive film to be the second conductor of the conductor 205 remain only in the opening. Thus, the conductor 205 including the first and second conductors, which has a flat top surface, can be formed (see FIGS. 3A to 3D). Note that the insulator 216 is partly removed by the CMP treatment in some cases.

Next, the insulator 220 is formed over the insulator 216 and the conductor 205. The insulator 220 can be formed by a sputtering method, a CVD method, an MBE method, a PLD method, an ALD method, or the like. In this embodiment, as the insulator 220, silicon oxide is formed by a CVD method.

Then, the insulator 222 is formed over the insulator 220. An insulator containing an oxide of one or both of aluminum and hafnium is preferably formed as the insulator 222. As the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, diffusion of hydrogen and water contained in a structure body provided around the transistor 200 into the transistor 200 through the insulator 222 is inhibited, and generation of an oxygen vacancy in the oxide 230 can be inhibited.

The insulator 222 can be formed by a sputtering method, a CVD method, an MBE method, a PLD method, an ALD method, or the like.

Then, an insulating film 224A is formed over the insulator 222. The insulating film 224A can be formed by a sputtering method, a CVD method, an MBE method, a PLD method, an ALD method, or the like (see FIGS. 3A to 3D). In this embodiment, as the insulating film 224A, silicon oxide is formed by a CVD method.

Subsequently, heat treatment is preferably performed. The heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The heat treatment is performed in a nitrogen atmosphere, an inert gas atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

In this embodiment, heat treatment is performed in a nitrogen atmosphere at 400° C. for one hour after the formation of the insulating film 224A. By the above heat treatment, impurities such as water or hydrogen included in the insulating film 224A can be removed, for example.

This heat treatment can also be performed after the formation of the insulator 220 and after the formation of the insulator 222. Although the heat treatment can be performed under the above-described conditions for the heat treatment, heat treatment after the formation of the insulator 220 is preferably performed in an atmosphere containing nitrogen.

Here, in order to form an excess-oxygen region in the insulating film 224A, plasma treatment using oxygen may be performed under a reduced pressure. The plasma treatment using oxygen is preferably performed using an apparatus including a power source for generating high-density plasma using microwaves, for example. Alternatively, a power source for applying a radio frequency (RF) to a substrate side may be provided. The use of high-density plasma enables high-density oxygen radicals to be produced, and application of the RF to the substrate side allows oxygen radicals generated by the high-density plasma to be efficiently introduced into the insulating film 224A. Alternatively, after plasma treatment using an inert gas with the apparatus, plasma treatment using oxygen in order to compensate for released oxygen may be performed. Note that impurities such as water or hydrogen included in the insulating film 224A can be removed by selecting the conditions of the plasma treatment appropriately. In this case, the heat treatment is unnecessary.

Next, an oxide film 230A to be the oxide 230a, and an oxide film 230B to be the oxide 230b are sequentially formed over the insulating film 224A (see FIGS. 3A to 3D). Note that the oxide films are preferably formed successively without exposure to the air. When the oxide films are formed without exposure to the air, impurities or moisture from the air can be prevented from being attached to the oxide films 230A and 230B, so that an interface between the oxide films 230A and 230B and the vicinity of the interface can be kept clean.

The oxide films 230A and 230B can be formed by a sputtering method, a CVD method, an MBE method, a PLD method, an ALD method, or the like.

In the case where the oxide films 230A and 230B are formed by a sputtering method, for example, oxygen or a mixed gas of oxygen and a rare gas is used as a sputtering gas. By increasing the proportion of oxygen in the sputtering gas, the amount of excess oxygen in the oxide films to be formed can be increased. In the case where the above oxide films are formed by a sputtering method, the above In-M-Zn oxide target can be used.

In particular, when the oxide film 230A is formed, part of oxygen contained in the sputtering gas is supplied to the insulating film 224A in some cases. Therefore, the proportion of oxygen in the sputtering gas for formation of the oxide film 230A is preferably 70% or higher, further preferably 80% or higher, and still further preferably 100%.

In the case where the oxide film 230B is formed by a sputtering method, when the proportion of oxygen in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in a channel formation region can have relatively high field-effect mobility.

In this embodiment, the oxide film 230A is formed using a target with an atomic ratio of In:Ga:Zn=1:3:4 by a sputtering method. The oxide film 230B is formed using a target with an atomic ratio of In:Ga:Zn=4:2:4.1 by a sputtering method. Note that each of the oxide films is preferably formed by appropriate selection of film formation conditions and an atomic ratio to have characteristics required for the oxide 230.

Next, heat treatment may be performed. For the heat treatment, the conditions for the heat treatment can be used. By the heat treatment, impurities such as water or hydrogen contained in the oxide films 230A and 230B can be removed, for example In this embodiment, treatment is performed in a nitrogen atmosphere at 400° C. for one hour, and successively another treatment is performed in an oxygen atmosphere at 400° C. for one hour.

Next, the oxide film 230A and the oxide film 230B are processed into island shapes to form the oxide 230a and the oxide 230b (see FIGS. 4A to 4D).

The oxide 230a and the oxide 230b are formed to at least partly overlap with the conductor 205. It is preferable that the side surfaces of the oxides 230a and 230b be substantially perpendicular to the top surface of the insulator 222, in which case a smaller area and higher density are achieved when the plurality of transistors 200 is provided. Note that an angle formed by the side surfaces of the oxides 230a and 230b and the top surface of the insulator 222 may be an acute angle. In that case, the angle formed by the side surfaces of the oxides 230a and 230b and the top surface of the insulator 222 is preferably larger.

The oxide 230b has a curved surface between the side surfaces of the oxides 230a and 230b and the top surface. That is, an end portion of the side surface and an end portion of the top surface are preferably curved (hereinafter such a curved shape is also referred to as a rounded shape). A radius of curvature of the curved surface at the end portion of the oxide 230b is greater than or equal to 3 nm and less than or equal to 10 nm, preferably greater than or equal to 5 nm and less than or equal to 6 nm. When the end portions are not angular, the coverage with films formed later in the film formation process can be improved.

Note that the oxide films may be processed by a lithography method. The processing can be performed by a dry etching method or a wet etching method. A dry etching method is suitable for microfabrication.

In the lithography method, first, a resist is exposed to light through a mask. Next, a region exposed to light is removed or left using a developing solution, so that a resist mask is formed. Then, etching through the resist mask is conducted. As a result, a conductor, a semiconductor, an insulator, or the like can be processed in to a desired shape. The resist mask is formed by, for example, exposure of the resist to light using KrF excimer laser light, ArF excimer laser light, extreme ultraviolet (EUV) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a mask for the exposure of the resist to light is unnecessary in the case of using an electron beam or an ion beam because direct writing is performed on the resist. To remove the resist mask, dry etching treatment such as ashing or wet etching treatment can be used. Alternatively, wet etching treatment can be performed after dry etching treatment. Further alternatively, dry etching treatment can be performed after wet etching treatment.

A hard mask formed of an insulator or a conductor may be used instead of the resist mask. In the case where a hard mask is used, a hard mask with a desired shape can be formed in the following manner: an insulating film or a conductive film that is the material of the hard mask is formed over the oxide film 230B, a resist mask is formed thereover, and then the material of the hard mask is etched. The etching of the oxide films 230A and 230B may be performed after or without removal of the resist mask. In the latter case, the resist mask may be removed during the etching. The hard mask may be removed by etching after the etching of the oxide films. The hard mask does not need to be removed in the case where the material of the hard mask does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, the capacitively coupled plasma etching apparatus may have a structure in which different high-frequency power sources are applied to one of the parallel plate type electrodes. Alternatively, the capacitively coupled plasma etching apparatus may have a structure in which high-frequency power sources with the same frequency are applied to the parallel plate type electrodes. Alternatively, the capacitively coupled plasma etching apparatus may have a structure in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, the treatment such as dry etching causes the attachment or diffusion of impurities due to an etching gas or the like to a surface or an inside of the oxide 230a, the oxide 230b, or the like. Examples of the impurities include fluorine and chlorine.

In order to remove the impurities, cleaning is performed. As the cleaning, any of wet cleaning using a cleaning solution or the like, plasma treatment using plasma, cleaning by heat treatment, and the like can be performed by itself or in appropriate combination.

The wet cleaning may be performed using an aqueous solution in which oxalic acid, phosphoric acid, hydrofluoric acid, or the like is diluted with carbonated water or pure water. Alternatively, ultrasonic cleaning using pure water or carbonated water may be performed. In this embodiment, ultrasonic cleaning using pure water or carbonated water is performed.

Next, heat treatment may be performed. For the heat treatment, the conditions for the above heat treatment can be used.

Next, an oxide film 230C is formed over the insulating film 224A, the oxide 230a, and the oxide 230b (see FIGS. 5A to 5D).

The oxide film 230C can be formed by a sputtering method, a CVD method, an MBE method, a PLD method, an ALD method, or the like. The oxide film 230C may be formed by a method similar to that of the oxide film 230A or the oxide film 230B in accordance with characteristics required for the oxide 230c. In this embodiment, the oxide film 230C is formed using a target with an atomic ratio of In:Ga:Zn=1:3:4 by a sputtering method.

Then, an insulating film 250A, a metal oxide film 252A, a conductive film 260A, a conductive film 260B, an insulating film 270A, and an insulating film 271A are formed in this order over the oxide film 230C (see FIGS. 5A to 5D).

First, the insulating film 250A is formed. The insulating film 250A can be formed by a sputtering method, a CVD method, an MBE method, a PLD method, an ALD method, or the like. For the insulating film 250A, silicon oxynitride is preferably formed by a CVD method. The film formation temperature of the insulating film 250A is preferably higher than or equal to 350° C. and lower than 450° C., particularly preferably approximately 400° C. When the insulating film 250A is formed at 400° C., an insulator having few impurities can be formed.

Note that oxygen is excited by microwaves to generate high-density oxygen plasma, and the insulating film 250A is exposed to the oxygen plasma, whereby oxygen can be supplied to the insulating film 250A.

Furthermore, heat treatment may be performed. For the heat treatment, the conditions for the above heat treatment can be used. The heat treatment can reduce the moisture concentration and the hydrogen concentration in the insulating film 250A.

Then, the metal oxide film 252A, the conductive film 260A, and the conductive film 260B are formed. As the metal oxide film 252A, an In—Ga—Zn oxide film is formed by a sputtering method. The metal oxide film 252A is preferably formed by a sputtering method in an atmosphere containing an oxygen gas. Formation of the metal oxide film 252A in an atmosphere containing an oxygen gas can form an excess-oxygen region in the insulating film 250A. When excess oxygen added to the insulating film 250A is supplied to the oxide 230, the oxygen vacancy in the oxide 230 can be compensated for.

When the metal oxide film 252A is formed in an oxygen gas atmosphere with a sputtering apparatus, oxygen can be introduced into the insulating films 250A and 224A while the metal oxide film 252A is formed. When an oxide of one or both of aluminum and hafnium that has a barrier property is used for the metal oxide film 252A, excess oxygen introduced into the insulating film 250A can be effectively sealed therein.

The conductive films 260A and 260B can be formed by a sputtering method, a CVD method, an MBE method, a PLD method, an ALD method, or the like. For example, titanium nitride is formed as the conductive film 260A and tungsten is formed as the conductive film 260B.

For example, as the conductive film 260A, a metal nitride film is preferably formed by a sputtering method. In the case where an oxide semiconductor typified by an In-Ga—Zn oxide is used as the metal oxide film 252A, for example, the metal oxide film 252A can have a high carrier density when nitrogen or hydrogen is supplied. In other words, the oxide semiconductor functions as an oxide conductor (0C). By the formation of a metal nitride film by a sputtering method as the conductive film 260A, the resistance of the metal oxide film 252A is reduced by the diffusion of the constituent element (especially, nitrogen) of the metal nitride to the metal oxide film 252A, and the resistance is reduced by damage (e.g., sputtering damage) caused during the formation of the conductive film 260A. Accordingly, the metal oxide film 252A has a higher carrier density and thus has a higher conductivity.

Furthermore, when a low-resistance metal film is stacked as the conductive film 260B, a transistor with a low driving voltage can be provided.

Subsequently, heat treatment can be performed. For the heat treatment, the conditions for the above heat treatment can be used. Note that the heat treatment is unnecessary in some cases. By the heat treatment, excess oxygen is added from the metal oxide film 252A to the insulating film 250A, whereby an excess-oxygen region can be easily formed in the insulating film 250A.

The insulating film 270A can be formed by a sputtering method, a CVD method, an MBE method, a PLD method, an ALD method, or the like. The insulating film 270A, which serves as a barrier film, is formed using an insulating material having a function of inhibiting the penetration of oxygen and impurities such as water or hydrogen. For example, aluminum oxide or hafnium oxide is preferably used. In that case, oxidization of the conductor 260 can be inhibited. This can inhibit entry of impurities such as water or hydrogen into the oxide 230 through the conductor 260 and the insulator 250. In this embodiment, aluminum oxide is formed as the insulating film 270A by an ALD method.

The insulating film 271A can be formed by a sputtering method, a CVD method, an MBE method, a PLD method, an ALD method, or the like. Here, the insulating film 271A is preferably thicker than an insulating film 272A to be formed in a later step. In that case, when the insulator 272 is formed in the following process, the insulator 271 can remain easily over the conductor 260. In this embodiment, as the insulating film 271A, silicon nitride is formed by a CVD method.

Next, the insulating film 271A is etched to form the insulator 271. The insulator 271 functions as a hard mask. Provision of the insulator 271 makes it possible for the side surface of the insulator 250, the side surface of the conductor 260a, the side surface of the conductor 260b, and the side surface of the insulator 270 to be formed substantially perpendicular to the top surface of the substrate.

Then, using the insulator 271 as a mask, the insulating film 250A, the metal oxide film 252A, the conductive film 260A, the conductive film 260B, and the insulating film 270A are etched to form the insulator 250, the metal oxide 252, the conductor 260 (the conductor 260a and the conductor 260b), and the insulator 270 (see FIGS. 6A to 6D).

Note that part of the oxide film 230C may be removed by the etching in a region where the oxide film 230C and the insulator 250 do not overlap with each other. In that case, the oxide film 230C may be thicker in a region overlapping with the insulator 250 than in the region not overlapping with the insulator 250.

The insulator 250, the metal oxide 252, the conductor 260, the insulator 270, and the insulator 271 are formed to at least partly overlap with the conductor 205 and the oxide 230.

The side surface of the insulator 250, the side surface of the metal oxide 252, the side surface of the conductor 260, and the side surface of the insulator 270 preferably form the same surface.

It is preferable that the same surface formed by the side surface of the insulator 250, the side surface of the metal oxide 252, the side surface of the conductor 260, and the side surface of the insulator 270 be substantially perpendicular to the top surface of the substrate. That is, in a cross section, an angle between the top surface of the oxide 230 and the side surfaces of the insulator 250, the metal oxide 252, the conductor 260, and the insulator 270 is preferably an acute angle and larger. Note that in the cross section, the angle formed by the side surfaces of the insulator 250, the metal oxide 252, the conductor 260, and the insulator 270 and the top surface of the oxide 230 may be an acute angle. In that case, the angle formed by the top surface of the oxide 230 and the side surfaces of the insulator 250, the metal oxide 252, the conductor 260, and the insulator 270 is preferably larger.

After the processing, the following process may be performed without removal of the hard mask (the insulator 271).

Next, the insulating film 272A is formed to cover the oxide 230, the insulator 250, the metal oxide 252, the conductor 260, the insulator 270, and the insulator 271 (see FIGS. 7A to 7D). The insulating film 272A can be formed by a sputtering method, a CVD method, an MBE method, a PLD method, an ALD method, or the like.

The insulating film 272A is preferably formed by an ALD method, which enables good coverage. By using an ALD method, the insulating film 272A having a uniform thickness can be formed on the side surfaces of the insulator 250, the metal oxide 252, the conductor 260, and the insulator 270 even in a step portion formed by the conductor 260 and the like. A dense thin film can be formed by an ALD method.

The insulating film 272A preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride are preferable because silicon oxide and silicon oxynitride are thermally stable, and silicon oxide and porous silicon oxide are preferable because an oxygen-excess region can be easily formed in a later step.

Alternatively, aluminum oxide having a barrier property or the like may be used for the insulating film 272A. In the case where the conductor 260 is a metal film that is easily oxidized, for example, an insulator having a barrier property can inhibit oxidization of the conductor 260 due to oxygen from above the insulating film 272A. This can suppress an increase in the resistance value of the conductor 260.

When aluminum oxide is formed by an ALD method as the insulating film 272A, the insulating film 272A preferably has a thickness of greater than or equal to 0.5 nm and less than or equal to 3.0 nm. With this structure, oxidization of the conductor 260 can be prevented, and excess oxygen can be supplied from the insulator 275 to the insulator 250 in a later step.

Next, the insulating film 272A is subjected to anisotropic etching, whereby the insulator 272 is formed in contact with the side surfaces of the insulator 250, the metal oxide 252, the conductor 260, and the insulator 270. Furthermore, an exposed part of the oxide film 230C is removed, whereby the oxide 230c is formed. Accordingly, the oxide 230 (the oxide 230a, the oxide 230b, and the oxide 230c) is completed (see FIGS. 8A to 8D).

Dry etching is preferably performed as the anisotropic etching. In this manner, the insulating film in a region on a plane substantially parallel to the substrate surface can be removed, so that the insulator 272 can be formed in a self-aligned manner.

Note that in this step, the insulating film 224A may be processed into an island shape (processed into the insulator 224). In this case, the insulator 222 can be used as an etching stopper film.

A film 242A is formed over the insulator 222, the insulator 224, and the oxide 230 with the insulator 250, the metal oxide 252, the conductor 260, the insulator 270, and the insulator 272 positioned therebetween (see FIGS. 9A to 9D). The film 242A may have a thickness of greater than or equal to 0.5 nm and less than or equal to 5 nm, preferably greater than or equal to 1 nm and less than or equal to 3 nm. The film 242A is a metal film, a nitride film containing a metal element, or an oxide film containing a metal element. For example, the film 242A is a film containing a metal element such as aluminum, ruthenium, titanium, tantalum, tungsten, or chromium. The film 242A can be formed by a sputtering method, a CVD method, an MBE method, a PLD method, an ALD method, or the like.

Subsequently, heat treatment is performed (see FIGS. 10A to 10D). The heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The heat treatment is performed in a nitrogen atmosphere or an inert gas atmosphere. The heat treatment may be performed under a reduced pressure. The heat treatment is performed in a nitrogen atmosphere at 400° C. for one hour after the formation of the film 242A, for example.

By the heat treatment in the atmosphere containing nitrogen, the metal element is diffused from the film 242A into the oxide 230; thus, the metal element can be added to the oxide 230. Moreover, oxygen in the oxide 230 at and near the interface with the film 242A may be absorbed by the film 242A. As a result, the oxide 230 at and near the interface with the film 242A become a metal compound and the resistance thereof is reduced (see FIGS. 10A to 10D). At this time, part of the oxide 230 may be alloyed with the metal element. When part of the oxide 230 is alloyed with the metal element, the metal element added to the oxide 230 becomes relatively stable; therefore, a highly-reliable semiconductor device can be provided.

If hydrogen in the oxide 230 diffuses into the region 231 and enters an oxygen vacancy in the region 231, the hydrogen becomes relatively stable. Hydrogen in an oxygen vacancy in the region 234 is released from the oxygen vacancy by heat treatment at 250° C. or higher, diffuses into the region 231, enters an oxygen vacancy in the region 231, and becomes relatively stable. Thus, the resistance of the region 231 is further reduced, and the region 234 is purified (impurities such as water or hydrogen therein are reduced) and the resistance of the region 234 is increased.

Heat treatment may be performed in a nitrogen atmosphere or an inert gas atmosphere, and then another heat treatment may be performed in an atmosphere containing an oxidizing gas at 10 ppm or more, 1% or more, or 10% or more. The heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C.

In the case where a region having conductivity remains in the film 242A, heat treatment in an oxidization atmosphere oxidizes the film 242A, whereby the film 242A becomes a high-resistant insulator. The film 242A that remains as an insulator can function as an interlayer film.

By the formation of the film 242A or the heat treatment, an oxygen vacancy may be formed in the region 231 and the region 232 due to absorption of oxygen in the region 231 and the region 232 adjacent to the region 231 by the film 242A. Entry of hydrogen in the oxide 230 to the oxygen vacancy increases the carrier density of the region 231 and the region 232. Therefore, the region 231 and the region 232 of the oxide 230 become n-type low-resistance regions.

Then, the film 242A is removed. The film 242A is not necessarily removed. When the metal film, the nitride film containing a metal element, or the oxide film containing a metal element is oxidized by oxygen absorbed from the oxide 230 to be a high-resistant insulator, for example, the film may remain. In this case, the film may function as an interlayer film. A dry etching method, a wet etching method, or the like may be used for this step. At the same time as the film 242A is removed, hydrogen in the oxide 230 absorbed by the film 242A can be removed. Accordingly, hydrogen, which is an impurity in the transistor 200, can be reduced.

Then, an insulating film 275A is formed (see FIGS. 11A to 11D). The insulating film 275A preferably includes an insulator with a low relative permittivity. The insulating film 275A preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide, silicon oxynitride, silicon nitride oxide, and porous silicon oxide are preferable because an oxygen-excess region can be easily formed in the insulator 275 in a later step. In addition, silicon oxide and silicon oxynitride are preferable because silicon oxide and silicon oxynitride are thermally stable.

Next, the insulating film 275A is subjected to anisotropic etching, whereby the insulator 275 is formed on the side surfaces of the insulator 272 and the oxide 230 (see FIGS. 12A to 12D). Subsequently, an insulating film to be the insulator 273 is formed over the insulator 275 and the oxide 230 (see FIGS. 13A to 13D).

The insulating film to be the insulator 273 is preferably formed by a sputtering method. The insulator formed by a sputtering method can be an insulator containing few impurities such as water or hydrogen.

When the insulating film to be the insulator 273 is formed in an oxygen gas atmosphere with a sputtering apparatus, oxygen can be introduced into the insulator 275 during the deposition. In the insulator 275 formed using silicon oxide, silicon oxynitride, silicon nitride oxide, or porous silicon oxide, an excess-oxygen region is likely to be formed. In contrast, an excess-oxygen region is less likely to be formed in the oxide 230 than in the silicon oxide even when an oxide film formed by a sputtering method is formed over the oxide 230. Therefore, when an oxide film is formed as the insulating film to be the insulator 273 by a sputtering method, an excess-oxygen region can be selectively formed in the insulator 275. At this time, since an excess-oxygen region is less likely to be formed in the oxide 230, an increase in the resistance of the low-resistance region of the oxide 230 can be inhibited.

As described above, oxygen can be effectively supplied from the excess-oxygen region of the insulator 275 to the region 234 of the oxide 230.

With the above structure, regions of the oxide 230 can be formed in a self-aligned manner. Thus, minute or highly integrated semiconductor devices can be manufactured with high yield.

Thus, by appropriately selecting the areas of the regions, a transistor having electrical characteristics necessary for the circuit design can be easily provided.

Subsequently, heat treatment can be performed. For the heat treatment, the conditions for the above heat treatment can be used. Note that the heat treatment is unnecessary in some cases. By the heat treatment, hydrogen trapped by an oxygen vacancy formed in the region 231 of the oxide 230 is absorbed by the insulator 273; therefore, hydrogen in the oxide 230 can be reduced.

Then, the insulator 280 is formed over the insulator 273 (see FIGS. 13A to 13D). The insulator 280 can be formed by a sputtering method, a CVD method, an MBE method, a PLD method, an ALD method, or the like. Alternatively, the insulating film to be the insulator 280 can be formed by a spin coating method, a dipping method, a droplet discharging method (such as an ink-jet method), a printing method (such as screen printing or offset printing), a doctor knife method, a roll coater method, a curtain coater method, or the like. In this embodiment, silicon oxynitride is used for the insulator 280.

Next, the insulator 280 is partly removed. The insulator 280 is preferably formed to have a flat top surface. For example, the insulator 280 may have a flat top surface right after the formation. Alternatively, the insulator 280 may be planarized by removing the insulator or the like from the top surface after the deposition so that the top surface becomes parallel to a reference surface such as a rear surface of the substrate. Such treatment is referred to as planarization treatment. As the planarization treatment, for example, chemical mechanical polishing (CMP) treatment, dry etching treatment, or the like can be performed. In this embodiment, CMP treatment is used as planarization treatment. Note that the top surface of the insulator 280 does not necessarily have planarity.

Next, openings reaching the oxide 230 are formed in the insulator 280 and the insulator 273 (see FIGS. 14A to 14D). The openings may be formed by a lithography method. Note that in order that the conductors 240a and 240b are provided in contact with the side surface of the oxide 230, the openings are formed to reach the oxide 230 such that the side surface of the oxide 230 is exposed in the openings.

Next, a conductive film to be the first conductor of the conductor 240 and the second conductor of the conductor 240 is formed. The conductive film can be formed by a sputtering method, a CVD method, an MBE method, a PLD method, an ALD method, or the like.

When the opening is formed in the insulator 280 and the insulator 273, for example, a low-resistance region of the region 231 of the oxide 230 may be removed. The first conductor of the conductor 240 may be a metal film, a nitride film containing a metal element, or an oxide film containing a metal element. Since the oxide 230 has a region in contact with the first conductor of the conductor 240, a metal compound or an oxygen vacancy is formed in the region, whereby the resistance of the region where the oxide 230 and the first conductor of the conductor 240 are in contact with each other can be reduced. The reduction in the resistance of the oxide 230 that is in contact with the first conductor of the conductor 240 can make a sufficient ohmic contact between the oxide 230 and the conductor 240. The first conductor of the conductor 240 preferably contains a metal element such as aluminum, ruthenium, titanium, tantalum, tungsten, or chromium.

Next, the conductive film to be the conductors 240a and 240b is partly removed by CMP treatment to expose the insulator 280. As a result, the conductive film remains only in the openings, so that the conductors 240a and 240b having flat top surfaces can be formed (see FIGS. 1A to 1D).

Through the above process, the semiconductor device including the transistor 200 can be manufactured. By the method for manufacturing a semiconductor device which is described in this embodiment and is illustrated in FIGS. 3A to 3D to FIGS. 14A to 14D, the transistor 200 can be formed.

According to one embodiment of the present invention, a semiconductor device with favorable electrical characteristics can be provided. Alternatively, according to one embodiment of the present invention, a semiconductor device with low off-state current can be provided. Alternatively, according to one embodiment of the present invention, a semiconductor device with high on-state current can be provided. Alternatively, according to one embodiment of the present invention, a semiconductor device with high reliability can be provided. Alternatively, according to one embodiment of the present invention, a semiconductor device that can be miniaturized or highly integrated can be provided. Alternatively, according to one embodiment of the present invention, a semiconductor device with low power consumption can be provided. Alternatively, according to one embodiment of the present invention, a semiconductor device with high productivity can be provided.

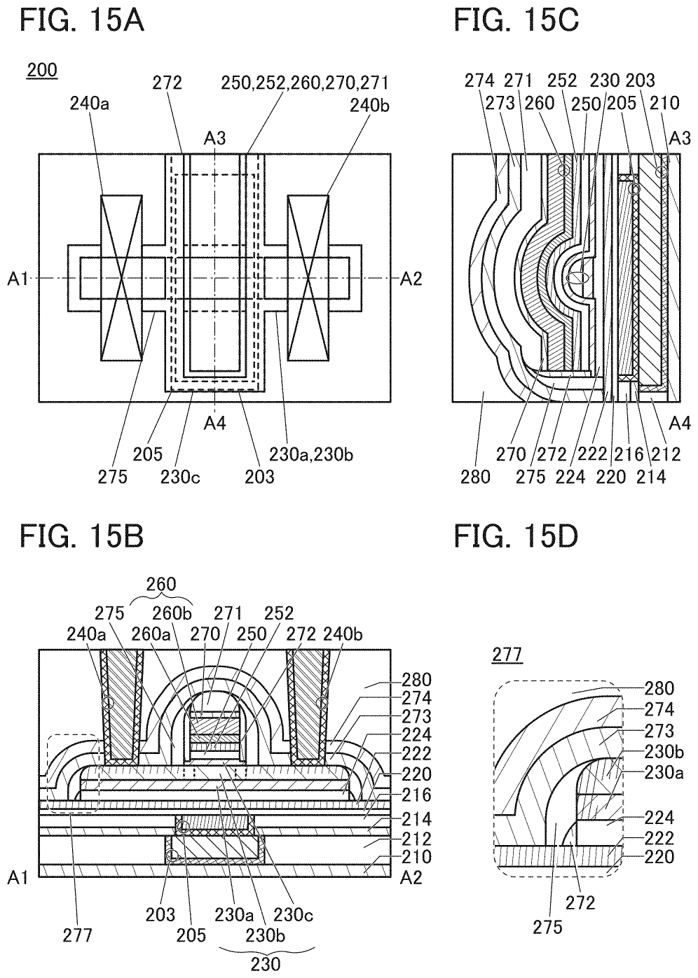

As described above, the compositions, methods, and the like described in this embodiment can be combined with any of the compositions, methods, and the like described in the other embodiments as appropriate.

<Modified example of semiconductor device> An example of a semiconductor device including the transistor 200 of one embodiment of the present invention will be described below with reference to FIGS. 15A to 15D.

FIG. 15A is a top view of the semiconductor device including the transistor 200. FIGS. 15B and 15C are cross-sectional views of the semiconductor device. FIG. 15B is a cross-sectional view taken along dashed-dotted line A1-A2 in FIG. 15A, which corresponds to a cross-sectional view in the channel length direction of the transistor 200. FIG. 15C is a cross-sectional view taken along dashed-dotted line A3-A4 in FIG. 15A, which corresponds to a cross-sectional view in the channel width direction of the transistor 200. FIG. 15D is an enlarged view of a region 277 surrounded by a broken line in FIG. 15B. For simplification of the drawing, some components are not illustrated in the top view in FIG. 15A.

Note that in the semiconductor device illustrated in FIGS. 15A to 15D, components having the same functions as the components in the semiconductor device described in <Structure example of semiconductor device> are denoted by the same reference numerals.

The structure of the transistor 200 is described with reference to FIGS. 15A to 15D below. Note that also in this section, the materials described in detail in <Structure example of semiconductor device> can be used as materials of the transistor 200.

The transistor 200 illustrated in FIGS. 15A to 15D is different from the semiconductor device described in <Structure example of semiconductor device> in at least that an insulator 274 is provided and the insulator 272 remains on the side surface of the insulator 224.

Specifically, the insulator 272 may remain on the side surface of the insulator 224 as illustrated in FIG. 15D. When the insulator 272 is processed, for example, the insulator 272 remains in some cases depending on the thickness of the insulator 271 functioning as a hard mask (see FIGS. 7A to 7D and FIGS. 8A to 8D). At this time, at least the insulator 272 on the side surface of the oxide 230 needs to be removed. That is, the side surface of the oxide 230 and the film 242A are preferably in contact with each other after the formation of the film 242A, as illustrated in FIGS. 9A to 9D.

When the insulator 272 remains on the side surface of the insulator 224, the coverage of the insulator 275 can be improved.

The insulator 274 may be provided over the transistor 200. The insulator 274 can be formed using silicon nitride in which hydrogen is reduced, for example.

When the transistor 200 is covered with the insulator 274, entry of impurities such as hydrogen from a component outside the transistor 200 into the transistor 200 can be inhibited.

As described above, the compositions, structures, methods, and the like described in this embodiment can be combined with any of the compositions, structures, methods, and the like described in the other embodiments as appropriate.

### Embodiment 2

Hydrogen in IGZO that can be used as an oxide semiconductor of the transistor 200 of one embodiment of the present invention will be described below.

<1. Movement of hydrogen atom> Here, the mobility of a hydrogen atom in an IGZO crystal was measured from the activation barrier along a transfer path of a hydrogen atom. Note that the two kinds of movement of a hydrogen atom were assumed: hopping between oxygen atoms; and movement on one oxygen atom.

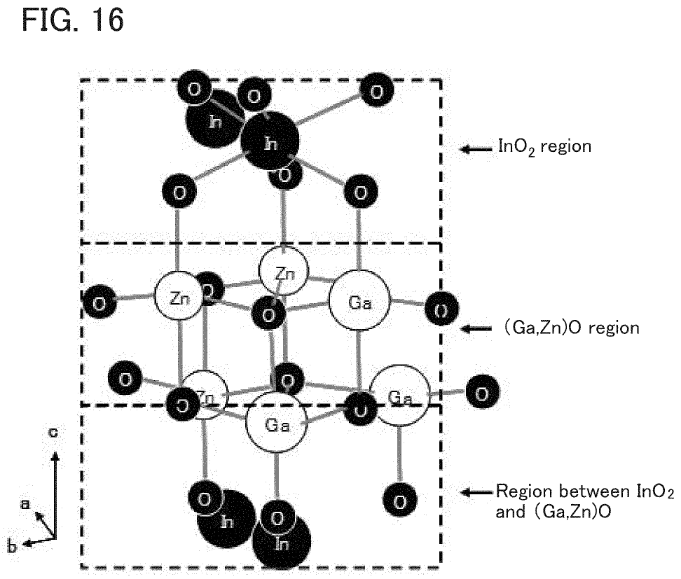

FIG. 16 is a schematic view showing different areas in an InGaZnO₄ crystal, in each of which the transfer path of a hydrogen atom was analyzed. The measurement was performed on the path in each of an InO₂ region, a (Ga, Zn)O region, and an InO₂—(Ga, Zn)O region (a-b plane direction), and the path crossing each region (c-axis direction).

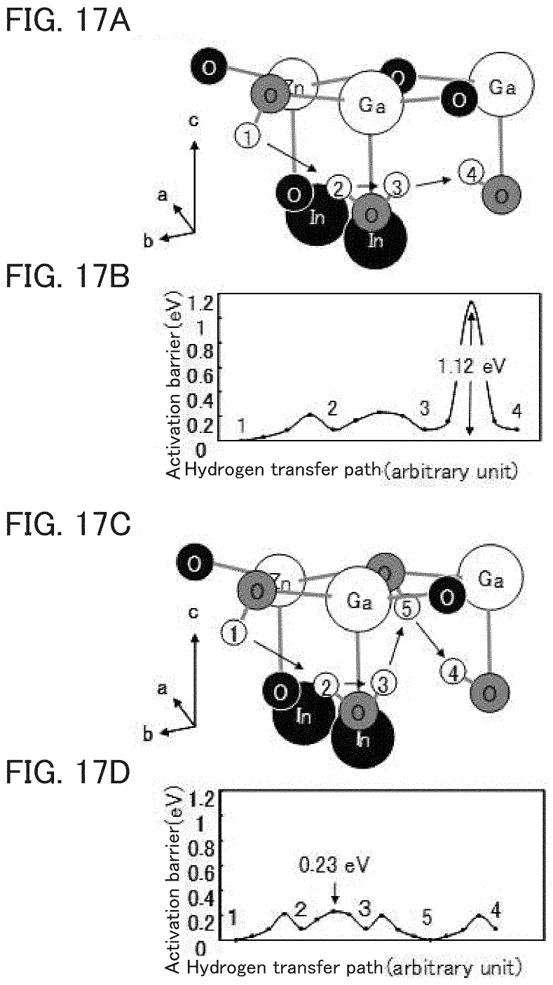

The activation barrier was calculated by the first-principles electron state and molecular dynamics simulation using the Vienna ab initio simulation package (VASP). The nudged elastic band (NEB) method, which is to find a chemical reaction path, was also employed. The NEB method is a technique for determining the minimum energy path between given initial and final states. The activation barrier here was a difference between the maximum energy on the path and an energy of the most stable structure on the path.

<<Region between InO₂ plane and (Ga, Zn)O plane>> FIGS. 17A to 17D show transfer paths of a hydrogen atom in the region between the InO₂ plane and the (Ga, Zn)O plane, and activation barriers along the paths. Note that an energy of the most stable structure on the path was taken as the origin of energy. FIGS. 17A and 17C show the transfer paths of a hydrogen atom which are referred to as a path A and a path B, respectively. Note that numbers in FIGS. 17A to 17D represent the order of transfer of a hydrogen atom. On the path A, a hydrogen atom transfers from 3 to 4 directly, whereas on the path B, a hydrogen atom transfers from 3 to 4 via 5.

FIG. 17B shows the calculation results of the activation barrier along the path A (a path where a hydrogen atom transfers from 1 to 4), and FIG. 17D shows the calculation results of the activation barrier along the path B (a path where a hydrogen atom transfers from 1 to 4 via 5).

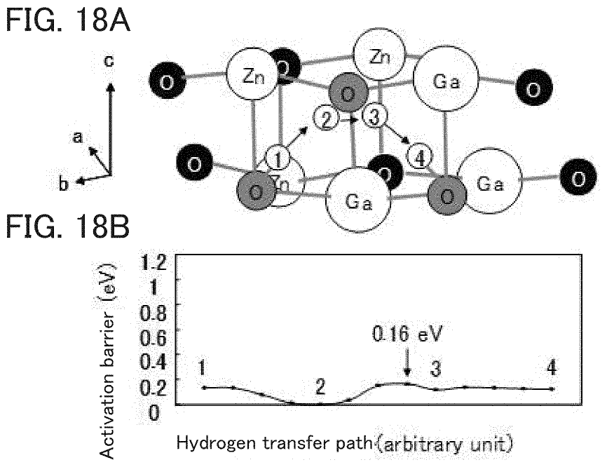

The activation barrier along the path A shown in FIG. 17B was 1.12 eV, and the activation barrier along the path B shown in FIG. 17D was 0.23 eV. The activation barrier along the path B is lower than that along the path A. Therefore, when a hydrogen atom transfers from 3 to 4, the path B with a lower activation barrier is probably taken. In other words, when a hydrogen atom transfers in the region between the InO₂ plane and the (Ga, Zn)O plane, the path B with a lower activation barrier will be taken.

<<(Ga, Zn)O region>> Next, a transfer path of a hydrogen atom in the (Ga, Zn)O region and the activation barrier along the path are shown in FIGS. 18A and 18B. Note that an energy of the most stable structure on the path was taken as the origin of energy. FIG. 18A shows the transfer path of a hydrogen atom in the (Ga, Zn)O region. The numbers in FIG. 18A represent the order of transfer of a hydrogen atom. FIG. 18B shows the calculation results of the activation barrier along the path where a hydrogen atom transfers from 1 to 4 in FIG. 18A.

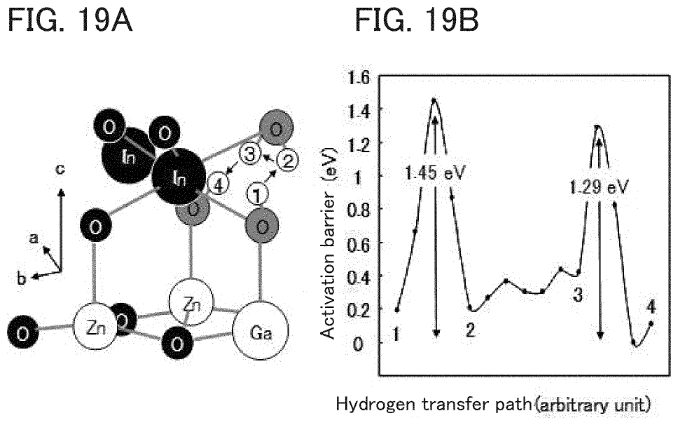

FIG. 18B shows that an activation barrier along the transfer path of a hydrogen atom in the (Ga, Zn)O region is approximately 0.16 eV, which is lower than an activation barrier shown in FIG. 17D. Given only the height of the barrier, a hydrogen atom will be more likely to transfer in the (Ga, Zn)O region than in the region between the InO₂ plane and the (Ga, Zn)O plane.

<<InO₂ region>> Next, a transfer path of a hydrogen atom in the InO₂ region and the activation barrier along the path are shown in FIGS. 19A and 19B. Note that an energy of the most stable structure on the path was taken as the origin of energy. FIG. 19A shows transfer of a hydrogen atom in the InO₂ region. The numbers in FIG. 19A represent the order of transfer of a hydrogen atom. FIG. 19B shows the calculation results of the activation barrier along the path where a hydrogen atom transfers from 1 to 4 in FIG. 19A.

FIG. 19B shows that activation barriers when a hydrogen atom transfers from one oxygen atom to another oxygen atom in the InO₂ region are higher than or equal to 1.2 eV, which are much higher than activation barriers shown in FIG. 17D and FIG. 18B. Accordingly, a hydrogen atom will be less likely to transfer in the InO₂ region than in the other regions.

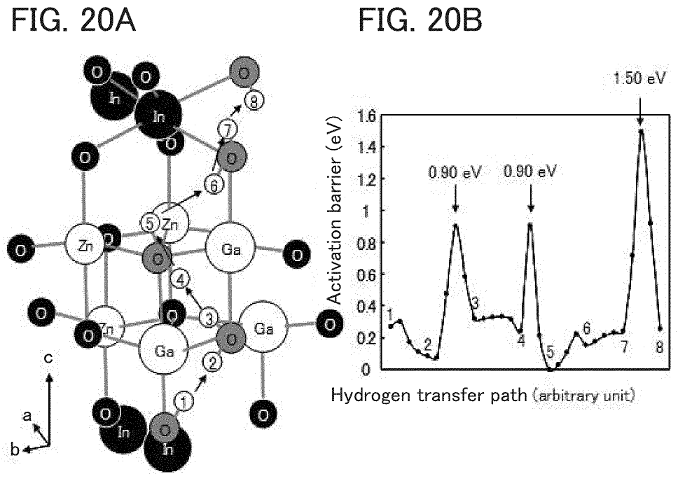

FIGS. 20A and 20B show a transfer path of a hydrogen atom in the c-axis direction and the activation barrier along the path. Note that an energy of the most stable structure on the path was taken as the origin of energy. FIG. 20A shows the transfer path of a hydrogen atom in the c-axis direction. The numbers in FIG. 20A represent the order of transfer of a hydrogen atom. FIG. 20B shows the calculation results of the activation barrier along the path where a hydrogen atom transfers from 1 to 8 in FIG. 20A.

FIG. 20B shows that an activation barrier along the transfer path of a hydrogen atom from 2 to 5 is 0.9 eV. That is, a high activation barrier exists on the path in and out of the (Ga, Zn)O region. This is probably because the transfer path of a hydrogen atom is blocked by a bond between a metal atom and an oxygen atom. FIG. 20B shows that an activation barrier along the transfer path of a hydrogen atom from 7 to 8 is approximately 1.5 eV. A high activation barrier is found to exist also when hydrogen in the InO₂ region. Hence, a hydrogen atom will be less likely to transfer continuously in the c-axis direction. Note that one cause of the high activation barrier might be a large radius of an In ion.

From the activation barriers obtained by calculation and the following Formula 1, movement frequency (Γ) was calculated.

$$Γ = v exp ( - \frac{{E}_{a}}{{k}_{B} T} ) \qquad [ Formula 1 ]$$

In the formula, Eₐ represents the activation barrier; k_{B}, the Boltzmann constant; T, the absolute temperature; and ν, the frequency factor.

Lastly, Table 1 shows the movement frequency that is estimated from the local large value of the activation barrier height (maximum barrier height) of each path.

TABLE 1

| | | Maximum barrier | Movement frequency (1/sec) | |
|---|---|---|---|---|
| Path | | height (eV) | 450° C. | 27° C. |
| Region between InO₂ plane and (Ga, Zn)O | A | 1.12 | 1.6E+05 | 1.0E−06 |
| plane (a-b plane direction) | | | | |
| Region between InO₂ plane and (Ga, Zn)O | B | 0.23 | 2.5E+11 | 1.4E+09 |
| plane (a-b plane direction) | | | | |
| (Ga, Zn)O region (a-b plane direction) | | 0.16 | 7.7E+11 | 2.1E+10 |
| InO₂ region (c-axis direction) | | 1.45 | 8.0E+02 | 4.6E−12 |
| Path into (out of) (Ga, Zn)O plane (c-axis | | 0.90 | 5.4E+06 | 7.8E−03 |
| direction) | | | | |

At temperatures of 27° C. and 450° C., the movement frequency in the a-b plane direction was the highest in the region between the InO₂ plane and the (Ga, Zn)O plane and in the (Ga, Zn)O region. In contrast, the movement frequency in the c-axis direction was likely to be low in the InO₂ region. This indicates that hydrogen preferentially diffuses along the a-b plane in a complete crystal system. In heat treatment at 450° C., however, hydrogen was found to diffuse in the IGZO film sufficiently.

<2. Site in which oxygen vacancy V_{O} is easily formed> The strength of bonding between a metal element and an oxygen element differs depending on the kind or valence of the metal; therefore, the ease of formation of an oxygen vacancy V_{O} in IGZO is probably determined by the kind, number, distance, or the like of metals bonded to an oxygen element. The ease of formation of an oxygen vacancy in an InGaZnO₄ crystal model was calculated.

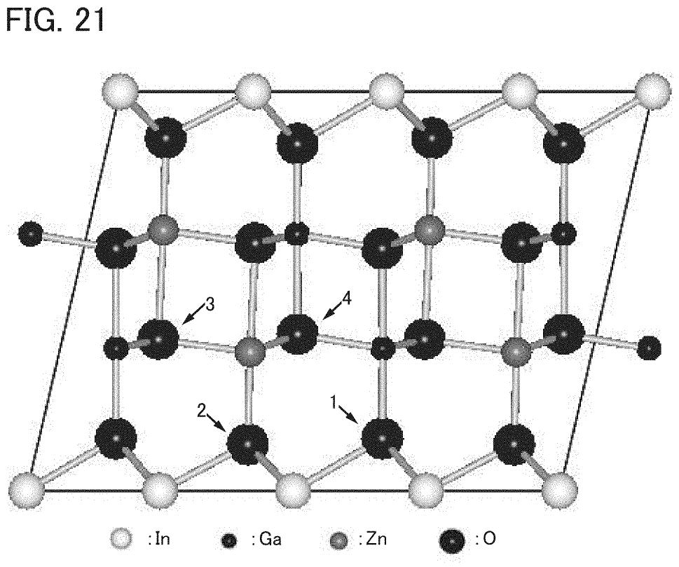

The model used for calculation is an InGaZnO₄ crystal model (112 atoms) shown in FIG. 21. In a (Ga, Zn)O region, Ga and Zn were placed so as to be energetically stable. In that case, there are four kinds of oxygen sites (1 to 4 in FIG. 21) depending on the kind and number of metals bonded to oxygen. Table 2 shows the four oxygen sites.

TABLE 2

| | |
|---|---|
| Oxygen site | Bonding partner |

| | | |
|---|---|---|
| InO₂ layer | 1 | In × 3, Ga × 1 |
| | 2 | In × 3, Zn × 1 |
| (Ga, Zn)O layer | 3 | Ga × 2, Zn × 2 |
| | 4 | Ga × 2, Zn × 2 |

An oxygen atom was extracted from each oxygen site in the above model, whereby oxygen vacancy models were obtained. Then, the total energy of each model after structure optimization was compared. Table 3 shows the calculation conditions.

TABLE 3

| Software | VASP |
|---|---|
| Functional | GGA-PBE |
| Pseudopotential | PAW |
| Cut-off energy | 500 eV |
| k points | 2 × 2 × 3 |

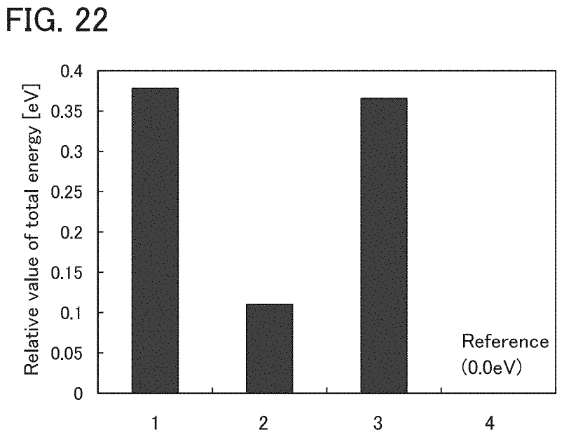

The total energy of each optimized structure was compared. FIG. 22 shows relative values of the total energies with the total energy of the oxygen vacancy model of the oxygen site 4 as a reference (0.0 eV). FIG. 22 indicates that an oxygen vacancy is most easily formed in the oxygen site 4, and relatively easily formed in the oxygen site 2. In contrast, an oxygen vacancy is presumably less likely to be formed in the oxygen sites 1 and 3 than in the oxygen sites 2 and 4.

<3. Ease of formation and stability of H_{O}> The calculation results described in <1. Movement of hydrogen atom> show that hydrogen diffuses into IGZO particularly when heat treatment is performed. Here, calculation was made on whether hydrogen is released from an oxygen vacancy V_{O} if the oxygen vacancy V_{O} exists. A state in which a hydrogen atom is in an oxygen vacancy V_{O} is referred to as H_{O} (also referred to as V_{O}H).

An InGaZnO₄ crystal model shown in FIG. 21 was used for calculation. Here, an activation barrier (Eₐ) along the transfer path in which a hydrogen atom in an oxygen vacancy V_{O} is released from the oxygen vacancy V_{O} to be bonded to an oxygen atom was calculated by the NEB method. The calculation conditions are shown in Table 4.

TABLE 4

| Software | VASP |
|---|---|
| Calculation | NEB method |
| Functional | GGA-PBE |
| Pseudopotential | PAW |
| Cut-off energy | 800 eV |
| k points | 2 × 2 × 3 |

The calculation results in <2. Site in which oxygen vacancy V_{O} is easily formed> shows that the oxygen vacancy V_{O} is most easily formed in the oxygen site 4 shown in FIG. 21. Here, calculation was made on whether a hydrogen atom is released from the oxygen vacancy V_{O} if the oxygen vacancy V_{O} exists in an oxygen site (“3” in FIG. 21) bonded to one Ga atom and two Zn atoms.

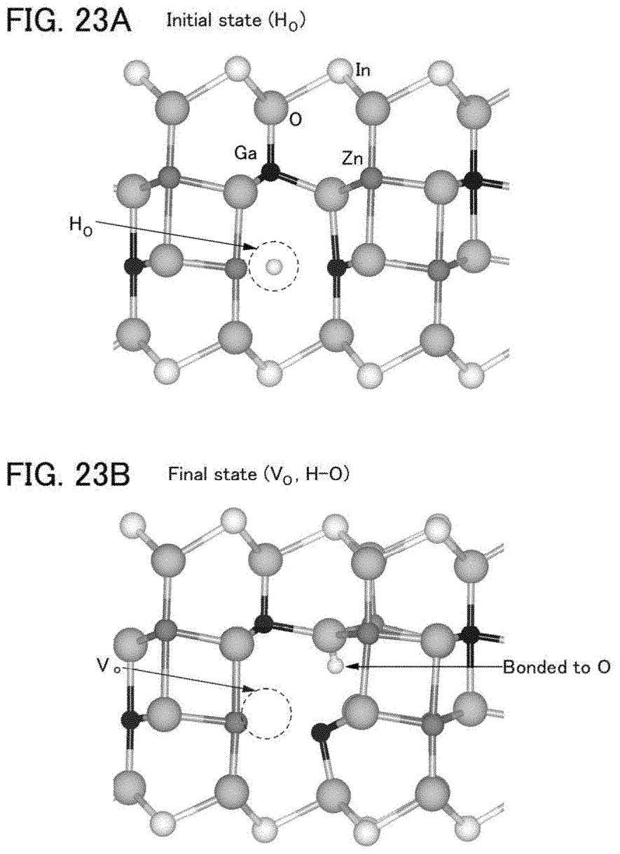

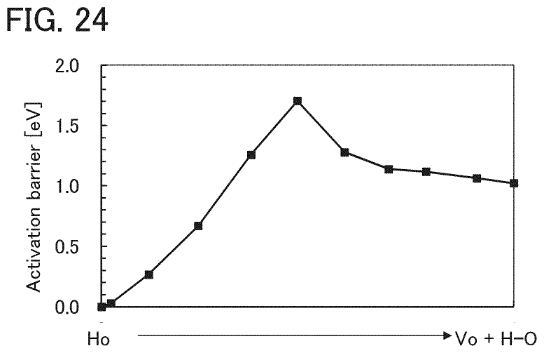

FIG. 23A shows a model in the initial state and FIG. 23B shows a model in the final state. Note that here, the initial state refers to a state in which a hydrogen atom exists in an oxygen vacancy V_{O} (H_{O}), and the final state refers to a structure including an oxygen vacancy V_{O} and a state in which a hydrogen atom is bonded to an oxygen atom bonded to one Ga atom and two Zn atoms (H—O). FIG. 24 shows an activation barrier along a transfer path of a hydrogen atom from the initial state to the final state. The total energy of the initial state was a reference (0.0 eV).

The calculation results show that an activation barrier (Eₐ) when a hydrogen atom is released from the oxygen vacancy V_{O} is approximately 1.70 eV.

Then, the average number of releases of a hydrogen atom from the oxygen vacancy V_{O} per hour was calculated by using Formula 1 and the above activation barrier (Eₐ) obtained by the calculation.

The average number of releases of a hydrogen atom from the oxygen vacancy V_{O} at room temperature and at 250° C. was calculated on the assumption that the frequency factor ν was 10¹³ [1/sec]. The average number of times that a hydrogen atom moves from a model of FIG. 23A to a model of FIG. 23B at room temperature was approximately 1×10⁻¹² [times]. This result shows that the probability of release of a hydrogen atom from the oxygen vacancy V_{O} is extremely low at room temperature and suggests that H_{O} is stable. The average number of times that a hydrogen atom moves from the model of FIG. 23A to the model of FIG. 23B at 250° C. was approximately 2 [times]. This result suggests that baking at a temperature higher than or equal to 250° C. for one hour can make a hydrogen atom released from the oxygen vacancy V_{O}.

The above results show that hydrogen in an oxygen vacancy V_{O} in a channel formation region is released by heat treatment, and the hydrogen released from the oxygen vacancy diffuses into a low-resistance region and easily enters an oxygen vacancy V_{O} in the low-resistance region to be H_{O}. The channel formation region is purified (impurities such as water or hydrogen are reduced) by the heat treatment, so that normally-off transistor characteristics are obtained.

As described above, the compositions, structures, methods, and the like described in this embodiment can be combined with any of the compositions, structures, methods, and the like described in the other embodiments as appropriate.

### Embodiment 3

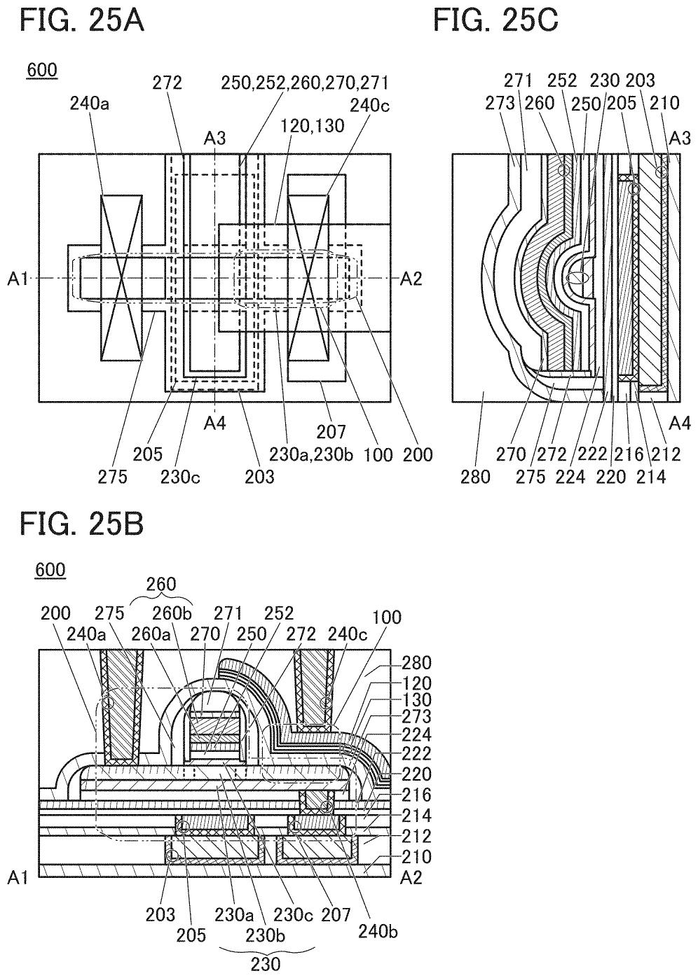

An example of a semiconductor device including the transistor 200 of one embodiment of the present invention will be described below.

<Structure example of semiconductor device> FIGS. 25A to 25C are a top view and cross-sectional views of the transistor 200 and a capacitor 100 of one embodiment of the present invention and the periphery of the transistor 200. Note that in this specification, a memory device including one capacitor and at least one transistor is referred to as a cell.

FIG. 25A is a top view of a cell 600 including the transistor 200 and the capacitor 100. FIGS. 25B and 25C are cross-sectional views of the cell 600. FIG. 25B is a cross-sectional view taken along dashed-dotted line A1-A2 in FIG. 25A, which corresponds to a cross-sectional view in the channel length direction of the transistor 200. FIG. 25C is a cross-sectional view taken along dashed-dotted line A3-A4 in FIG. 25A, which corresponds to a cross-sectional view in the channel width direction of the transistor 200. For simplification of the drawing, some components are not illustrated in the top view in FIG. 25A.

[Cell 600] The semiconductor device of one embodiment of the present invention includes the transistor 200, the capacitor 100, and the insulator 280 functioning as an interlayer film. Furthermore, the conductor 240 (the conductor 240a, the conductor 240b, and a conductor 240c) functioning as a plug that is electrically connected to the transistor 200 is included.

The transistor 200 and the capacitor 100 are provided on the same layer in the cell 600 of FIGS. 25A to 25C, whereby part of components in the transistor 200 can be used as part of components in the capacitor 100. That is, part of the components of the transistor 200 may function as part of the components of the capacitor 100.

Furthermore, part of the capacitor 100 or the entire capacitor 100 overlaps with the transistor 200, so that the total area of the projected area of the transistor 200 and the projected area of the capacitor 100 can be reduced.

Furthermore, the conductor 240b and a conductor 207 functioning as plugs or wirings electrically connected to the transistor 200 are provided below a region where the capacitor 100 and the transistor 200 overlap with each other, so that the cell 600 can be easily miniaturized or highly integrated. Since the conductor 207 can be formed in the same step as the conductor 205, which is one of the components of the transistor 200, the manufacturing process can be simplified. As in the transistor 200, a conductor functioning as a wiring may be provided in contact with the bottom surface of the conductor 207 in the capacitor 100.

The layout of the transistor 200 and the capacitor 100 can be designed as appropriate depending on the required capacitance of the capacitor 100.

For example, the area of the capacitor 100 depends on the area where the region 231b of the oxide 230 and a conductor 120 overlap with each other with an insulator 130 positioned therebetween. That is, when the capacitance value needed for the cell 600 cannot be obtained by the capacitor 100 illustrated in FIGS. 25A and 25B, the widths of the regions 231b of the oxide 230a and the oxide 230b in the A3-A4 direction are made larger than those of the regions 234 of the oxide 230a and the oxide 230b, which can increase the capacitance value.

The length of the region 231b of the oxide 230 in the A1-A2 direction may be longer than that of the conductor 120. In that case, the conductor 240b can be embedded in the insulator 280. That is, the region 231b of the oxide 230 and the conductor 240b may be provided in contact with each other in a region where the region 231b of the oxide 230 and the conductor 120 do not overlap with each other. In that case, the conductors 240a, 240b, and 240c can be formed in the same step; this can make the manufacturing process simple.

With this structure, miniaturization or high integration of the semiconductor device can be achieved. Moreover, the design flexibility of the semiconductor device can be increased. Furthermore, the transistor 200 and the capacitor 100 can be formed through the same process. Accordingly, the process can be shortened, leading to an improvement in productivity.

[Transistor 200] The structure of the transistor included in the semiconductor device described in the above embodiment can be used as the structure of the transistor 200. The transistor 200 in FIGS. 25A to 25C is only an example and the transistor 200 is not limited to the structure illustrated therein, and an appropriate transistor may be used in accordance with a circuit configuration or a driving method.

[Capacitor 100] The capacitor 100 has common components as the transistor 200 as illustrated in FIGS. 25A to 25C. In this embodiment, an example of the capacitor 100 in which the region 231b provided in the oxide 230 of the transistor 200 functions as one electrode of the capacitor 100 is shown.

The capacitor 100 includes the region 231b of the oxide 230, the insulator 273 over the region 231b, the insulator 130 over the insulator 273, and the conductor 120 over the insulator 130. Moreover, the conductor 120 is preferably provided over the insulator 130 to at least partly overlap with the region 231b of the oxide 230. Furthermore, the conductor 240c is preferably provided in contact with the top surface of the conductor 120.

The region 231b of the oxide 230 functions as one electrode of the capacitor 100, and the conductor 120 functions as the other electrode of the capacitor 100. The insulator 130 and the insulator 273 function as a dielectric of the capacitor 100. The resistance of the region 231b of the oxide 230 is reduced, and is a conductive oxide. Thus, the region 231b of the oxide 230 can function as one electrode of the capacitor 100.

An insulator with a high relative permittivity is preferably used as the insulator 130. An insulator that can be used as the insulator 222 or the like may be used. For example, an insulator containing an oxide of one or both of aluminum and hafnium can be used. Aluminum oxide, hafnium oxide, an oxide containing aluminum and hafnium (hafnium aluminate), or the like is preferably used for the insulator containing an oxide of one or both of aluminum and hafnium. The insulator 130 may have a stacked-layer structure of, for example, two or more of silicon oxide, silicon oxynitride, silicon nitride oxide, silicon nitride, aluminum oxide, hafnium oxide, an oxide containing aluminum and hafnium (hafnium aluminate), and the like. For example, hafnium oxide, aluminum oxide, and hafnium oxide are preferably formed in this order by an ALD method. The thickness of each of the hafnium oxide and the aluminum oxide is greater than or equal to 0.5 nm and less than or equal to 5 nm. With such a stacked-layer structure, the capacitor 100 can have a large capacitance value and a low leakage current.

Although the side surface of the insulator 130 corresponds to the side surface of the conductor 120 when seen from the top as illustrated in FIG. 25A, one embodiment of the present invention is not limited thereto. For example, the insulator 130 may be formed without patterning so that the insulator 130 covers the transistor 200.

Although the insulator 130 and the insulator 273 are provided as the dielectric of the capacitor 100 in FIGS. 25A to 25C, one embodiment of the present invention is not limited thereto. For example, a region of the insulator 273 that overlaps with the capacitor 100 may be removed and the insulator 130 may be used as the dielectric of the capacitor 100. Alternatively, for example, the insulator 130 is unnecessary and the insulator 273 may be used as a dielectric of the capacitor 100.

In the case where the insulator 274 is provided in the transistor 200, a region of the insulator 274 that overlaps with the capacitor 100 may be removed or the insulator 274 may be used as the dielectric of the capacitor 100.

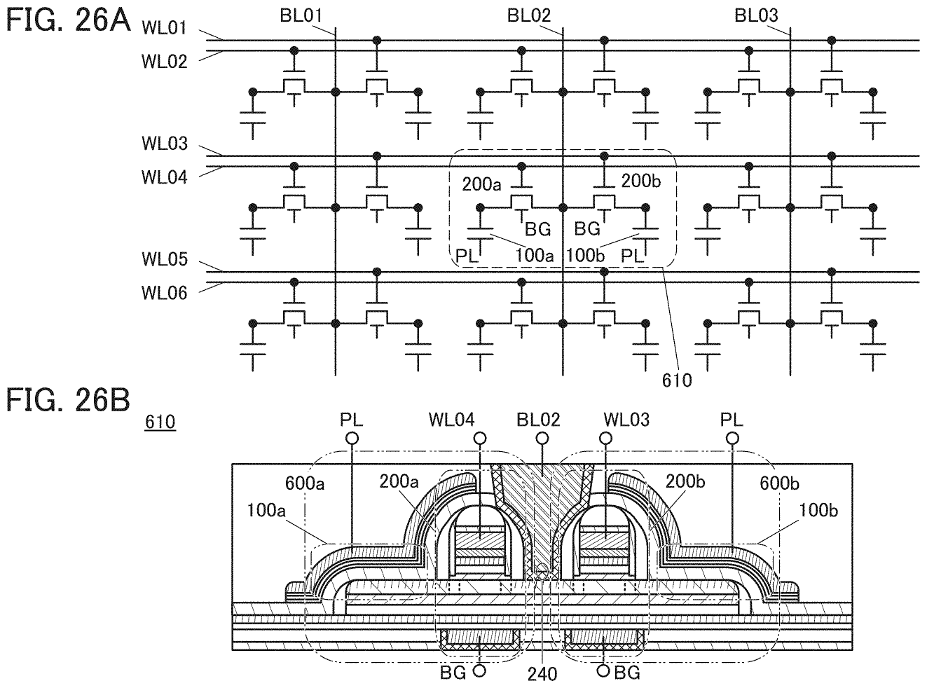

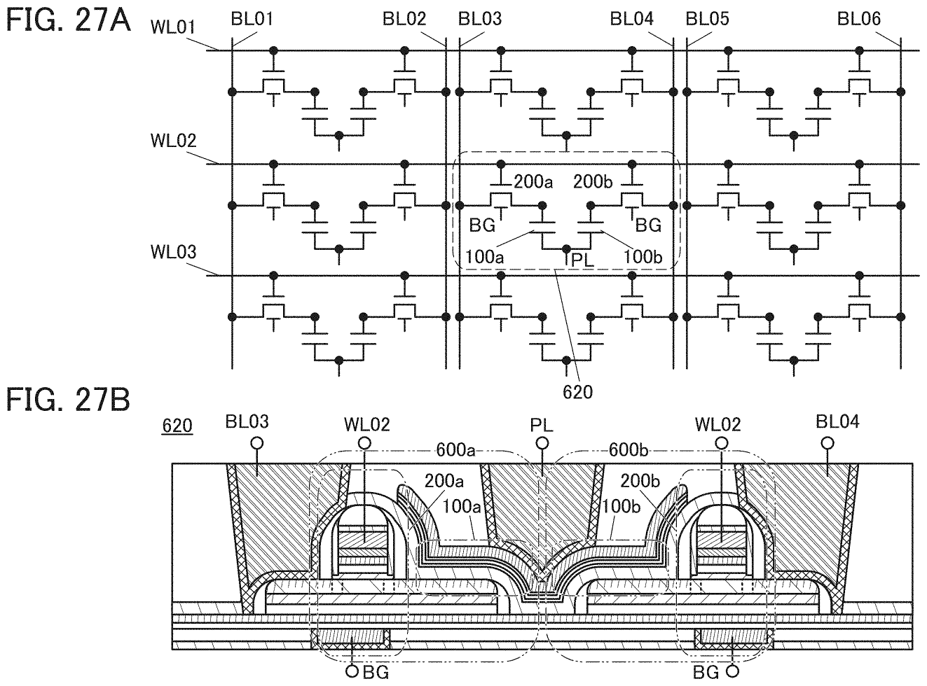

The conductor 120 is preferably formed using a conductive material containing tungsten, copper, or aluminum as its main component. Although not illustrated, the conductor 120 may have a stacked-layer structure, for example, a stacked layer of titanium, titanium nitride, and any of the above conductive materials.

<Structure of cell array> FIGS. 26A and 26B and FIGS. 27A and 27B illustrate examples of cell arrays of this embodiment. For example, the cells 600 each including the transistor 200 and the capacitor 100 illustrated in FIGS. 25A to 25C are arranged in a matrix, whereby a cell array can be formed.

FIG. 26A is a circuit diagram showing an embodiment in which the cells 600 in FIGS. 25A to 25C are arranged in a matrix. In FIG. 26A, one of a source and a drain of each of the transistors included in the cells 600 which are adjacent in the row direction are electrically connected to common BLs (BL01, BL02, and BL03). Furthermore, the BLs are also electrically connected to one of the source and the drain of each of the transistors included in the cells 600 arranged in the column direction. In contrast, the first gates of transistors included in the cells 600 which are adjacent in the row direction are electrically connected to different WLs (WL01 to WL06). In addition, the transistors included in the cells 600 may each be provided with a second gate BG. The threshold voltage of the transistor can be controlled by a potential applied to the BG. The first electrode of the capacitor included in the cell 600 is electrically connected to the other of the source and the drain of the transistor. At this time, the first electrode of the capacitor is formed using part of components of the transistor. In addition, the second electrode of the capacitor included in the cell 600 is electrically connected to a PL.

FIG. 26B is a cross-sectional view which illustrates part of a row including a circuit 610 including a cell 600a electrically connected to a WL04 and the BL02 and a cell 600b electrically connected to the WL03 and the BL02 in FIG. 26A. FIG. 26B illustrates a cross-sectional view of the cell 600a and the cell 600b.

The cell 600a includes a transistor 200a and a capacitor 100a. The cell 600b includes a transistor 200b and a capacitor 100b.

One of a source and a drain of the transistor 200a and one of a source and a drain of the transistor 200b are both electrically connected to the BL02.

In the above-described structure, line sharing of a wiring which is electrically connected to one of a source and a drain is possible; thus, the area occupied by the cell array can be further reduced.

FIG. 27A is a circuit diagram showing an embodiment, which is different from that in FIG. 26A, in which the cells 600 in FIGS. 25A to 25C are arranged in a matrix. In FIG. 27A, first gates of transistors included in the cells 600 arranged in the row direction are electrically connected to common WLs (WL01, WL02, and WL03). Furthermore, one of a source and a drain of each of the transistors included in the cells 600 arranged in the column direction are electrically connected to common BLs (BL01 to BL06). In addition, the transistors included in the cells 600 may each be provided with the second gate BG. The threshold voltage of the transistor can be controlled by a potential applied to the BG. The first electrode of the capacitor included in the cell 600 is electrically connected to the other of the source and the drain of the transistor. At this time, the first electrode of the capacitor is formed using part of components of the transistor. In addition, the second electrode of the capacitor included in the cell 600 is electrically connected to the PL. As illustrated in FIG. 27A, second electrodes of capacitors of the cell 600 and the adjacent cell 600 may be connected to the same PL.

FIG. 27B is a cross-sectional view which illustrates part of a row including a circuit 620 including the cell 600a electrically connected to the WL02 and the BL03 and the cell 600b electrically connected to the WL02 and the BL04 in FIG. 27A. FIG. 27B illustrates a cross-sectional view of the cell 600a and the cell 600b.

The cell 600a includes the transistor 200a and the capacitor 100a. The cell 600b includes the transistor 200b and the capacitor 100b.

The same conductor is used for the second electrode of the capacitor 100a and the second electrode of the capacitor 100b and the conductor is electrically connected to the PL.

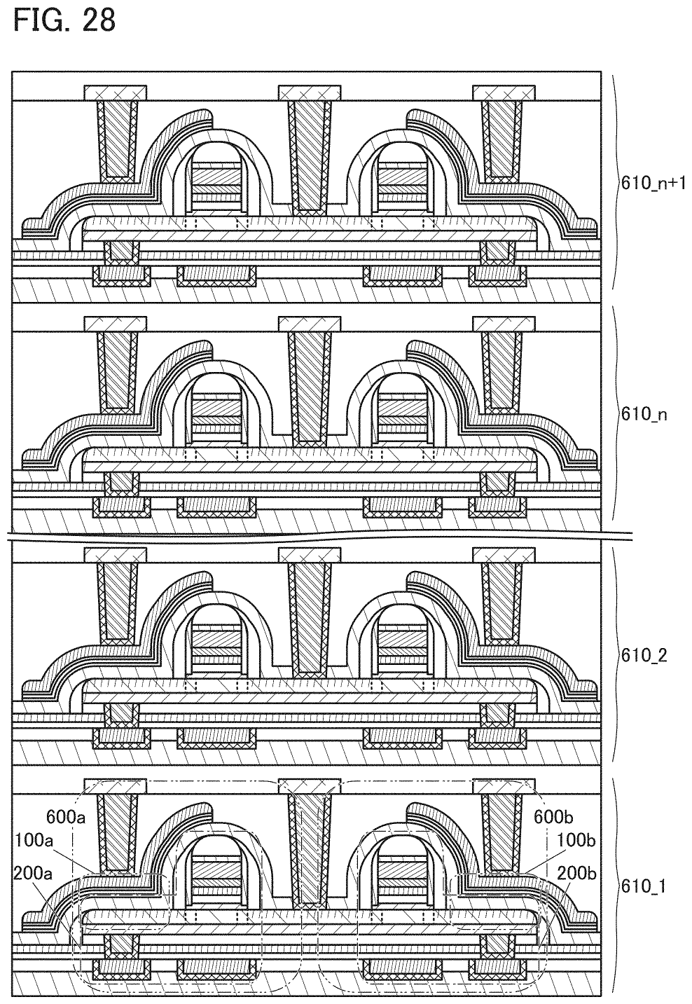

Not only the cells 600 are arranged side by side but also the cells 600 may be stacked. FIG. 28 illustrates a cross-sectional view of a structure in which n+1 cell arrays each including the circuit 610 are stacked. When a plurality of cell arrays are stacked as illustrated in FIG. 28, cells can be provided in an integrated manner without increasing the occupation area of the cell arrays. That is, a 3D cell array can be formed.

As described above, the compositions, structures, methods, and the like described in this embodiment can be combined with any of the compositions, structures, methods, and the like described in the other embodiments as appropriate.

### Embodiment 4

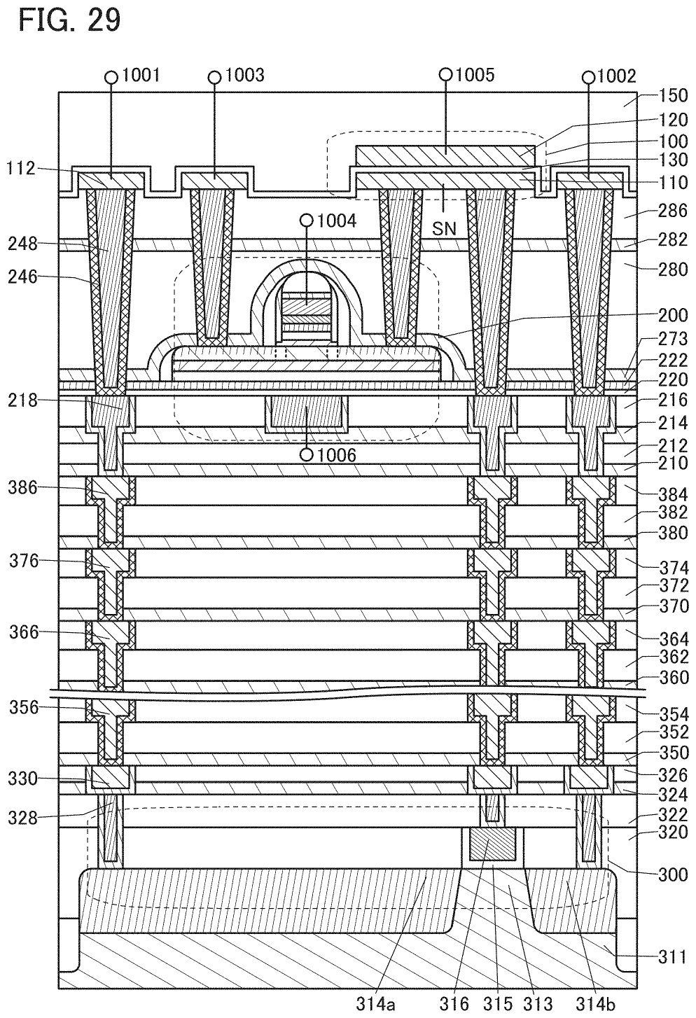

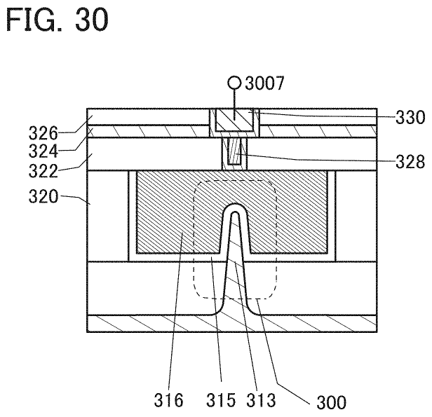

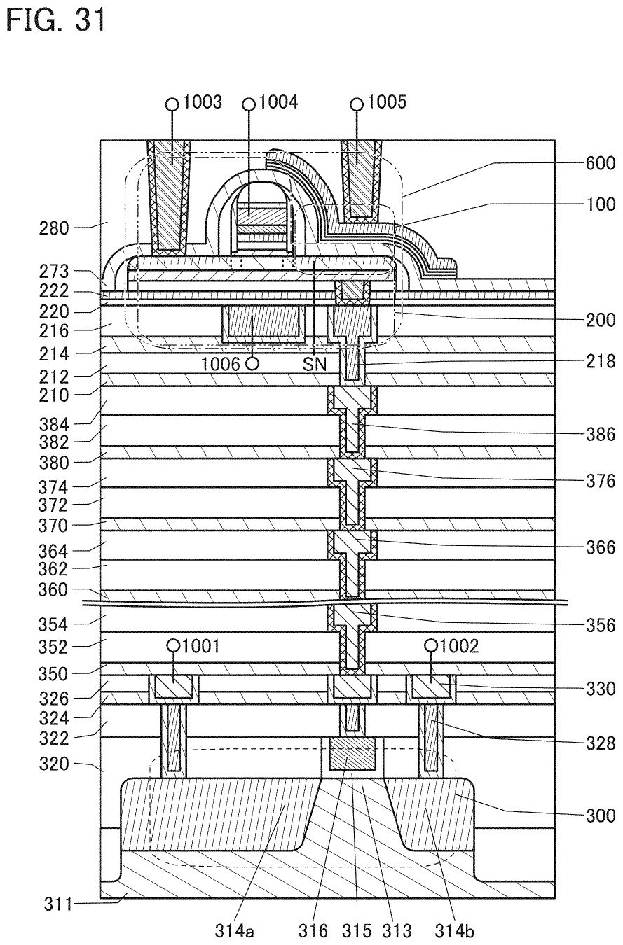

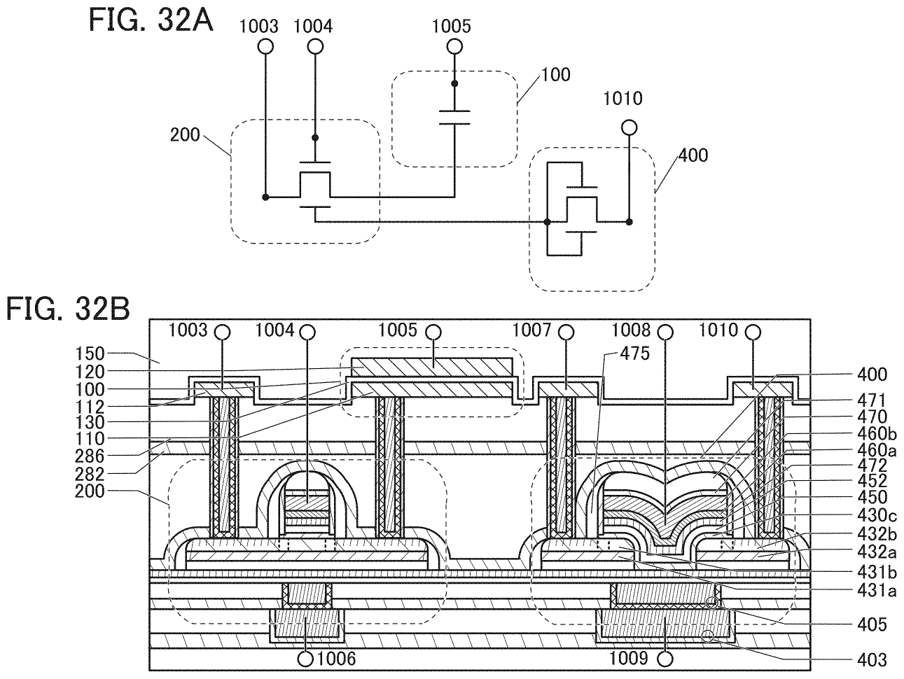

In this embodiment, one embodiment of a semiconductor device will be described with reference to FIG. 29, FIG. 30, FIG. 31, FIGS. 32A and 32B, FIG. 33, and FIG. 34.

<Memory device 1> A memory device illustrated in FIG. 29, FIG. 30, and FIG. 31 includes a transistor 300, the transistor 200, and the capacitor 100. FIG. 29 and FIG. 31 are cross-sectional views in the channel length direction of the transistors 200 and 300. FIG. 30 is a cross-sectional view in the channel width direction of the transistor 300 and its periphery.

The transistor 200 is a transistor whose channel is formed in a semiconductor layer containing an oxide semiconductor. Since the off-state current of the transistor 200 is low, a memory device including the transistor 200 can retain stored data for a long time. In other words, such a memory device does not require refresh operation or has an extremely low frequency of the refresh operation, which leads to a sufficient reduction in power consumption of the memory device.

In the memory devices illustrated in FIG. 29 and FIG. 31, a wiring 1001 is electrically connected to a source of the transistor 300. A wiring 1002 is electrically connected to a drain of the transistor 300. A wiring 1003 is electrically connected to one of the source and the drain of the transistor 200. A wiring 1004 is electrically connected to a top gate of the transistor 200. A wiring 1006 is electrically connected to a bottom gate of the transistor 200. A gate of the transistor 300 and the other of the source and the drain of the transistor 200 are electrically connected to one electrode of the capacitor 100. A wiring 1005 is electrically connected to the other electrode of the capacitor 100.

The memory devices illustrated in FIG. 29 and FIG. 31 has a feature that the potential of the gate of the transistor 300 can be retained and thus enables writing, retaining, and reading of data as follows.

Writing and retaining of data are described. First, the potential of the wiring 1004 is set to a potential at which the transistor 200 is turned on, so that the transistor 200 is turned on. Accordingly, the potential of the wiring 1003 is supplied to a node SN where the gate of the transistor 300 and one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 1004 is set to a potential at which the transistor 200 is turned off, so that the transistor 200 is turned off. Thus, the charge is retained in the node SN (retaining).

In the case where the off-state current of the transistor 200 is low, the charge of the node SN is retained for a long time.

Next, reading of data is described. An appropriate potential (reading potential) is supplied to the wiring 1005 while a predetermined potential (constant potential) is supplied to the wiring 1001, whereby the potential of the wiring 1002 varies depending on the amount of charge retained in the node SN. This is because in the case of using an n-channel transistor as the transistor 300, an apparent threshold voltage V_{th_H} at the time when a high-level charge is given to the gate of the transistor 300 is lower than an apparent threshold voltage V_{th_L} at the time when a low-level charge is given to the gate of the transistor 300. Here, an apparent threshold voltage refers to the potential of the wiring 1005 which is needed to turn on the transistor 300. Thus, the potential of the wiring 1005 is set to a potential V₀ which is between V_{th_H} and V_{th_L}, whereby the charge supplied to the node SN can be determined. For example, in the case where a high-level charge is supplied to the node SN in writing and the potential of the wiring 1005 is V₀ (>V_{th_H}), the transistor 300 is turned on. Meanwhile, in the case where a low-level charge is supplied to the node SN in writing, the transistor 300 remains off even when the potential of the wiring 1005 is V₀ (<V_{th_L}). Thus, the data retained in the node SN can be read by determining the potential of the wiring 1002.

<Structure of memory device 1> The memory device of one embodiment of the present invention includes the transistor 300, the transistor 200, and the capacitor 100 as illustrated in FIG. 29. The transistor 200 is provided above the transistor 300, and the capacitor 100 is provided above the transistor 300 and the transistor 200.

The transistor 300 is provided in and on a substrate 311 and includes a conductor 316, an insulator 315, a semiconductor region 313 that is a part of the substrate 311, and a low-resistance region 314a and a low-resistance region 314b functioning as a source region and a drain region.

As illustrated in FIG. 30, the top surface and the side surface in the channel width direction of the semiconductor region 313 of the transistor 300 is covered with the conductor 316 with the insulator 315 positioned therebetween. In this way, the effective channel width is increased in the Fin-type transistor 300, whereby the on-state characteristics of the transistor 300 can be improved. In addition, since contribution of the electric field of the gate electrode can be increased, the off-state characteristics of the transistor 300 can be improved.

The transistor 300 is either a p-channel transistor or an n-channel transistor.

It is preferable that a region of the semiconductor region 313 where a channel is formed, a region in the vicinity thereof, the low-resistance regions 314a and 314b functioning as the source and drain regions, and the like contain a semiconductor such as a silicon-based semiconductor, further preferably single crystal silicon. Alternatively, a material containing germanium (Ge), silicon germanium (SiGe), gallium arsenide (GaAs), gallium aluminum arsenide (GaAlAs), or the like may be contained. Silicon whose effective mass is adjusted by applying stress to the crystal lattice and thereby changing the lattice spacing may be contained. Alternatively, the transistor 300 may be a high-electron-mobility transistor (HEMT) with GaAs and GaAlAs, or the like.

The low-resistance regions 314a and 314b contain an element which imparts n-type conductivity, such as arsenic or phosphorus, or an element which imparts p-type conductivity, such as boron, in addition to the semiconductor material used for the semiconductor region 313.

The conductor 316 functioning as a gate electrode can be formed using a semiconductor material such as silicon containing the element which imparts n-type conductivity, such as arsenic or phosphorus, or the element which imparts p-type conductivity, such as boron, or using a conductive material such as a metal material, an alloy material, or a metal oxide material.

Note that since the work function of a conductor depends on a material of the conductor, the threshold voltage can be adjusted by changing the material of the conductor. Specifically, it is preferable to use titanium nitride, tantalum nitride, or the like for the conductor. Furthermore, in order to ensure the conductivity and embeddability, it is preferable to use a stacked layer of metal materials such as tungsten and aluminum for the conductor. It is particularly preferable to use tungsten in terms of heat resistance.

Note that the transistor 300 illustrated in FIG. 29 is only an example and the structure of the transistor 300 is not limited to that illustrated in FIG. 29; a transistor appropriate for a circuit configuration or a driving method can be used.

An insulator 320, an insulator 322, an insulator 324, and an insulator 326 are stacked sequentially to cover the transistor 300.

The insulator 320, the insulator 322, the insulator 324, and the insulator 326 can be formed using, for example, silicon oxide, silicon oxynitride, silicon nitride oxide, silicon nitride, aluminum oxide, aluminum oxynitride, aluminum nitride oxide, or aluminum nitride.

The insulator 322 may function as a planarization film for eliminating a level difference caused by the transistor 300 or the like underlying the insulator 322. For example, the top surface of the insulator 322 may be planarized by planarization treatment using a chemical mechanical polishing (CMP) method or the like to increase the level of planarity.

The insulator 324 is preferably formed using a film having a barrier property that prevents hydrogen or impurities from the substrate 311, the transistor 300, or the like from diffusing to a region where the transistor 200 is provided.

For the film having a barrier property against hydrogen, silicon nitride formed by a CVD method can be used, for example. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm², in the TDS analysis at a film surface temperature of the insulator 324 of higher than or equal to 50° C. and lower than or equal to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 or less times that of the insulator 324, further preferably 0.6 or less times that of the insulator 324. In the case where a material with a low permittivity is used for an interlayer film, the parasitic capacitance between wirings can be reduced.

A conductor 328, a conductor 330, and the like that are electrically connected to the capacitor 100 or the transistor 200 are provided in the insulator 320, the insulator 322, the insulator 324, and the insulator 326. Note that the conductor 328 and the conductor 330 each function as a plug or a wiring. A plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and another part of the conductor functions as a plug.

As a material for each of plugs and wirings (e.g., the conductor 328 and the conductor 330), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 29, an insulator 350, an insulator 352, and an insulator 354 are stacked sequentially. Furthermore, a conductor 356 is formed in the insulator 350, the insulator 352, and the insulator 354. The conductor 356 functions as a plug or a wiring. Note that the conductor 356 can be formed using a material similar to those for the conductor 328 and the conductor 330.

Note that the insulator 350 is preferably formed using an insulator having a barrier property against hydrogen, as with the insulator 324, for example. Furthermore, the conductor 356 preferably contains a conductor having a barrier property against hydrogen. In particular, the conductor having a barrier property against hydrogen is formed in an opening of the insulator 350 having a barrier property against hydrogen. In such a structure, the transistor 300 and the transistor 200 can be separated by a barrier layer, so that the diffusion of hydrogen from the transistor 300 to the transistor 200 can be prevented.

Note that as the conductor having a barrier property against hydrogen, tantalum nitride is preferably used, for example. The use of a stack including tantalum nitride and tungsten having high conductivity can inhibit the diffusion of hydrogen from the transistor 300 while the conductivity of a wiring is ensured. In that case, the tantalum nitride layer having a barrier property against hydrogen is preferably in contact with the insulator 350 having a barrier property against hydrogen.

A wiring layer may be provided over the insulator 354 and the conductor 356. For example, in FIG. 29, an insulator 360, an insulator 362, and an insulator 364 are stacked sequentially. Furthermore, a conductor 366 is formed in the insulator 360, the insulator 362, and the insulator 364. The conductor 366 functions as a plug or a wiring. Note that the conductor 366 can be formed using a material similar to those for the conductor 328 and the conductor 330.

Note that the insulator 360 is preferably formed using an insulator having a barrier property against hydrogen, as with the insulator 324, for example. Furthermore, the conductor 366 preferably contains a conductor having a barrier property against hydrogen. In particular, the conductor having a barrier property against hydrogen is formed in an opening of the insulator 360 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 364 and the conductor 366. For example, in FIG. 29, an insulator 370, an insulator 372, and an insulator 374 are stacked sequentially. Furthermore, a conductor 376 is formed in the insulator 370, the insulator 372, and the insulator 374. The conductor 376 functions as a plug or a wiring. Note that the conductor 376 can be formed using a material similar to those for the conductor 328 and the conductor 330.

Note that the insulator 370 is preferably formed using an insulator having a barrier property against hydrogen, as with the insulator 324, for example. Furthermore, the conductor 376 preferably contains a conductor having a barrier property against hydrogen. In particular, the conductor having a barrier property against hydrogen is formed in an opening of the insulator 370 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 374 and the conductor 376. For example, in FIG. 29, an insulator 380, an insulator 382, and an insulator 384 are stacked sequentially. Furthermore, a conductor 386 is formed in the insulator 380, the insulator 382, and the insulator 384. The conductor 386 functions as a plug or a wiring. Note that the conductor 386 can be formed using a material similar to those for the conductor 328 and the conductor 330.

Note that the insulator 380 is preferably formed using an insulator having a barrier property against hydrogen, as with the insulator 324, for example. Furthermore, the conductor 386 preferably contains a conductor having a barrier property against hydrogen. In particular, the conductor having a barrier property against hydrogen is formed in an opening of the insulator 380 having a barrier property against hydrogen. In such a structure, the transistor 300 and the transistor 200 can be separated by a barrier layer, so that the diffusion of hydrogen from the transistor 300 to the transistor 200 can be prevented.

Although the wiring layer including the conductor 356, the wiring layer including the conductor 366, the wiring layer including the conductor 376, and the wiring layer including the conductor 386 are described above, the memory device of this embodiment is not limited thereto. The number of wiring layers similar to the wiring layer including the conductor 356 may be three or less or five or more.

The insulator 210, the insulator 212, the insulator 214, and the insulator 216 are stacked sequentially over the insulator 384. A material having a barrier property against oxygen or hydrogen is preferably used for one of the insulators 210, 212, 214, and 216.

For example, each of the insulator 210 and the insulator 214 is preferably formed using a film having a barrier property that prevents hydrogen or impurities from the substrate 311, a region where the transistor 300 is provided, or the like from diffusing to a region where the transistor 200 is provided. Therefore, each of the insulator 210 and the insulator 214 can be formed using a material similar to that for the insulator 324.

For the film having a barrier property against hydrogen, silicon nitride formed by a CVD method can be used, for example. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which a small amount of hydrogen is released.

For the film having a barrier property against hydrogen used for the insulator 210 and the insulator 214, for example, a metal oxide such as aluminum oxide, hafnium oxide, or tantalum oxide is preferably used.

In particular, aluminum oxide has an excellent blocking effect that prevents permeation of oxygen and impurities such as hydrogen and moisture which cause a change in electrical characteristics of the transistor. Accordingly, the use of aluminum oxide can prevent the entry of impurities such as hydrogen and moisture into the transistor 200 during and after a manufacturing process of the transistor. In addition, release of oxygen from the oxide contained in the transistor 200 can be prevented. Therefore, aluminum oxide is suitably used for a protective film of the transistor 200.

The insulator 212 and the insulator 216 can be formed using a material similar to that for the insulator 320, for example. In the case where a material with a relatively low permittivity is used for an interlayer film, the parasitic capacitance between wirings can be reduced. A silicon oxide film or a silicon oxynitride film can be used for the insulators 212 and 216, for example.

A conductor 218, a conductor (the conductor 205) included in the transistor 200, and the like are provided in the insulators 210, 212, 214, and 216. Note that the conductor 218 functions as a plug or a wiring that is electrically connected to the capacitor 100 or the transistor 300. The conductor 218 can be formed using a material similar to those for the conductors 328 and 330.

In particular, part of the conductor 218 that is in contact with the insulators 210 and 214 is preferably a conductor having a barrier property against oxygen, hydrogen, and water. In such a structure, the transistors 300 and 200 can be separated by a layer having a barrier property against oxygen, hydrogen, and water. As a result, the diffusion of hydrogen from the transistor 300 to the transistor 200 can be prevented.

The transistor 200 is provided over the insulator 216. Note that the structure of the transistor of the semiconductor device described in the above embodiment can be used as the structure of the transistor 200 described here. Note that the transistor 200 in FIG. 29 is only an example and the structure of the transistor 200 is not limited to that illustrated in FIG. 29; a transistor appropriate for a circuit configuration or a driving method can be used.

The insulator 280 is provided over the transistor 200.

An insulator 282 is provided over the insulator 280. A material having a barrier property against oxygen or hydrogen is preferably used for the insulator 282. Thus, the insulator 282 can be formed using a material similar to that used for forming the insulator 214. For the insulator 282, a metal oxide such as aluminum oxide, hafnium oxide, or tantalum oxide is preferably used, for example.

In particular, aluminum oxide has an excellent blocking effect that prevents permeation of oxygen and impurities such as hydrogen and moisture which cause a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide contained in the transistor 200 can be prevented. Therefore, aluminum oxide is suitably used for a protective film of the transistor 200.

An insulator 286 is provided over the insulator 282. The insulator 286 can be formed using a material similar to that used for forming the insulator 320. In the case where a material with a relatively low permittivity is used for an interlayer film, the parasitic capacitance between wirings can be reduced. For example, a silicon oxide film, a silicon oxynitride film, or the like can be used for the insulator 286.

A conductor 246, a conductor 248, and the like are provided in the insulators 220, 222, 280, 282, and 286.

The conductors 246 and 248 function as plugs or wirings that are electrically connected to the capacitor 100, the transistor 200, or the transistor 300. The conductors 246 and 248 can be formed using a material similar to those used for forming the conductors 328 and 330.

The capacitor 100 is provided above the transistor 200. The capacitor 100 includes a conductor 110, a conductor 120, and an insulator 130.

A conductor 112 may be provided over the conductors 246 and 248. The conductor 112 functions as a plug or a wiring that is electrically connected to the capacitor 100, the transistor 200, or the transistor 300. The conductor 110 functions as the electrode of the capacitor 100. The conductor 112 and the conductor 110 can be formed at the same time.

The conductor 112 and the conductor 110 can be formed using a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added.

The conductor 112 and the conductor 110 each have a single-layer structure in FIG. 29; however, one embodiment of the present invention is not limited thereto, and a stacked-layer structure of two or more layers may be used. For example, between a conductor having a barrier property and a conductor having high conductivity, a conductor which is highly adhesive to the conductor having a barrier property and the conductor having high conductivity may be formed.

As a dielectric of the capacitor 100, the insulator 130 is provided over the conductors 112 and 110. The insulator 130 can be formed to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

A material with high dielectric strength, such as silicon oxynitride, is preferably used for the insulator 130, for example. In the capacitor 100 having such a structure, the dielectric strength can be increased and the electrostatic breakdown of the capacitor 100 can be prevented because of the insulator 130.

Over the insulator 130, the conductor 120 is provided so as to overlap with the conductor 110. Note that the conductor 120 can be formed using a conductive material such as a metal material, an alloy material, or a metal oxide material. It is preferable to use a high-melting-point material which has both heat resistance and conductivity, such as tungsten or molybdenum, and it is particularly preferable to use tungsten. In the case where the conductor 120 is formed concurrently with another component such as a conductor, copper (Cu), aluminum (A1), or the like which is a low-resistance metal material can be used.

An insulator 150 is provided over the conductor 120 and the insulator 130. The insulator 150 can be formed using a material similar to that used for forming the insulator 320. The insulator 150 may function as a planarization film that covers a roughness thereunder.

With the use of the structure, a change in electrical characteristics can be prevented and reliability can be improved in a semiconductor device including a transistor including an oxide semiconductor. A transistor including an oxide semiconductor with a high on-state current can be provided. A transistor including an oxide semiconductor with a low off-state current can be provided. A semiconductor device with low power consumption can be provided.

<Modification example of memory device 1> An example of the memory device of one embodiment of the present invention is described with reference to FIG. 31.

FIG. 31 is a cross-sectional view of a memory device including the capacitor 100, the transistor 200, and the transistor 300. Note that in the memory device illustrated in FIG. 31, components having the same functions as the components in the semiconductor device described in the above embodiment and <Structure of memory device 1> are denoted by the same reference numerals.

The memory device illustrated in FIG. 31 is different from that in <Structure of memory device 1> in including the cell 600 described in the above embodiment.

Specifically, the memory device illustrated in FIG. 31 includes the cell 600 in which the capacitor 100 and the transistor 200 share some components.

In the above structure, the cell 600 and the transistor 300 partly or entirely overlap with each other, so that the total area of the projected area of the memory device can be reduced. Accordingly, the cell 600 can be easily miniaturized or highly integrated and manufacturing process can be simplified.

<Memory device 2> A semiconductor device illustrated in FIGS. 32A and 32B is a memory device including a transistor 400, the transistor 200, and the capacitor 100. One embodiment of the memory device is described below with reference to FIGS. 32A and 32B.

FIG. 32A is a circuit diagram showing an example of the connection relationship of the transistor 200, the transistor 400, and the capacitor 100 in the semiconductor device described in this embodiment. FIG. 32B is a cross-sectional view of the semiconductor device in which the wirings 1004 to 1010 and the like correspond to those in FIG. 32A.

The transistors 200 and 400 formed over a substrate (not illustrated) have different structures. For example, the transistor 400 may have a smaller drain current than the transistor 200 when a bottom gate voltage and a top gate voltage are each 0 V. The transistor 400 is a switching element capable of controlling the potential of the bottom gate of the transistor 200. Therefore, a charge at a node connected to the bottom gate of the transistor 200 can be prevented from being lost by making the node have a desired potential and then turning off the transistor 400.

As illustrated in FIGS. 32A and 32B, in the transistor 200, the gate is electrically connected to the wiring 1004, one of the source and the drain is electrically connected to the wiring 1003, and the other of the source and the drain is electrically connected to one electrode of the capacitor 100. The other electrode of the capacitor 100 is electrically connected to the wiring 1005. A drain of the transistor 400 is electrically connected to the wiring 1010. As illustrated in FIG. 32B, the bottom gate of the transistor 200 and the source, a top gate, and a bottom gate of the transistor 400 are electrically connected through the wiring 1006, the wiring 1007, the wiring 1008, and the wiring 1009.

The on/off state of the transistor 200 can be controlled by application of a potential to the wiring 1004. When the transistor 200 is on to apply a potential to the wiring 1003, charges can be supplied to the capacitor 100 through the transistor 200. At this time, by making the transistor 200 off, the charges supplied to the capacitor 100 can be held. By application of a given potential to the wiring 1005, the potential of a connection portion between the transistor 200 and the capacitor 100 can be controlled by capacitive coupling. For example, when a ground potential is applied to the wiring 1005, the charges are held easily. Furthermore, by application of a negative potential to the wiring 1010, the negative potential is applied to the bottom gate of the transistor 200 through the transistor 400, whereby the threshold voltage of the transistor 200 can be higher than 0 V, the off-state current can be reduced, and I_{cut} can be noticeably reduced. Note that I_{cut} refers to a drain current when voltage applied to the top gate is 0 V.

With a structure in which the top gate and the bottom gate of the transistor 400 are diode-connected to the source, and a source of the transistor 400 and the bottom gate of the transistor 200 are connected, the bottom-gate voltage of the transistor 200 can be controlled by the wiring 1010. When the negative potential of the bottom gate of the transistor 200 is held, the voltage between the top gate and the source of the transistor 400 and the voltage between the bottom gate and the source of the transistor 400 are each 0 V. Since the I_{cut} of the transistor 400 is extremely small and the threshold voltage of the transistor 400 is higher than that of the transistor 200, the structure allows the negative potential of the bottom gate of the transistor 200 to be held for a long time without supply of power to the transistor 400.

Moreover, the negative potential of the bottom gate of the transistor 200 is held, in which case I_{cut} of the transistor 200 can be noticeably reduced even without supply of power to the transistor 200. In other words, the charges can be held in the capacitor 100 for a long time even without supply of power to the transistor 200 and the transistor 400. For example, with the use of the semiconductor device as a memory element, data can be held for a long time without power supply. Therefore, a memory device with a low refresh frequency or a memory device that does not need refresh operation can be provided.

Note that the connection relationship of the transistor 200, the transistor 400, and the capacitor 100 is not limited to that illustrated in FIGS. 32A and 32B. The connection relationship can be modified as appropriate in accordance with a necessary circuit configuration.

<Structure of memory device 2> FIG. 32B is a cross-sectional view of a memory device including the capacitor 100, the transistor 200, and the transistor 400. Note that in the memory device illustrated in FIGS. 32A and 32B, components having the same functions as the components in the semiconductor device described in the above embodiment and <Structure of memory device 1> are denoted by the same reference numerals.

The memory device of one embodiment of the present invention includes the transistor 200, the transistor 400, and the capacitor 100 as illustrated in FIGS. 32A and 32B. The transistor 200 and the transistor 400 are provided in the same layer, and the capacitor 100 is provided above the transistor 400 and the transistor 200.

Note that the capacitor and the transistor included in the semiconductor device described in the above embodiments with reference to FIG. 29 and FIG. 31 can be used as the capacitor 100 and the transistor 200. Note that the capacitor 100, the transistor 300, the transistor 200, and the transistor 400 illustrated in FIGS. 32A and 32B are only examples and the structures of those are not limited to the structures illustrated in FIGS. 32A and 32B; a transistor appropriate for a circuit configuration or a driving method can be used.

The transistor 400 and the transistor 200 are formed in the same layer and thus can be fabricated in parallel. The transistor 400 includes a conductor 460 (a conductor 460a and a conductor 460b) functioning as a top gate electrode, a conductor 405 functioning as a bottom gate electrode, insulators 470 and 472 in contact with the conductor 460, an insulator 475 provided on the side surface of the conductor 460 with the insulator 472 positioned therebetween, the insulators 220, 222, and 224 and an insulator 450 functioning as gate insulating layers, an oxide 430c including a region where a channel is formed, oxides 431a and 431b functioning as one of a source and a drain, and oxides 432a and 432b functioning as the other of the source and the drain. The conductor 405 functioning as a bottom gate electrode is electrically connected to a conductor 403 functioning as a wiring.

In the transistor 400, the conductor 405 is in the same layer as the conductor 205. The oxides 431a and 432a are in the same layer as the oxide 230a, and the oxides 431b and 432b are in the same layer as the oxide 230b. The oxide 430c is in the same layer as the oxide 230c. The insulator 450 is in the same layer as the insulator 250. A metal oxide 452 is in the same layer as the metal oxide 252. The conductor 460 is in the same layer as the conductor 260. The insulator 470 is in the same layer as the insulator 270. The insulator 472 is in the same layer as the insulator 272. The insulator 475 is in the same layer as the insulator 275.

In the oxide 430c functioning as an active layer of the transistor 400, oxygen vacancies and impurities such as water or hydrogen are reduced, as in the oxide 230 or the like. Accordingly, the threshold voltage of the transistor 400 can be higher than 0 V, an off-state current can be reduced, and the drain current when the bottom gate voltage and the top gate voltage are 0 V can be extremely low.

As described above, the oxides 431a and 432a are in the same layer as the oxide 230a, and the oxides 431b and 432b are in the same layer as the oxide 230b. Thus, low-resistance regions corresponding to the regions 231a and 231b are formed in the oxides 431a, 432a, 431b, and 432b.

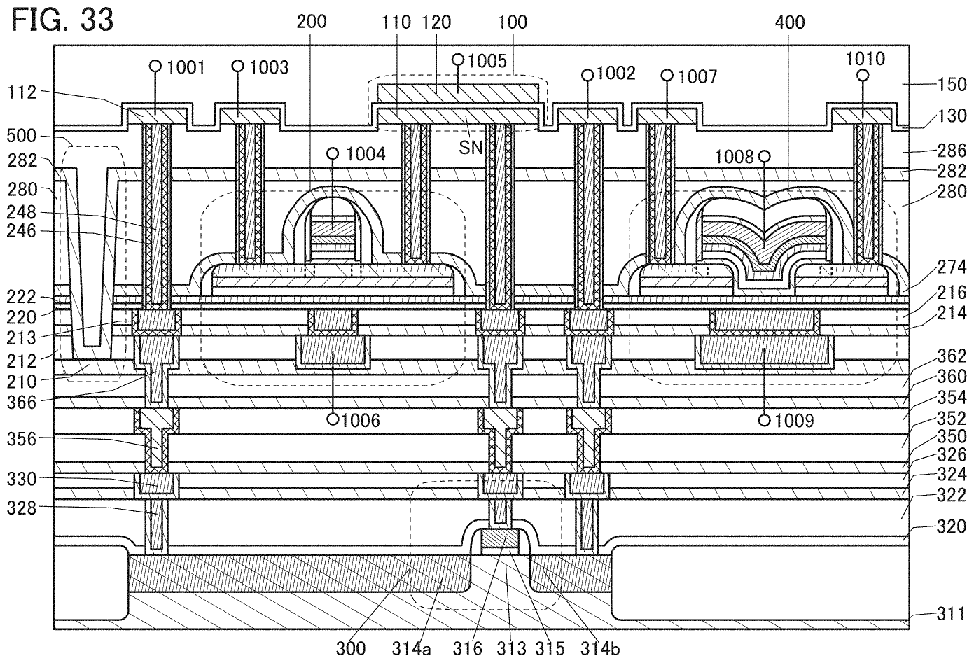

With the use of the structure, a change in electrical characteristics can be prevented and reliability can be improved in a semiconductor device including a transistor including an oxide semiconductor. The power consumption of a semiconductor device including a transistor including an oxide semiconductor can be reduced. A semiconductor device including a transistor including an oxide semiconductor can be miniaturized or highly integrated. A miniaturized or highly integrated semiconductor device can be provided with high productivity.

<Memory device 3> A semiconductor device illustrated in FIG. 33 is a memory device including the transistor 300, the transistor 200, and the capacitor 100. One embodiment of the memory device is described below with reference to FIG. 33.

The transistor 200 is a transistor in which a channel is formed in a semiconductor layer containing an oxide semiconductor, and can be the transistor described in the above embodiment. Since the transistor described in the above embodiment can be formed with high yield even when it is miniaturized, the transistor 200 can be miniaturized. The use of such a transistor in a memory device allows miniaturization or high integration of the memory device. Since the off-state current of the transistor described in the above embodiment is low, a memory device including the transistor can retain stored data for a long time. In other words, such a memory device does not require refresh operation or has an extremely low frequency of the refresh operation, which leads to a sufficient reduction in power consumption of the memory device.

In FIG. 33, the wiring 1001 is electrically connected to a source of the transistor 300. The wiring 1002 is electrically connected to a drain of the transistor 300. The wiring 1003 is electrically connected to one of a source and a drain of the transistor 200. The wiring 1004 is electrically connected to the top gate of the transistor 200. The wiring 1006 is electrically connected to the bottom gate of the transistor 200. A gate of the transistor 300 and the other of the source and the drain of the transistor 200 are electrically connected to one electrode of the capacitor 100. The wiring 1005 is electrically connected to the other electrode of the capacitor 100.

The wiring 1007 is electrically connected to the source of the transistor 400. The wiring 1008 is electrically connected to a gate of the transistor 400, the wiring 1009 is electrically connected to a back gate of the transistor 400, and the wiring 1010 is electrically connected to the drain of the transistor 400. The wiring 1006, the wiring 1007, the wiring 1008, and the wiring 1009 are electrically connected to each other.

The semiconductor device illustrated in FIG. 33 has a feature that the potential of the gate of the transistor 300 can be retained and thus enable writing, retaining, and reading of data as follows.

Writing and retaining of data are described. First, the potential of the wiring 1004 is set to a potential at which the transistor 200 is turned on, so that the transistor 200 is turned on. Accordingly, the potential of the wiring 1003 is supplied to a node SN where the gate of the transistor 300 and the one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 1004 is set to a potential at which the transistor 200 is turned off, so that the transistor 200 is turned off. Thus, the charge is retained in the node SN (retaining).

In the case where the off-state current of the transistor 200 is low, the charge of the node SN is retained for a long time.

Next, reading of data is described. An appropriate potential (reading potential) is supplied to the wiring 1005 while a predetermined potential (constant potential) is supplied to the wiring 1001, whereby the potential of the wiring 1002 varies depending on the amount of charge retained in the node SN. This is because in the case of using an n-channel transistor as the transistor 300, an apparent threshold voltage V_{th_H} at the time when a high-level charge is given to the gate of the transistor 300 is lower than an apparent threshold voltage V_{th_L} at the time when a low-level charge is given to the gate of the transistor 300. Here, an apparent threshold voltage refers to the potential of the wiring 1005 which is needed to turn on the transistor 300. Thus, the potential of the wiring 1005 is set to a potential V₀ which is between V_{th_H} and V_{th_L}, whereby the charge supplied to the node SN can be determined. For example, in the case where a high-level charge is supplied to the node SN in writing and the potential of the wiring 1005 is V₀ (>V_{th_H}), the transistor 300 is turned on. Meanwhile, in the case where a low-level charge is supplied to the node SN in writing, even when the potential of the wiring 1005 is V₀ (<V_{th_L}), the transistor 300 remains off. Thus, the data retained in the node SN can be read by determining the potential of the wiring 1002.

<Structure example of memory device 3> FIG. 33 is a cross-sectional view of a memory device including the capacitor 100, the transistor 200, the transistor 300, and the transistor 400. Note that in the memory device illustrated in FIG. 33, components having the same functions as the components in the semiconductor device described in the above embodiment, <Structure of memory device 1>, and <Structure of memory device 2> are denoted by the same reference numerals.

The memory device of one embodiment of the present invention includes the transistor 300, the transistor 200, the transistor 400, and the capacitor 100 as illustrated in FIG. 33. The transistor 200 and the transistor 400 are provided above the transistor 300, and the capacitor 100 is provided above the transistor 300, the transistor 200, and the transistor 400.

Note that the capacitor and the transistor included in the semiconductor device described in the above embodiments with reference to FIG. 29, FIG. 30, FIG. 31, and FIGS. 32A and 32B can be used as the capacitor 100, the transistor 200, the transistor 300, and the transistor 400. Note that the capacitor 100, the transistor 300, the transistor 200, and the transistor 400 illustrated in FIG. 33 are only examples and the structures of those are not limited to the structures illustrated in FIG. 33; a transistor appropriate for a circuit configuration or a driving method can be used.

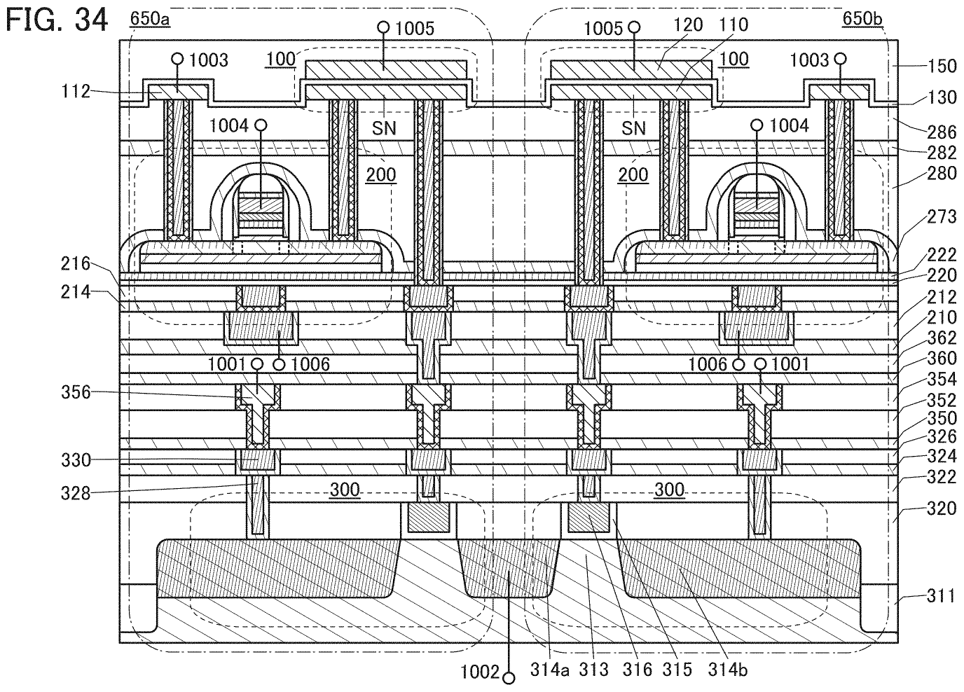

With the use of the structure, a change in electrical characteristics can be prevented and reliability can be improved in a semiconductor device including a transistor including an oxide semiconductor. The power consumption of a semiconductor device including a transistor including an oxide semiconductor can be reduced. A semiconductor device including a transistor including an oxide semiconductor can be miniaturized or highly integrated. A miniaturized or highly integrated semiconductor device can be provided with high productivity.

<Structure of memory cell array> FIG. 34 illustrates an example of a memory cell array of this embodiment. When the transistors 200 are arranged as memory cells in a matrix, a memory cell array can be formed.

The memory device illustrated in FIG. 34 is a semiconductor device constituting a memory cell array in which the memory devices illustrated in FIG. 29 and FIG. 33 are arranged in a matrix. Note that one transistor 400 can control the back-gate voltages of the plurality of transistors 200. For this reason, the number of transistors 400 is preferably smaller than the number of transistors 200.

Accordingly, in FIG. 34, the transistor 400 illustrated in FIG. 33 is omitted. FIG. 34 is a cross-sectional view that illustrates part of a row in which the memory devices illustrated in FIG. 29 and FIG. 33 are arranged in a matrix.

The structure of the transistor 300 in FIG. 34 is different from that of the transistor 300 in FIG. 33. In the transistor 300 illustrated in FIG. 34, the semiconductor region 313 (part of the substrate 311) in which the channel is formed has a protruding shape. Furthermore, the conductor 316 is provided so as to cover the top and side surfaces of the semiconductor region 313 with the insulator 315 positioned therebetween. Note that the conductor 316 may be formed using a material for adjusting the work function. The transistor 300 is also referred to as Fin-type transistors because they each utilize a protruding portion of the semiconductor substrate. An insulator functioning as a mask for forming the protruding portion may be provided in contact with the top surface of the protruding portion. Although the case where the protruding portion is formed by processing part of the semiconductor substrate is described here, a semiconductor film having a protruding shape may be formed by processing an SOI substrate.

In the memory device illustrated in FIG. 34, a memory cell 650a and a memory cell 650b are arranged adjacent to each other. The transistors 300 and 200 and the capacitor 100 are included and electrically connected to the wirings 1001, 1002, 1003, 1004, 1005, and 1006 in each of the memory cells 650a and 650b. Also in the memory cells 650a and 650b, a node where a gate of the transistor 300 and one electrode of the capacitor 100 are electrically connected to each other is referred to as the node SN. Note that the wiring 1002 is shared by the memory cells 650a and 650b adjacent to each other.

In the case where memory cells are arrayed, it is necessary that data of a desired memory cell is read in read operation. For example, in the case of a NOR-type memory cell array, only data of a desired memory cell can be read by turning off the transistors 300 of memory cells from which data is not read. In this case, a configuration may be employed in which only data of a desired memory cell can be read by supplying a potential at which the transistor 300 is turned off regardless of the charge supplied to the node SN, that is, a potential lower than V_{th_H}, is supplied to the wiring 1005 connected to the memory cells from which data is not read. Alternatively, in the case of a NAND-type memory cell array, for example, only data of a desired memory cell can be read by turning on the transistors 300 of memory cells from which data is not read. In this case, a configuration may be employed in which only data of a desired memory cell can be read by supplying a potential at which the transistor 300 is turned on regardless of the charge supplied to the node SN, that is, a potential higher than V_{th_L} is supplied to the wiring 1005 connected to the memory cells from which data is not read.

With the use of the structure, a change in electrical characteristics can be prevented and reliability can be improved in a semiconductor device including a transistor including an oxide semiconductor. The power consumption of a semiconductor device including a transistor including an oxide semiconductor can be reduced. A semiconductor device including a transistor including an oxide semiconductor can be miniaturized or highly integrated. A miniaturized or highly integrated semiconductor device can be provided with high productivity.

As described above, the compositions, structures, methods, and the like described in this embodiment can be combined with any of the compositions, structures, methods, and the like described in the other embodiments as appropriate.

### Embodiment 5

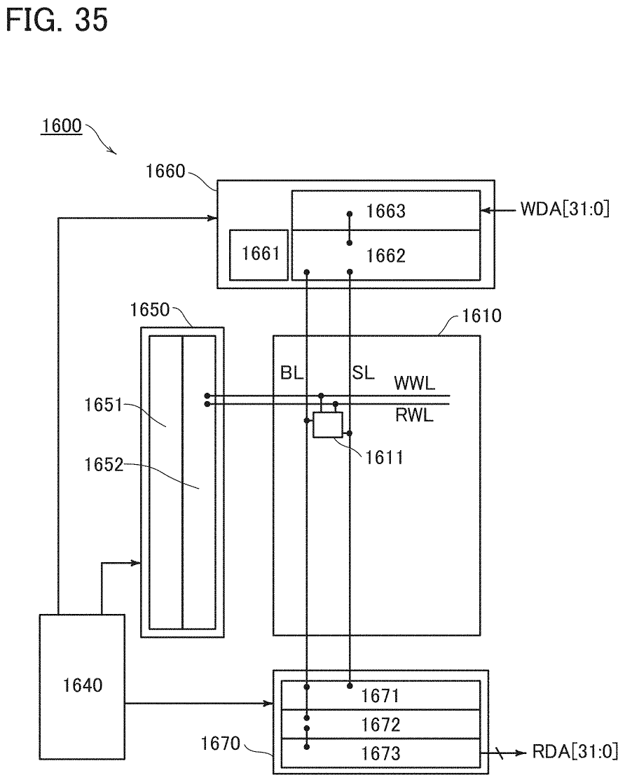

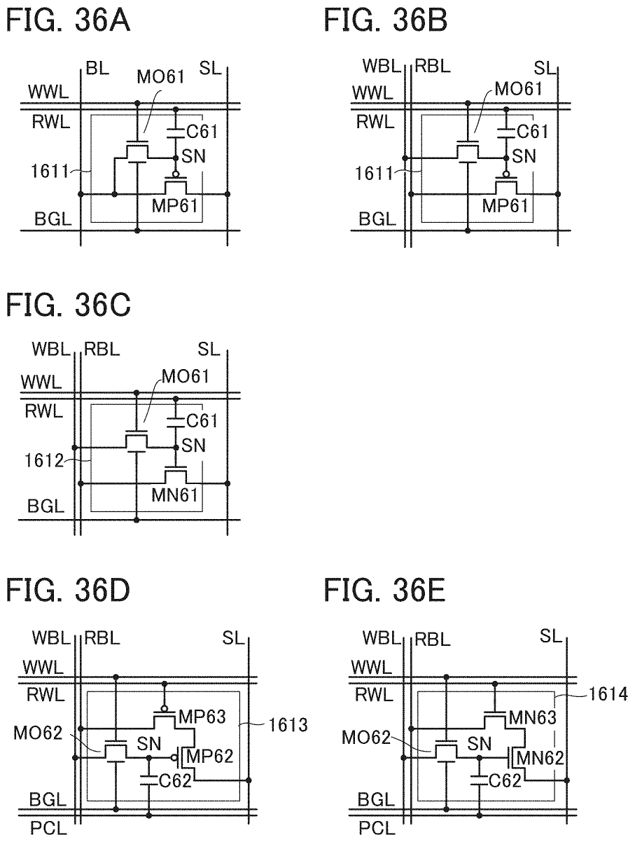

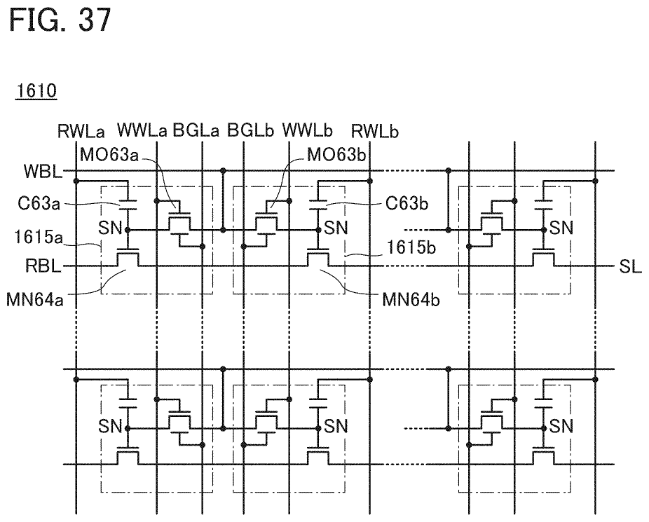

In this embodiment, NOSRAM will be described as an example of a memory device including a transistor in which oxide is used for a semiconductor (hereinafter referred to as an OS transistor) and a capacitor, which is one embodiment of the present invention, with reference to FIG. 35, FIGS. 36A to 36E, and FIG. 37. NOSRAM (registered trademark) is an abbreviation of “nonvolatile oxide semiconductor RAM”, which indicates RAM including a gain cell (2T or 3T) memory cell. Hereinafter, a memory device including an OS transistor, such as NOSRAM, is referred to as an OS memory in some cases.

A memory device in which OS transistors are used in memory cells (hereinafter referred to as an OS memory) is used in NOSRAM. The OS memory is a memory including at least a capacitor and an OS transistor that controls charge and discharge of the capacitor. The OS memory has excellent retention characteristics because the OS transistor has an extremely low off-state current and thus can function as a nonvolatile memory.

<<NOSRAM>> FIG. 35 shows a configuration example of NOSRAM. NOSRAM 1600 in FIG. 35 includes a memory cell array 1610, a controller 1640, a row driver 1650, a column driver 1660, and an output driver 1670. Note that the NOSRAM 1600 is multilevel NOSRAM in which one memory cell stores multilevel data.

The memory cell array 1610 includes a plurality of memory cells 1611, a plurality of word lines WWL, a plurality of word lines RWL, a plurality of bit lines BL, and a plurality of source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals input from the outside (e.g., a chip enable signal and a write enable signal) to generate control signals of the row driver 1650, the column driver 1660, and the output driver 1670.

The row driver 1650 has a function of selecting a row to be accessed. The row driver 1650 includes a row decoder 1651 and a word line driver 1652.

The column driver 1660 drives a source line SL and a bit line BL. The column driver 1660 includes a column decoder 1661, a write driver 1662, and a digital-analog converter circuit (DAC) 1663.

The DAC 1663 converts 3-bit digital data into an analog voltage. The DAC 1663 converts 32-bit data WDA[31:0] into an analog voltage per 3 bits.

The write driver 1662 has a function of precharging the source line SL, a function of bringing the source line SL into an electrically floating state, a function of selecting the source line SL, a function of inputting a writing voltage generated from the DAC 1663 to the selected source line SL, a function of precharging the bit line BL, a function of bringing the bit line BL into an electrically floating state, and the like.

The output driver 1670 includes a selector 1671, an analog-digital converter circuit (ADC) 1672, and an output buffer 1673. The selector 1671 selects a source line SL to be accessed and transmits voltage of the selected source line SL to the ADC 1672. The ADC 1672 has a function of converting an analog voltage into 3-bit digital data. The voltage of the source line SL is converted into 3-bit data in the ADC 1672, and the output buffer 1673 stores the data output from the ADC 1672.

The configuration of the row driver 1650, the column driver 1660, and the output driver 1670 described in this embodiment is not limited to the above configuration. The arrangement of those drivers and wirings connected to the drivers may be changed or the functions of the drivers and the wirings connected to the drivers may be changed or added, depending on the configuration, driving method, or the like of the memory cell array 1610. For example, the bit line BL may have part of a function of the source line SL.

Although the amount of data held in each of the memory cells 1611 is 3 bits in the above description, the structure of the memory device of this embodiment is not limited thereto. The amount of data held in each of the memory cells 1611 may be 2 bits or less or 4 bits or more. In the case where the amount of data held in each of the memory cells 1611 is one bit, for example, the DAC 1663 and the ADC 1672 may be unnecessary.

<Memory cell> FIG. 36A is a circuit diagram showing a configuration example of the memory cell 1611. The memory cell 1611 is a 2T gain cell and is electrically connected to the word lines WWL and RWL, the bit line BL, the source line SL, and the wiring BGL. The memory cell 1611 includes a node SN, an OS transistor M061, a transistor MP61, and a capacitor C61. The OS transistor M061 is a write transistor. The transistor MP61 is a read transistor and is formed using a p-channel Si transistor, for example. The capacitor C61 is a storage capacitor for holding the voltage of the node SN. The node SN is a data holding node and corresponds to a gate of the transistor MP61 here.

The write transistor of the memory cell 1611 is formed using the OS transistor M061; thus, the NOSRAM 1600 can hold data for a long time.

In the example of FIG. 36A, a write bit line and a read bit line are a common bit line; however, as shown in FIG. 36B, a bit line WBL functioning as a write bit line and a bit line RBL functioning as a read bit line may be provided.

FIGS. 36C to 36E show other configuration examples of the memory cell. FIGS. 36C to 36E show examples where the write bit line WBL and the read bit line RBL are provided; however, as shown in FIG. 36A, the write bit line and the read bit line may be a common bit line.

The memory cell 1612 shown in FIG. 36C is a modification example of the memory cell 1611 where the read transistor is changed into an n-channel transistor (MN61). The transistor MN61 may be an OS transistor or a Si transistor.

In the memory cells 1611 and 1612, the OS transistor M061 may be an OS transistor with no back gate.

The memory cell 1613 shown in FIG. 36D is a 3T gain cell and is electrically connected to the word lines WWL and RWL, the bit lines WBL and RBL, the source line SL, the wiring BGL, and a wiring PCL. The memory cell 1613 includes a node SN, an OS transistor M062, a transistor MP62, a transistor MP63, and a capacitor C62. The OS transistor M062 is a write transistor. The transistor MP62 is a read transistor and the transistor MP63 is a selection transistor.

The memory cell 1614 shown in FIG. 36E is a modification example of the memory cell 1613 where the read transistor and the selection transistor are changed into n-channel transistors (MN62 and MN63). Each of the transistors MN62 and MN63 may be an OS transistor or a Si transistor.

The OS transistors provided in the memory cells 1611 to 1614 may each be a transistor with no back gate or a transistor with a back gate.

The so-called NOR memory device in which the memory cells 1611 or the like are connected in parallel to the bit lines RBL is described above, but the memory device of this embodiment is not limited thereto. For example, a so-called NAND memory device in which memory cells 1615 described below are connected in series may be provided.

FIG. 37 is a circuit diagram showing a configuration example of the memory cell array 1610, which is a NAND memory cell array. The memory cell array 1610 shown in FIG. 37 includes the source line SL, the bit line RBL, the bit line WBL, the word line WWL, the word line RWL, the wiring BGL, and the memory cell 1615. The memory cell 1615 includes the node SN, an OS transistor M063, a transistor MN64, and a capacitor C63. Here, the transistor MN64 is an n-channel Si transistor, for example; the transistor MN64 is not limited thereto and may be a p-channel Si transistor or an OS transistor.

Memory cells 1615a and 1615b shown in FIG. 37 are described below as examples. The letter “a” or “b” is added to the reference numerals of the wirings and circuit elements connected to the memory cell 1615a or the memory cell 1615b.

In the memory cell 1615a, a gate of a transistor MN64a, one of a source and a drain of an OS transistor MO63a, and one electrode of a capacitor C63a are electrically connected to one another. The bit line WBL and the other of the source and the drain of the OS transistor MO63a are electrically connected to each other. A word line WWLa and a gate of the OS transistor MO63a are electrically connected to each other. A wiring BGLa and a back gate of the OS transistor MO63a are electrically connected to each other. A word line RWLa and the other electrode of the capacitor C63a are electrically connected to each other.

The memory cell 1615b can be provided so as to be symmetric to the memory cell 1615a with respect to a contact portion of the bit line WBL, the memory cell 1615a, and the memory cell 1615b. Therefore, circuit elements of the memory cell 1615b are connected to wirings in a manner similar to the memory cell 1615a.

A source of the transistor MN64a of the memory cell 1615a is electrically connected to a drain of a transistor MN64b of the memory cell 1615b. A drain of the transistor MN64a of the memory cell 1615a is electrically connected to the bit line RBL. A source of the transistor MN64b of the memory cell 1615b is electrically connected to the source line SL through the transistors MN64 of the plurality of memory cells 1615. As described here, the plurality of transistors MN64 are connected in series between the bit line RBL and the source line SL in the NAND memory cell array 1610.

In a memory device including the memory cell array 1610 illustrated in FIG. 37, writing operation and reading operation are performed for each group of memory cells (hereinafter referred to as a memory cell column) connected to the same word line WWL (or the word line RWL). For example, the writing operation can be performed as follows. A potential at which the OS transistor M063 is turned on is supplied to the word line WWL connected to a memory cell column to which data is written so that the OS transistors M063 in the memory cell column are turned on. Accordingly, the potential of the bit line WBL is supplied to the gates of the transistors MN64 and one electrode of the capacitors C63 in the selected memory cell column, whereby a predetermined charge is supplied to the gate. After that, turning off the OS transistors M063 in the memory cell column allows the predetermined charge retained in the gate. Thus, data can be written to the memory cell 1615 in the selected memory cell column.

For example, the reading operation can be performed as follows. First, a potential at which the transistor MN64 is turned on is supplied to the word line RWL not connected to a memory cell column from which data is read regardless of a charge supplied to the gate of the transistor MN64, so that the transistors MN64 in memory cell columns from which data is not read are turned on. Then, a potential (reading potential) at which an on state or an off state of the transistor MN64 is determined is supplied to the word line RWL connected to the memory cell column from which data is read in accordance with a charge of the gate of the transistor MN64. After that, a fixed potential is supplied to the source line SL and a reading circuit connected to the bit line RBL is operated. Here, the plurality of transistors MN64 between the source line SL and the bit line RBL are turned on except the transistors MN64 in the memory cell column from which data is read; therefore, the conductance between the source line SL and the bit line RBL depends on the state (an on state or an off state) of the transistor MN64 in the memory cell column from which data is read. Since the conductance of the transistor varies depending on the charge of the gate of the transistor MN64 in the memory cell column from which data is read, the potential of the bit line RBL varies accordingly. By reading the potential of the bit line RBL with the reading circuit, data can be read from the memory cells 1615 in the selected memory cell column.

There is theoretically no limitation on the number of rewriting operations of the NOSRAM 1600 because data is rewritten by charging and discharging of the capacitor C61, C62, or C63; and data can be written to and read from the NOSRAM with low energy. Furthermore, since data can be held for a long time, the refresh rate can be reduced.

In the case where the semiconductor device described in any of the above embodiments is used for the memory cells 1611, 1612, 1613, 1614, and 1615, the transistor 200 can be used as the OS transistors M061, M062, and M063, the capacitor 100 can be used as the capacitors C61, C62, and C63, and the transistor 300 can be used as the transistors MP61, MP62, MP63, MN61, MN62, MN63, and MN64. Thus, the area occupied by each set consisting of one transistor and one capacitor in the top view can be reduced, so that the memory device of this embodiment can be highly integrated. As a result, storage capacity per unit area of the memory device of this embodiment can be increased.

The structure described in this embodiment can be used in appropriate combination with the structure described in any of the other embodiments.

### Embodiment 6

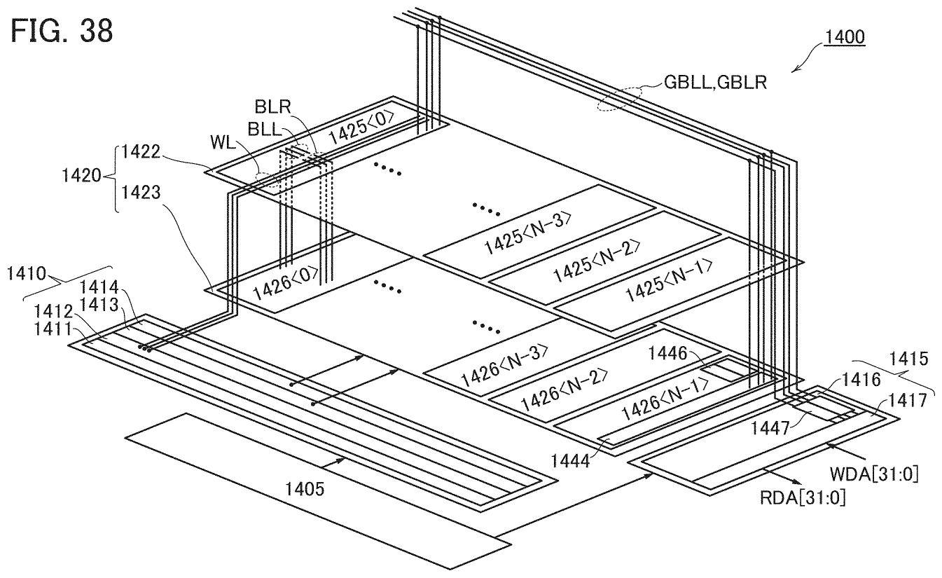

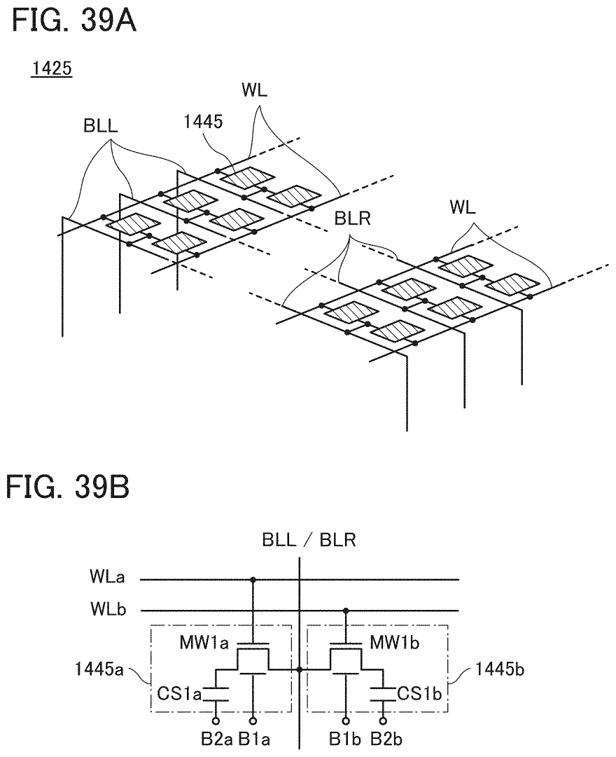

In this embodiment, a DOSRAM will be described as another example of the memory device of one embodiment of the present invention that includes an OS transistor and a capacitor, with reference to FIG. 38 and FIGS. 39A and 39B. A DOSRAM (registered trademark) stands for “dynamic oxide semiconductor RAM,” which is a RAM including a 1T1C (one-transistor/one-capacitor) memory cell. As in the NOSRAM, an OS memory is used in the DOSRAM.

<<DOSRAM 1400>> FIG. 38 illustrates a configuration example of the DOSRAM. As illustrated in FIG. 38, a DOSRAM 1400 includes a controller 1405, a row circuit 1410, a column circuit 1415, and a memory cell and sense amplifier array 1420 (hereinafter referred to as MC-SA array 1420).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

(MC-SA array 1420) The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts a hierarchical bit line structure, where the bit lines are layered into local and global bit lines.

The memory cell array 1422 includes N local memory cell arrays 1425<0> to 1425<N−1>, where N is an integer greater than or equal to 2. FIG. 39A illustrates a configuration example of the local memory cell array 1425. The local memory cell array 1425 includes a plurality of memory cells 1445, a plurality of word lines WL, and a plurality of bit lines BLL and BLR. In the example in FIG. 39A, the local memory cell array 1425 has an open bit-line architecture but may have a folded bit-line architecture.

FIG. 39B illustrates a circuit configuration example of a pair of memory cells 1445a and 1445b connected to the same bit line BLL (BLR). The memory cell 1445a includes a transistor MW1a, a capacitor CS1a, and terminals B1a and B2a. The memory cell 1445a is connected to a word line WLa and the bit line BLL (BLR). The memory cell 1445b includes a transistor MW1b, a capacitor CS1b, and terminals B1b and B2b. The memory cell 1445b is connected to a word line WLb and the bit line BLL (BLR). Hereinafter, in the case where the description applies to either the memory cell 1445a or the memory cell 1445b, the memory cell 1445 and its components are described without using the letter “a” or “b”, in some cases.

The transistor MW1a has a function of controlling the charging and discharging of the capacitor CS1a, and the transistor MW1b has a function of controlling the charging and discharging of the capacitor CS1b. A gate of the transistor MW1a is electrically connected to the word line WLa, a first terminal of the transistor MW1a is electrically connected to the bit line BLL (BLR), and a second terminal of the transistor MW1a is electrically connected to a first terminal of the capacitor CS1a. A gate of the transistor MW1b is electrically connected to the word line WLb, a first terminal of the transistor MW1b is electrically connected to the bit line BLL (BLR), and a second terminal of the transistor MW1b is electrically connected to a first terminal of the capacitor CS1b. In this way, the bit line BLL (BLR) is electrically connected to both the first terminal of the transistor MW1a and the first terminal of the transistor MW1b.

The transistor MW1 has a function of controlling the charging and discharging of the capacitor CS1. A second terminal of the capacitor CS1 is electrically connected to the terminal B2. A constant voltage (e.g., low power supply voltage) is applied to the terminal B2.

In the case where the semiconductor device described in any of the above embodiments is used in each of the memory cells 1445a and 1445b, the transistors 200a and 200b can be used as the transistors MW1a and MW1b, respectively, and the capacitors 100a and 100b can be used as the capacitors CS1a and CS1b, respectively. In this case, the area occupied by each set consisting of one transistor and one capacitor in the top view can be reduced; accordingly, the memory device of this embodiment can be highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with voltage applied to the terminal B1. For example, a fixed voltage (e.g., negative constant voltage) may be applied to the terminal B1; alternatively, the voltage applied to the terminal B1 may be changed in response to the operation of the DOSRAM 1400.

The back gate of the transistor MW1 may be electrically connected to the gate, the source, or the drain of the transistor MW1. The transistor MW1 does not necessarily include the back gate.

The sense amplifier array 1423 includes N local sense amplifier arrays 1426<0> to 1426<N−1>. The local sense amplifier arrays 1426 each include one switch array 1444 and a plurality of sense amplifiers 1446. Each of the sense amplifiers 1446 is electrically connected to a bit line pair. The sense amplifiers 1446 each have a function of precharging the corresponding bit line pair, a function of amplifying a voltage difference of the bit line pair, and a function of retaining the voltage difference. The switch array 1444 has a function of selecting a bit line pair and electrically connecting the selected bit line pair and a global bit line pair to each other.

Here, two bit lines that are compared simultaneously by the sense amplifier are collectively referred to as the bit line pair, and two global bit lines that are compared simultaneously by the global sense amplifier are collectively referred to as the global bit line pair. The bit line pair can be referred to as a pair of bit lines, and the global bit line pair can be referred to as a pair of global bit lines. Here, the bit line BLL and the bit line BLR form one bit line pair, and the global bit line GBLL and the global bit line GBLR form one global bit line pair. In the following description, the expressions “bit line pair (BLL, BLR)” and “global bit line pair (GBLL, GBLR)” are also used.

(Controller 1405) The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

(Row circuit 1410) The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, each of the plurality of local sense amplifier arrays 1426 is driven independently.

(Column circuit 1415) The column circuit 1415 has a function of controlling the input of data signals WDA [31:0], and a function of controlling the output of data signals RDA [31:0]. The data signals WDA[3]:01 are write data signals, and the data signals RDA[3]:01 are read data signals.

Each of the global sense amplifiers 1447 is electrically connected to the global bit line pair (GBLL, GBLR). The global sense amplifiers 1447 each have a function of amplifying a voltage difference of the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a column where data is to be written. The local sense amplifier array 1426 amplifies the written data, and then retains the amplified data. In the specified local memory cell array 1425, the word line WL of the row where data is to be written is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified with an address signal. In the specified local memory cell array 1425, the word line WL of a row where data is to be read is selected, and data of the memory cell 1445 is written to the bit line. The local sense amplifier array 1426 detects a voltage difference of the bit line pair of each column as data, and retains the data. The switch array 1444 writes the data of a column specified by the address signal to the global bit line pair; the data is chosen from the data retained at the local sense amplifier array 1426. The global sense amplifier array 1416 determines and retains the data of the global bit line pair. The data retained at the global sense amplifier array 1416 is output to the input/output circuit 1417. Thus, the read operation is completed.

The DOSRAM 1400 has no limitations on the number of rewrites in principle and data can be read and written with low energy consumption, because data is rewritten by charging and discharging the capacitor CS1. A simple circuit configuration of the memory cell 1445 allows a high memory capacity.

The transistor MW1 is an OS transistor. The extremely low off-state current of the OS transistor can inhibit charge leakage from the capacitor CS1. Therefore, the retention time of the DOSRAM 1400 is considerably longer than that of a DRAM. This allows less frequent refresh, which can reduce power needed for refresh operations. Thus, the DOSRAM 1400 is suitably used for a memory device that can rewrite a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which allows the storage capacitance of the memory cell 1445 to be reduced. In addition, providing the switch array 1444 in the local sense amplifier array 1426 allows the number of long bit lines to be reduced. For the reasons described above, a load to be driven during access to the DOSRAM 1400 is reduced, enabling a reduction in power consumption.

The structure described in this embodiment can be used in appropriate combination with any of the other structures described in the other embodiments.

### Embodiment 7

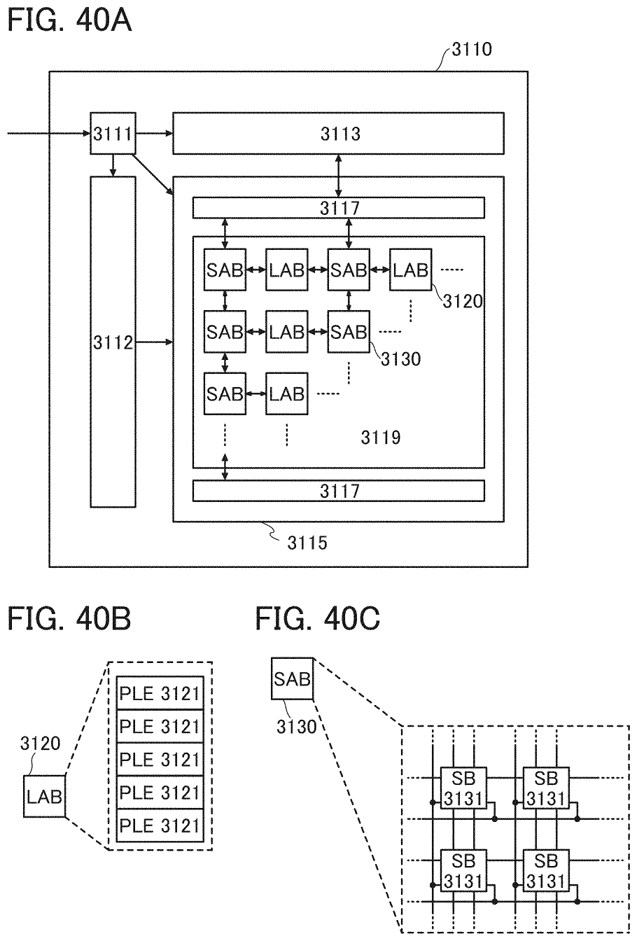

In this embodiment, a field-programmable gate array (FPGA) will be described as an example of a semiconductor device one embodiment of the present invention in which an OS transistor and a capacitor according to are included, with reference to FIGS. 40A to 40C, FIGS. 41A to 41C, FIG. 42, and FIGS. 43A and 43B. In the FPGA of this embodiment, an OS memory is used for a configuration memory and a register. Here, such an FPGA is referred to as an “OS-FPGA”.

<<OS-FPGA>> FIG. 40A illustrates a configuration example of an OS-FPGA. An OS-FPGA 3110 illustrated in FIG. 40A is capable of normally-off (NOFF) computing for context switching by a multi-context configuration and fine-grained power gating in each PLE. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 40B illustrates an example in which the LAB 3120 includes five PLEs 3121. As illustrated in FIG. 40C, the SAB 3130 includes a plurality of switch blocks (SBs) 3131 arranged in array. The LAB 3120 is connected to the LABs 3120 in four directions (on the left, right, top, and bottom sides) through its input terminals and the SABs 3130.

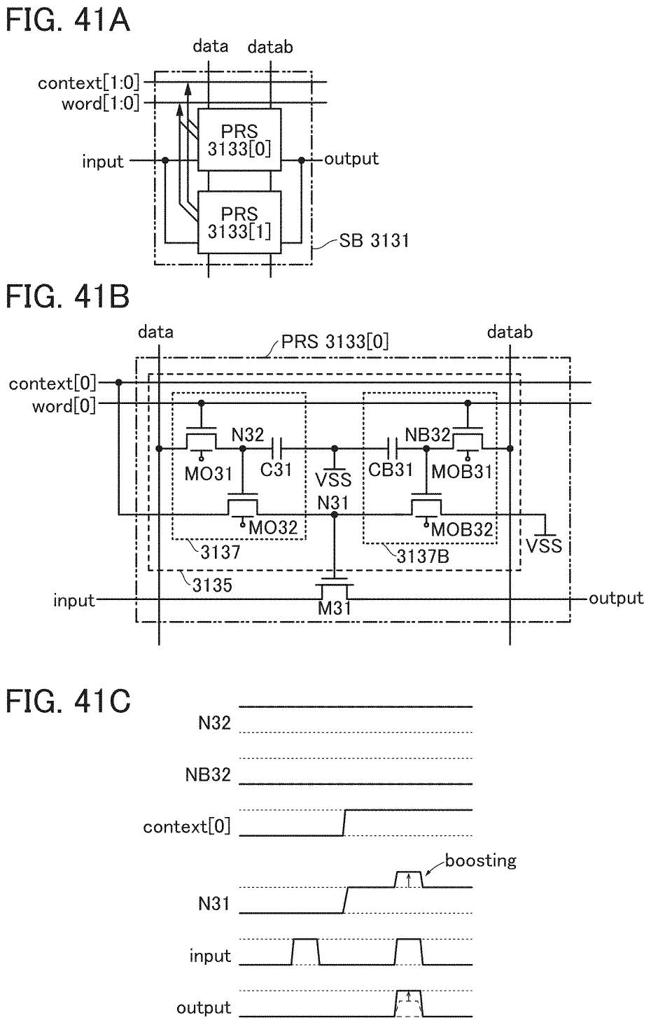

The SB 3131 is described with reference to FIGS. 41A to 41C. To the SB 3131 in FIG. 41A, data, datab, signals context[1:0], and signals word[1:0] are input. The data and the datab are configuration data, and the logics of the data and the datab are complementary to each other. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes a programmable routing switch (PRS) 3133[0] and a PRS 3133[1]. The PRS 3133[0] and the PRS 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 41B illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signal context[0] and the signal word[0] are input to the PRS 3133[0], and the signal context[1] and the signal word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes a memory circuit 3137 and a memory circuit 3137B. The memory circuit 3137 and the memory circuit 3137B have the same circuit configuration. The memory circuit 3137 includes a capacitor C31, an OS transistor M031, and an OS transistor M032. The memory circuit 3137B includes a capacitor CB31, an OS transistor MOB31, and an OS transistor MOB32.

In the case where the semiconductor device described in any of the above embodiments is used in the SAB 3130, the transistor 200 can be used as each of the OS transistors M031 and MOB31, and the capacitor 100 can be used as each of the capacitors C31 and CB31. In this case, the area occupied by each set consisting of one transistor and one capacitor in the top view can be reduced; accordingly, the semiconductor device of this embodiment can be highly integrated.

The OS transistors M031, M032, MOB31, and MOB32 each include a back gate, and these back gates are electrically connected to power supply lines that each supply a fixed voltage.

A gate of the Si transistor M31, a gate of the OS transistor M032, and a gate of the OS transistor MOB32 correspond to a node N31, a node N32, and a node NB32, respectively. The node N32 and the node NB32 are each a charge retention node of the CM 3135. The OS transistor M032 controls the conduction state between the node N31 and a signal line for the signal context[0]. The OS transistor MOB32 controls the conduction state between the node N31 and a low-potential power supply line VSS.

A logic of data that the memory circuit 3137 retains and a logic of data that the memory circuit 3137B retains are complementary to each other. Thus, either the OS transistor M032 or the OS transistor MOB32 is turned on.

The operation example of the PRS 3133[0] is described with reference to FIG. 41C. In the PRS 3133[0], in which configuration data has already been written, the node N32 is at “H”, whereas the node NB32 is at “L”.

The PRS 3133[0] is inactivated while the signal context[0] is at “L”. During this period, even when an input terminal of the PRS 3133[0] is transferred to “H”, the gate of the Si transistor M31 is kept at “L” and an output terminal of the PRS 3133[0] is also kept at “L”.

The PRS 3133[0] is activated while the signal context[0] is at “H”. When the signal context[0] is transferred to “H”, the gate of the Si transistor M31 is transferred to “H” by the configuration data stored in the CM 3135.

While the PRS 3133[0] is active, when the potential of the input terminal is changed to “H”, the gate voltage of the Si transistor M31 is increased by boosting because the OS transistor M032 of the memory circuit 3137 is a source follower. As a result, the OS transistor M032 of the memory circuit 3137 loses the driving capability, and the gate of the Si transistor M31 is brought into a floating state.

In the PRS 3133 with a multi-context function, the CM 3135 also functions as a multiplexer.

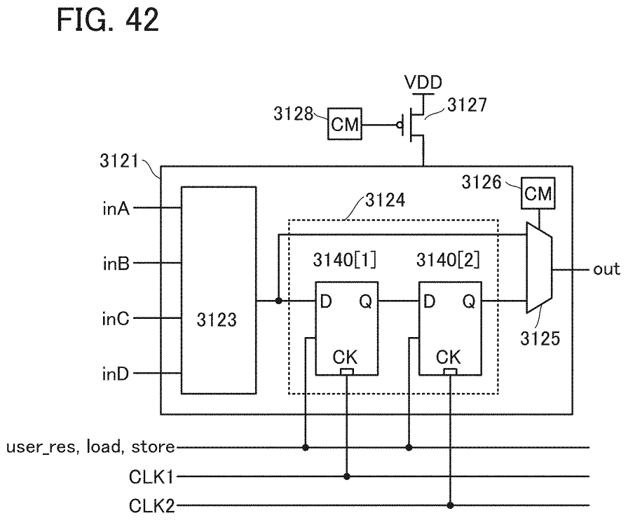

FIG. 42 illustrates a configuration example of the PLE 3121. The PLE 3121 includes a lookup table (LUT) block 3123, a register block 3124, a selector 3125, and a CM 3126. The LUT block 3123 is configured to select and output data in the LUT block in accordance with inputs inA to inD. The selector 3125 selects an output of the LUT block 3123 or an output of the register block 3124 in accordance with the configuration data stored in the CM 3126.

The PLE 3121 is electrically connected to a power supply line for a voltage VDD through a power switch 3127. Whether the power switch 3127 is turned on or off is determined in accordance with configuration data stored in a CM 3128. Fine-grained power gating can be performed by providing the power switch 3127 for each PLE 3121. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as OS-FF).

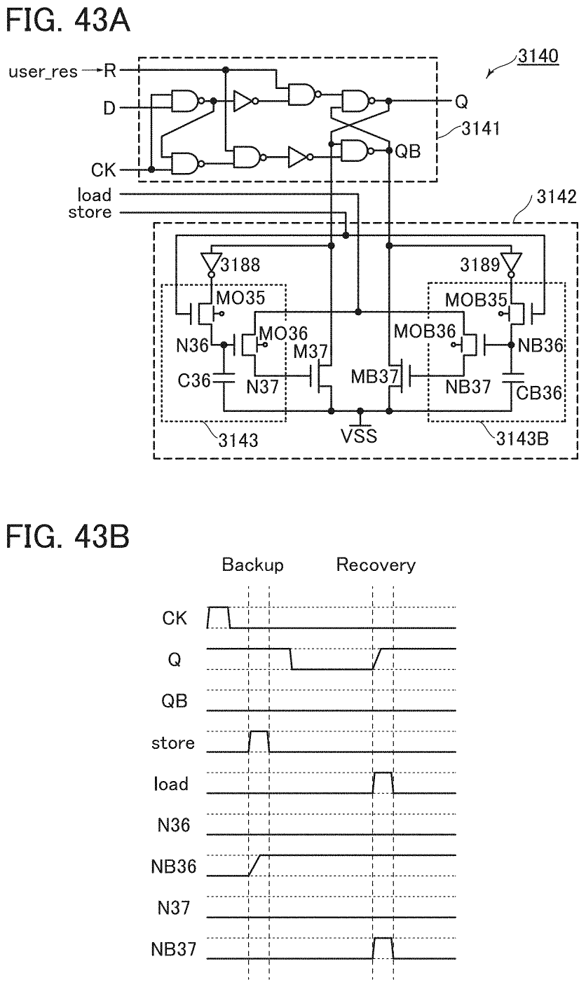

The register block 3124 includes an OS-FF 3140[1] and an OS-FF 3140[2]. A signal user_res, a signal load, and a signal store are input to the OS-FFs 3140[1] and 3140[2]. A clock signal CLK1 is input to the OS-FF 3140[1] and a clock signal CLK2 is input to the OS-FF 3140[2]. FIG. 43A illustrates a configuration example of the OS-FF 3140.

The OS-FF 3140 includes a FF 3141 and a shadow register 3142. The FF 3141 includes a node CK, a node R, a node D, a node Q, and a node QB. A clock signal is input to the node CK. The signal user_res is input to the node R. The signal user_res is a reset signal. The node D is a data input node, and the node Q is a data output node. The logics of the node Q and the node QB are complementary to each other.

The shadow register 3142 can function as a backup circuit of the FF 3141. The shadow register 3142 backs up data of the node Q and data of the node QB in response to the signal store and writes back the backed up data to the node Q and the node QB in response to the signal load.

The shadow register 3142 includes an inverter circuit 3188, an inverter circuit 3189, a Si transistor M37, a Si transistor MB37, a memory circuit 3143, and a memory circuit 3143B. The memory circuit 3143 and the memory circuit 3143B each have the same circuit configuration as the memory circuit 3137 of the PRS 3133. The memory circuit 3143 includes a capacitor C36, an OS transistor M035, and an OS transistor M036. The memory circuit 3143B includes a capacitor CB36, an OS transistor MOB35, and an OS transistor MOB36. A node N36 and a node NB36 correspond to a gate of the OS transistor M036 and a gate of the OS transistor MOB36, respectively, and are each a charge retention node. A node N37 and a node NB37 correspond to a gate of the Si transistor M37 and a gate of the Si transistor MB37, respectively.

In the case where the semiconductor device described in any of the above embodiments is used in the LAB 3120, the transistor 200 can be used as each of the OS transistors M035 and MOB35, and the capacitor 100 can be used as each of the capacitors C36 and CB36. In this case, the area occupied by each set consisting of one transistor and one capacitor in the top view can be reduced; accordingly, the semiconductor device of this embodiment can be highly integrated.

The OS transistors M035, M036, MOB35, and MOB36 each include a back gate, and these back gates are electrically connected to power supply lines that each supply a fixed voltage.

An example of an operation method of the OS-FF 3140 is described with reference to FIG. 43B.

(Backup) When the signal store at “H” is input to the OS-FF 3140, the shadow register 3142 backs up data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the node Q and the data of the node QB of the FF 3141 are lost, the shadow register 3142 retains the backed up data even when power supply is stopped.

(Recovery) The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is restored to a state at the backup operation.

A combination of the fine-grained power gating and backup/recovery operation of the OS-FF 3140 allows power consumption of the OS-FPGA 3110 to be effectively reduced.

A possible error in a memory circuit is a soft error due to the entry of radiation. The soft error is a phenomenon in which a malfunction such as inversion of data stored in a memory is caused by electron-hole pair generation when a transistor is irradiated with α rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory including an OS transistor has a high soft-error tolerance. Therefore, the OS-FPGA 3110 including an OS memory can have high reliability.

The configuration described in this embodiment can be used in appropriate combination with any of the other configurations described in the other embodiments.

### Embodiment 8

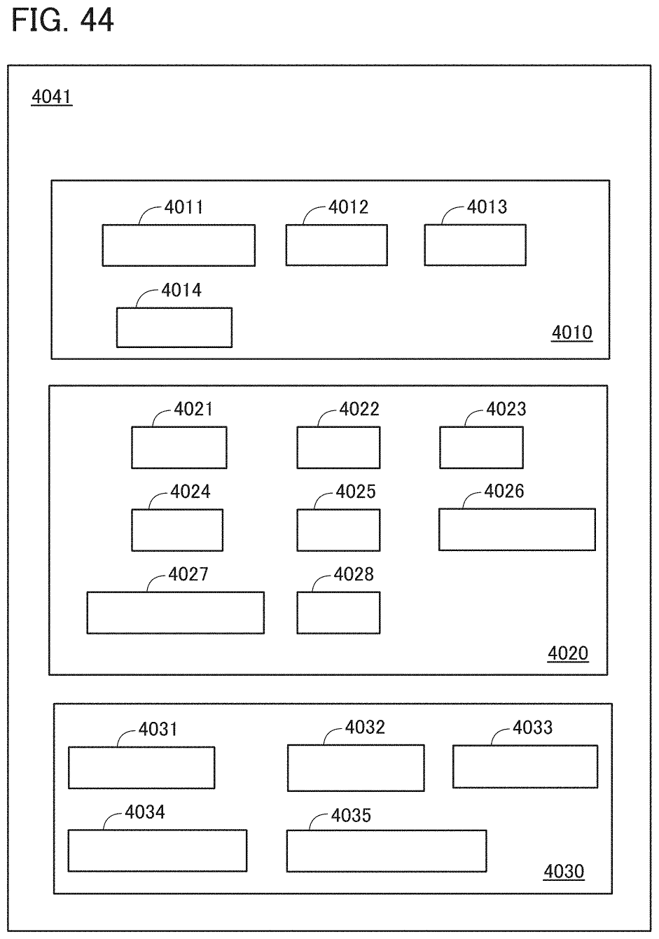

In this embodiment, an AI system in which the semiconductor device of any of the above-described embodiments is used will be described with reference to FIG. 44.

FIG. 44 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a central processing unit (CPU) 4021, a graphics processing unit (GPU) 4022, a phase locked loop (PLL) 4023, a static random access memory (SRAM) 4024, a programmable read only memory (PROM) 4025, a memory controller 4026, a power supply circuit 4027, and a power management unit (PMU) 4028.

The input/output portion 4030 includes an external memory control circuit 4031, an audio codec 4032, a video codec 4033, a general-purpose input/output module 4034, and a communication module 4035.

The arithmetic portion 4010 can perform neural network learning or neural network inference.

The analog arithmetic circuit 4011 includes an analog/digital (A/D) converter circuit, a digital/analog (D/A) converter circuit, and a product-sum operation circuit.

The analog arithmetic circuit 4011 is preferably formed using an OS transistor. The analog arithmetic circuit 4011 formed using an OS transistor includes an analog memory and can execute a product-sum operation necessary for the learning and the inference with low power consumption.

The DOSRAM 4012 is a DRAM including an OS transistor which temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data has to be stored piece by piece because of the circuit area limitation and small storage capacity of the SRAM. The DOSRAM 4012 has a larger storage capacity than an SRAM because memory cells of the DOSRAM can be highly integrated even in a limited circuit area. Therefore, the DOSRAM 4012 can efficiently store the input data.

The NOSRAM 4013 is a nonvolatile memory including an OS transistor. The NOSRAM 4013 consumes less power in writing data than the other nonvolatile memories such as a flash memory, a resistive random access memory (ReRAM), and a magnetoresistive random access memory (MRAM). Furthermore, unlike a flash memory and a ReRAM which deteriorate by data writing, the NOSRAM does not have a limit on the number of times of data writing.

Furthermore, the NOSRAM 4013 can store multilevel data of two or more bits as well as one-bit binary data. The multilevel data storage in the NOSRAM 4013 leads to a reduction of the memory cell area per bit.

Because the NOSRAM 4013 can store analog data as well as digital data, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. In this specification, analog data refers to data having a resolution of three bits (eight levels) or more. The above-described multilevel data might be included in the analog data.

Data and parameters used in the neural network calculation can be once stored in the NOSRAM 4013. The data and parameters may be stored in a memory provided outside the AI system 4041 via the CPU 4021. However, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA including an OS transistor. By including the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), a deep belief network (DBN), or the like described later, with a hardware. The connection of the neural network with a hardware enables higher speed performance.

The FPGA 4014 is an FPGA including an OS transistor. An OS-FPGA can have a smaller memory area than an FPGA formed using an SRAM. Thus, adding a context switching function only causes a small increase in area. Moreover, an OS-FPGA can transmit data and parameters at high speed by utilizing the boosting.

In the AI system 4041, the analog arithmetic circuit 4011, the DOSRAM 4012, the NOSRAM 4013, and the FPGA 4014 can be provided on one die (chip). Thus, the AI system 4041 can perform calculation of the neural network quickly with low power consumption. The analog arithmetic circuit 4011, the DOSRAM 4012, the NOSRAM 4013, and the FPGA 4014 can be manufactured through the same manufacturing process. This enables the AI system 4041 to be manufactured at low cost.

Note that the arithmetic portion 4010 need not necessarily include all of the following: the DOSRAM 4012, the NOSRAM 4013, and the FPGA 4014. One or more memories are selected from the DOSRAM 4012, the NOSRAM 4013, and the FPGA 4014 in accordance with a problem that is desired to be solved in the AI system 4041.

The AI system 4041 can implement a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for implementing at least one of the methods. Part or the whole of the program may be stored in the NOSRAM 4013.

Most of the existing programs used as libraries are designed on the premise that the programs are processed by a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be performed at high speed.

The power supply circuit 4027 generates not only a low power supply potential for a logic circuit but also a potential for an analog operation. The power supply circuit 4027 may include an OS memory. In this case, storing a reference potential in the OS memory can reduce the power consumption of the power supply circuit 4027.

The PMU 4028 is configured to temporarily stop the power supply to the AI system 4041.

As a register in each of the CPU 4021 and the GPU 4022, an OS memory is preferably included. By including the OS memory, each of the CPU 4021 and the GPU 4022 can retain data (logic value) in the OS memory even when power supply is stopped. As a result, the AI system 4041 can save the power.

The PLL 4023 is configured to generate a clock. The AI system 4041 performs an operation on the basis of the clock generated by the PLL 4023. The PLL 4023 preferably includes an OS memory. When an OS memory is included in the PLL 4023, an analog potential with which the clock oscillation frequency is controlled can be held.

The AI system 4041 may store data in an external memory such as a DRAM. For this reason, the AI system 4041 preferably includes the memory controller 4026 functioning as an interface with the external DRAM. Furthermore, the memory controller 4026 is preferably provided near the CPU 4021 or the GPU 4022. Thus, quick data transmission can be achieved.

Some or all of the circuits illustrated in the control portion 4020 can be formed on the same die as the arithmetic portion 4010. Thus, the AI system 4041 can execute neural network calculation at high speed with low power consumption.

Data used for neural network calculation is stored in an external memory device such as a hard disk drive (HDD) or a solid state drive (SSD) in many cases. Therefore, the AI system 4041 preferably includes the external memory control circuit 4031 functioning as an interface with the external memory device.

Because audio and video are often subjects of the learning and inference using the neural network, the AI system 4041 includes the audio codec 4032 and the video codec 4033. The audio codec 4032 encodes and decodes audio data, and the video codec 4033 encodes and decodes video data.

The AI system 4041 can perform learning or make an inference using data obtained from an external sensor. For this reason, the AI system 4041 includes the general-purpose input/output module 4034. The general-purpose input/output module 4034 includes a universal serial bus (USB), an inter-integrated circuit (I2C), or the like, for example.

The AI system 4041 can perform learning or make an inference using data obtained via the Internet. For this reason, the AI system 4041 preferably includes the communication module 4035.

The analog arithmetic circuit 4011 may include a multi-level flash memory as an analog memory. However, the flash memory has a limit on the number of rewriting times. In addition, the multi-level flash memory is extremely difficult to embed; in other words, the arithmetic circuit and the memory are difficult to form on the same die.

Alternatively, the analog arithmetic circuit 4011 may include a ReRAM as an analog memory. However, the ReRAM has a limit on the number of rewriting times and also has a problem in storage accuracy. Moreover, because the ReRAM is a two-terminal element, the complicated circuit design is necessary for separating data writing and data reading.

Further alternatively, the analog arithmetic circuit 4011 may include an MRAM as an analog memory. However, the MRAM has a problem in storage capacity because of its low magnetoresistive ratio.

In consideration of the above, an OS memory is preferably used as an analog memory in the analog arithmetic circuit 4011.

The structure described in this embodiment can be used in appropriate combination with any of the other structures described in the other embodiments.

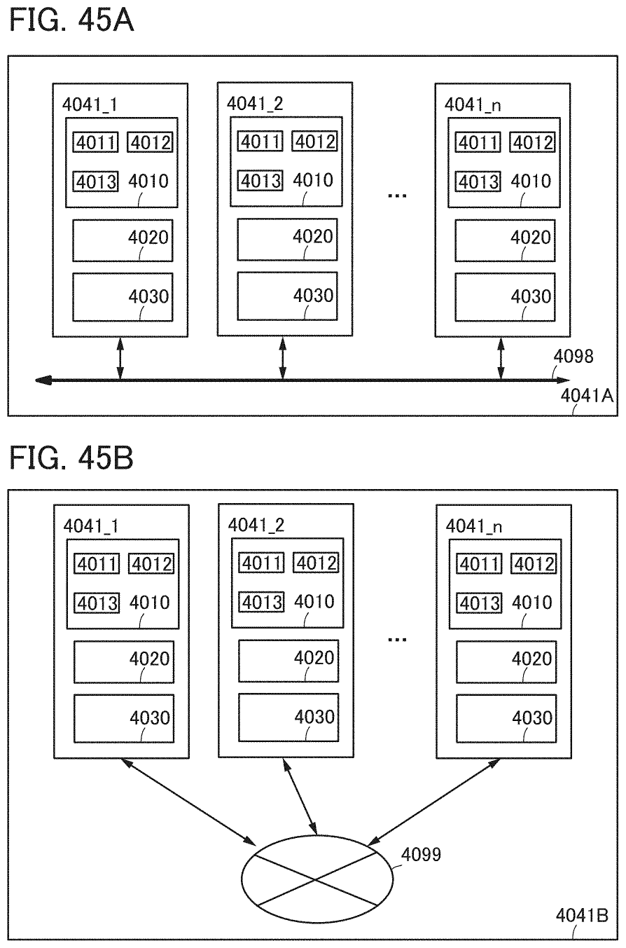

### Embodiment 9

<Application example of AI system> In this embodiment, application examples of the AI system described in the above embodiment will be described with reference to FIGS. 45A and 45B.

FIG. 45A illustrates an AI system 4041A in which the AI systems 4041 described with FIG. 44 are arranged in parallel and a signal can be transmitted between the systems via a bus line.

The AI system 4041A illustrated in FIG. 45A includes AI systems 4041_1 to 4041_n (n is a natural number). The AI systems 4041_1 to 4041_n are connected to each other via a bus line 4098.

FIG. 45B illustrates an AI system 4041B in which the AI systems 4041 described with FIG. 44 are arranged in parallel as in FIG. 45A and a signal can be transmitted between the systems via a network.

The AI system 4041B illustrated in FIG. 45B includes the AI systems 4041_1 to 4041_n. The AI systems 4041_1 to 4041_n are connected to each other via a network 4099.

A communication module is provided in each of the AI systems 4041_1 to 4041_n; such a configuration enables wireless or wired communication via the network 4099. A communication module can communicate via an antenna. Communication can be performed when an electronic device is connected to a computer network such as the Internet (infrastructure of the World Wide Web, WWW), an intranet, an extranet, a personal area network (PAN), a local area network (LAN), a campus area network (CAN), a metropolitan area network (MAN), a wide area network (WAN), or a global area network (GAN), for example In the case of performing wireless communication, it is possible to use, as a communication protocol or a communication technology, a communications standard such as Long-Term Evolution (LTE), Global System for Mobile Communication (GSM: registered trademark), Enhanced Data Rates for GSM Evolution (EDGE), Code Division Multiple Access 2000 (CDMA2000), or W-CDMA (registered trademark), or a communications standard developed by IEEE such as Wi-Fi (registered trademark), Bluetooth (registered trademark), or ZigBee (registered trademark).

With the configuration illustrated in FIG. 45A or 45B, analog signals obtained with external sensors or the like can be processed by different AI systems. For example, analog signals containing biological information such as brain waves, a pulse, blood pressure, and body temperature obtained with a variety of sensors such as a brain wave sensor, a pulse wave sensor, a blood pressure sensor, and a temperature sensor can be processed by different AI systems. Since each of the AI systems performs signal processing or learning, the amount of information processed by each AI system can be reduced. Accordingly, the signal processing or learning requires a smaller amount of arithmetic processing. As a result, recognition accuracy can be increased. With the use of data obtained with each AI system, biological information that irregularly changes should be able to be collectively grasped instantly.

The structure described in this embodiment can be used in appropriate combination with any of the other structures described in the other embodiments.

### Embodiment 10

In this embodiment, an example of an IC incorporating the AI system described in the above embodiment will be described.

In the AI system described in the above embodiment, a digital processing circuit (e.g., a CPU) that includes a Si transistor and an OS-FPGA, an OS memory (e.g., a DOSRAM or a NOSRAM), and an analog arithmetic circuit that include OS transistors can be integrated into one die.

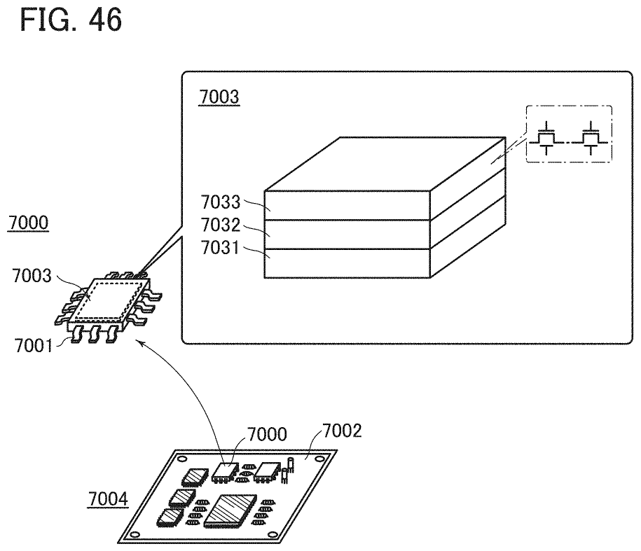

FIG. 46 illustrates the example of the IC incorporating the AI system. An AI system IC 7000 illustrated in FIG. 46 includes a lead 7001 and a circuit portion 7003. The AI system IC 7000 is mounted on a printed circuit board 7002, for example. A plurality of such IC chips are combined and electrically connected to each other on the printed circuit board 7002; thus, a circuit board on which electronic components are mounted (a circuit board 7004) is formed. In the circuit portion 7003, the circuits described in the above embodiment are provided on one die. The circuit portion 7003 has a stacked-layer structure as described in the above embodiment, which is broadly divided into a Si transistor layer 7031, a wiring layer 7032, and an OS transistor layer 7033. Since the OS transistor layer 7033 can be stacked over the Si transistor layer 7031, the size of the AI system IC 7000 can be easily reduced.

Although a Quad Flat Package (QFP) is used as a package of the AI system IC 7000 in FIG. 46, the package is not limited thereto.

The digital processing circuit (e.g., a CPU) and the OS-FPGA, the OS memory (e.g., a DOSRAM or a NOSRAM), and the analog arithmetic circuit that include OS transistors can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated into the IC at low cost.

The structure described in this embodiment can be used in appropriate combination with any of the other structures described in the other embodiments.

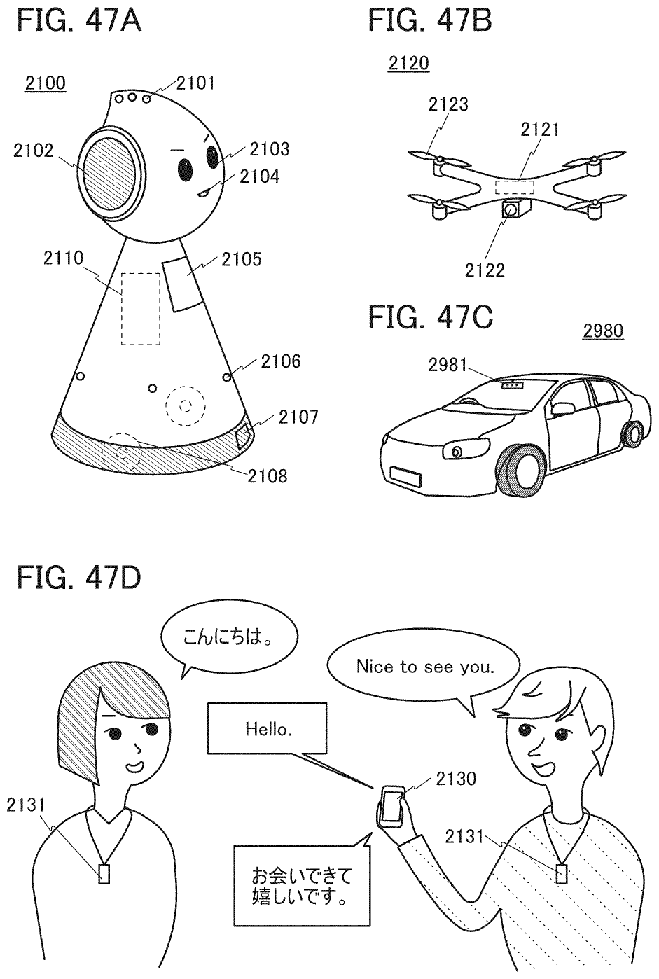

### Embodiment 11

<Electronic device> A semiconductor device of one embodiment of the present invention can be used for a variety of electronic devices. FIGS. 47A to 47D, FIGS. 48A and 48B, and FIG. 49 illustrate specific examples of the electronic devices using the semiconductor device of one embodiment of the present invention.

A robot 2100 illustrated in FIG. 47A includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel.

The upper camera 2103 and the lower camera 2106 each have a function of capturing an image of the surroundings of the robot 2100. The obstacle sensor 2107 can detects an obstacle in the direction where the robot 2100 advances with the moving mechanism 2108. The robot 2100 can move safely by recognizing an ambient environment with the upper camera 2103, the lower camera 2106, and the obstacle sensor 2107.

A flying object 2120 illustrated in FIG. 47B includes an arithmetic device 2121, a propeller 2123, and a camera 2122 and has a function of flying autonomously.

The above electronic component can be used for the arithmetic device 2121 and the camera 2122 of the flying object 2120.

FIG. 47C is an external view illustrating an example of an automobile. An automobile 2980 includes a camera 2981 and the like. The automobile 2980 also includes various sensors and the like such as infrared radar, millimeter wave radar, and laser radar. The automobile 2980 judges traffic information therearound such as the presence of a pedestrian with analyzing an image taken by the camera 2981, and thus can perform automatic driving.

FIG. 47D illustrates a situation where a portable electronic device 2130 performs simultaneous interpretation in communication between people who speak different language.

The portable electronic device 2130 includes a microphone, a speaker, and the like and has a function of recognizing user's speaking voice and translating it into a language spoken by a collocutor.

The user has a portable microphone 2131 in FIG. 47D. The portable microphone 2131 has a radio communication function and a function of transmitting a detected sound to the portable electronic device 2130.

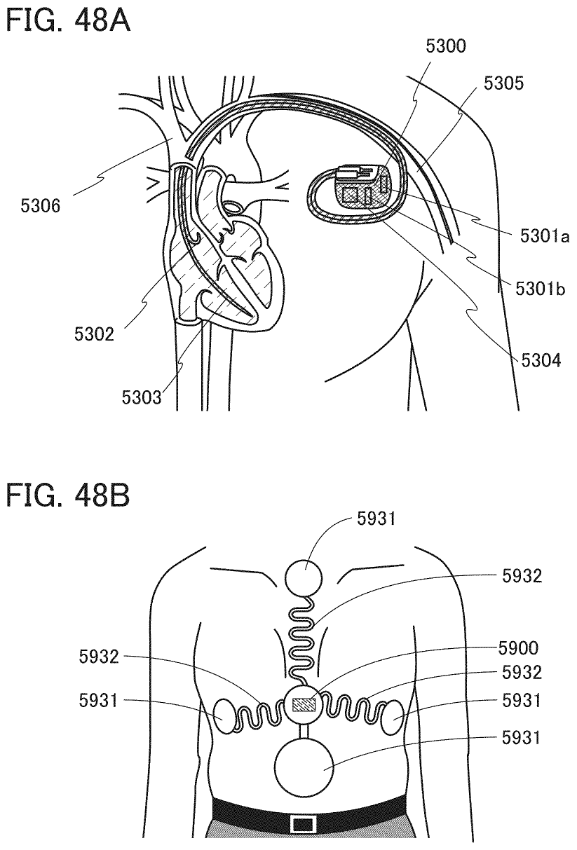

FIG. 48A is a cross-sectional schematic view of an example of a pacemaker.

A pacemaker body 5300 includes at least batteries 5301a and 5301b, a regulator, a control circuit, an antenna 5304, a wire 5302 reaching a right atrium, and a wire 5303 reaching a right ventricle.

The pacemaker body 5300 is implanted in the body by surgery, and the two wires pass through a subclavian vein 5305 and a superior vena cava 5306 of the human body, with the end of one of them placed in the right ventricle and the end of the other of them placed in the right atrium.

The antenna 5304 can receive electric power, and the batteries 5301a and 5301b are charged with the electric power, which can reduce the frequency of replacing the pacemaker. Since the pacemaker body 5300 has a plurality of batteries, the safety is high, and even when one of the batteries fails, the other can function. In this manner, the plurality of batteries function as auxiliary power supplies.

In addition to the antenna 5304 that can receive electric power, an antenna that can transmit a physiological signal may be provided for the pacemaker. For example, a system that monitors the cardiac activity, capable of monitoring physiological signals such as pulses, respiratory rate, heart rate, and body temperature with an external monitoring device may be constructed.

A sensor 5900 illustrated in FIG. 48B is attached to a human body with the use of a bond pad or the like. The sensor 5900 obtains biological data such as a heart rate or an electrocardiogram by supplying a signal through a wiring 5932 to an electrode 5931 or the like attached to the human body. The obtained data is transmitted to a terminal such as a reading device as a wireless signal.

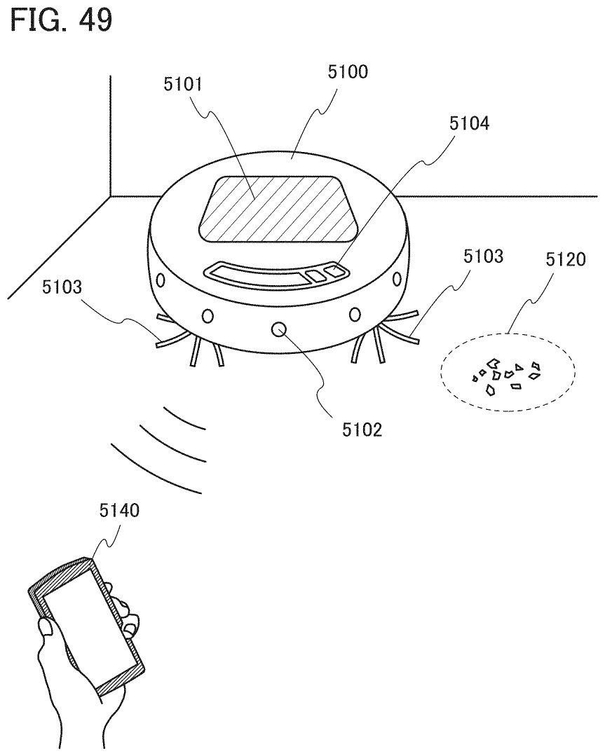

FIG. 49 is a schematic view illustrating an example of a cleaning robot.

A cleaning robot 5100 includes a display 5101 on its top surface, a plurality of cameras 5102 on its side surface, a brush 5103, and an operation button 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a radio communication means.

The cleaning robot 5100 can run autonomously, detect dust 5120, and vacuum the dust from the inlet provided on the bottom surface.

The cleaning robot 5100 can judge whether or not there is an obstacle such as a wall, furniture, or a step by analyzing an image taken by the cameras 5102. In the case where the cleaning robot 5100 detects an object that is likely to be caught in the brush 5103, such as a wiring, by analyzing an image, the rotation of the brush 5103 can be stopped.

The display 5101 can display the remaining capacity of a battery, the amount of vacuumed dust, and the like. The display 5101 may display a path in which the cleaning robot 5100 has run. The display 5101 may be a touch panel and the operation button 5104 may be provided on the display 5101.

The cleaning robot 5100 can communicate with a portable electronic device 5140 such as a smartphone. The portable electronic device 5140 can display an image taken by the cameras 5102. Therefore, an owner of the cleaning robot 5100 can monitor his/her room even from the outside. The owner can also check the display on the display 5101 by the portable electronic device 5140 such as a smartphone.

A memory device including the semiconductor device of one embodiment of the present invention can hold control data, a control program, or the like of the above electronic device for a long time. With the use of the semiconductor device of one embodiment of the present invention, a highly reliable electronic device can be provided.

An IC in which the above AI system is incorporated can be used for the arithmetic device or the like of the above-described electronic device, for example. Accordingly, the electronic device of this embodiment can perform optimal operations depending on circumstances with low power consumption by utilizing the AI system.

This embodiment can be implemented in an appropriate combination with any of the structures described in the other embodiments, examples, and the like.

### Example

In this example, an interface between an oxide and a metal or a metal compound formed over the oxide was evaluated. For the evaluation, Sample 1 and Sample 2 each including an oxide and a metal or a metal compound formed over the oxide were used. Sample 2 was subjected to heat treatment after the formation of the metal or the metal compound over the oxide.

A method for fabricating Sample 1 is described. An oxide was formed over a substrate using a target with an atomic ratio of In:Ga:Zn=4:2:4.1 by a sputtering method. The formed oxide was subjected to heat treatment in a nitrogen atmosphere at 400° C. for one hour and then successively subjected to another heat treatment in an oxygen atmosphere at 400° C. for one hour. After the heat treatment, a metal compound was formed to have a thickness of 20 nm over the oxide in an atmosphere containing nitrogen using a target with an atomic ratio of Ti:Al=1:1 by a sputtering method. The obtained metal compound contained titanium, aluminum, and nitrogen; thus, the obtained metal compound can be represented by TiAlN or TiAlNx.

A method for fabricating Sample 2 is described. An oxide was formed over a substrate using a target with an atomic ratio of In:Ga:Zn=4:2:4.1 by a sputtering method. The formed oxide was subjected to heat treatment in a nitrogen atmosphere at 400° C. for one hour and then successively subjected to another heat treatment in an oxygen atmosphere at 400° C. for one hour. After the heat treatment, a metal compound was formed to have a thickness of 20 nm over the oxide in an atmosphere containing nitrogen using a target with an atomic ratio of Ti:Al=1:1 by a sputtering method. The obtained metal compound contained titanium, aluminum, and nitrogen; thus, the obtained metal compound can be represented by TiAlN or TiAlNx. After the formation of the metal compound, heat treatment was performed in a nitrogen atmosphere at 400° C. for one hour.

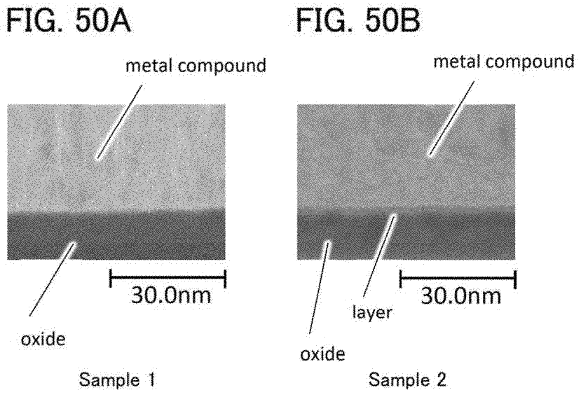

A cross section of the interface between the oxide and the metal compound of each of Samples 1 and 2 was observed. The cross section was observed with a scanning transmission electron microscope (STEM). For the observation, HD-2700 manufactured by Hitachi High-Technologies Corporation was used. FIG. 50A shows the cross-sectional STEM observation result of Sample 1. FIG. 50B shows the cross-sectional STEM observation result of Sample 2.

The comparison between FIGS. 50A and 50B shows that a layer is formed between the oxide and the metal compound in FIG. 50B. The layer may be formed by the heat treatment after the formation of the metal compound.

Next, the sheet resistance of an oxide was measured. The measurement upper limit of a sheet resistance measurer was 6×10⁶ Ω/sq. The measurement of the sheet resistance was performed using Sample 3 and Sample 4. Sample 3 was fabricated by forming an oxide and performing heat treatment like Samples 1 and 2, and a metal compound is not formed. Sample 4 was fabricated by forming a metal compound and performing heat treatment like Sample 2, and removing the metal compound to expose a mixed layer of the oxide and the metal compound.

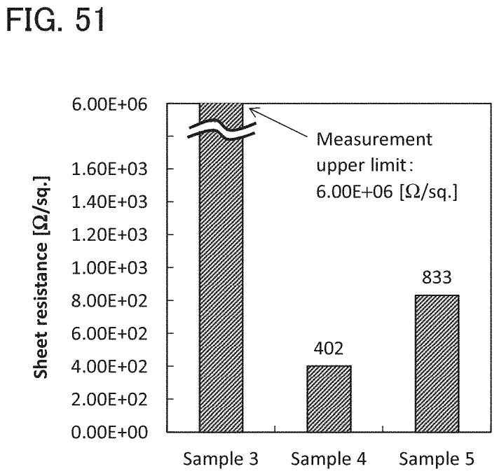

The sheet resistance of Sample 3 exceeded the range; the sheet resistance of the oxide was higher than or equal to 6×10⁶ Ω/sq. The sheet resistance of Sample 4 was 402 Ω/sq. The results revealed that a low-resistance region is formed at least on a surface of the oxide by forming the metal compound over the oxide and performing heat treatment (see FIG. 51).

### Comparative Example

As a method for reducing the resistance of an oxide, forming silicon nitride containing hydrogen in contact with the oxide is known. Sample 5 was fabricated by forming an oxide like Samples 1 and 2, forming silicon nitride over the oxide by a plasma CVD method, and removing the silicon nitride, and then the sheet resistance of the oxide was measured. The sheet resistance of Sample 5 was 833 Ω/sq. The sheet resistance of the oxide was reduced also by forming silicon nitride in contact with the oxide. At the same time, the resistance of Sample 4 in this example was lower than that of Sample 5 (see FIG. 51).

This example can be implemented in an appropriate combination with any of the structures described in the other embodiments, examples, and the like.

### REFERENCE NUMERALS

100: capacitor, 100a: capacitor, 100b: capacitor, 110: conductor, 112: conductor, 120: conductor, 130: insulator, 150: insulator, 200: transistor, 200a: transistor, 200b: transistor, 203: conductor, 205: conductor, 207: conductor, 210: insulator, 212: insulator, 214: insulator, 216: insulator, 218: conductor, 220: insulator, 222: insulator, 224: insulator, 224A: insulating film, 230: oxide, 230a: oxide, 230A: oxide film, 230b: oxide, 230B: oxide film, 230c: oxide, 230C: oxide film, 231: region, 231a: region, 231b: region, 232: region, 232a: region, 232b: region, 234: region, 239: region, 240: conductor, 240a: conductor, 240b: conductor, 240c: conductor, 242A: film, 246: conductor, 248: conductor, 250: insulator, 250A: insulating film, 252: metal oxide, 252A: metal oxide film, 260: conductor, 260a: conductor, 260A: conductive film, 260b: conductor, 260B: conductive film, 270: insulator, 270A: insulating film, 271: insulator, 271A: insulating film, 272: insulator, 272A: insulating film, 273: insulator, 274: insulator, 275: insulator, 275A: insulating film, 277: region, 280: insulator, 282: insulator, 286: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 360: insulator, 362: insulator, 364: insulator, 366: conductor, 370: insulator, 372: insulator, 374: insulator, 376: conductor, 380: insulator, 382: insulator, 384: insulator, 386: conductor, 400: transistor, 403: conductor, 405: conductor, 430c: oxide, 431a: oxide, 431b: oxide, 432a: oxide, 432b: oxide, 450: insulator, 452: metal oxide, 460: conductor, 460a: conductor, 460b: conductor, 470: insulator, 472: insulator, 475: insulator, 600: cell, 600a: cell, 600b: cell, 610: circuit, 620: circuit, 650a: memory cell, 650b: memory cell, 1001: wiring, 1002: wiring, 1003: wiring, 1004: wiring, 1005: wiring, 1006: wiring, 1007: wiring, 1008: wiring, 1009: wiring, and 1010: wiring.

This application is based on Japanese Patent Application Serial No. 2017-096084 filed with Japan Patent Office on May 12, 2017, the entire contents of which are hereby incorporated by reference.

1. A semiconductor device comprising:
a transistor comprising:
an oxide having a first region, a second region, and a third region therebetween;
a first insulator over the first region;
a conductor over the first insulator; and
a second insulator in contact with a side surface of the first insulator and a side surface of the conductor,
wherein:
the first region functions as a channel formation region of the transistor,
the third region partly overlaps with the second insulator,
the second region has a lower oxygen concentration than the first and third regions, and
the third region comprises a region having an oxygen concentration between the first region and the second region.

2. The semiconductor device according to claim 1, wherein the transistor further comprises a first film in contact with the second region and over the oxide.

3. The semiconductor device according to claim 1, wherein the oxide contains In, an element M, and Zn (M is Al, Ga, Y, or Sn).

4. The semiconductor device according to claim 3, wherein an atomic proportion contains higher In than the element M.

5. The semiconductor device according to claim 1, wherein the second region contains nitrogen and at least one of Al, Ru, Ti, Ta, Cr, and W.

6. The semiconductor device according to claim 1, wherein the first region has a lower hydrogen concentration than the second region and the third region.

7. The semiconductor device according to claim 1, wherein the transistor is a normally-off transistor.

8. The semiconductor device according to claim 2, wherein the first film is partly mixed with the second region.

9. The semiconductor device according to claim 2, wherein the first film contains nitrogen and at least one of Al, Ru, Ti, Ta, Cr, and W.

10. The semiconductor device according to claim 2, wherein the first film has a thickness in a range of 0.5 nm or more and less than 5 nm.

11. A method for manufacturing a semiconductor device comprising:
forming a transistor comprising:
an oxide having a first region, a second region, and a third region therebetween;
a first insulator over the oxide;
a conductor over the first insulator; and
a second insulator in contact with a side surface of the first insulator and a side surface of the conductor;
forming a first film containing a metal to cover the oxide, the first insulator, the conductor, and the second insulator and to be in contact with the second region; and
performing first heat treatment on the oxide and the first film in an atmosphere containing nitrogen to make oxygen in the second region extracted by the first film,
wherein the first region functions as a channel formation region of the transistor.

12. The method according to claim 11, wherein the first film is formed by a sputtering method using at least one of an argon gas and a nitrogen gas.

13. The method according to claim 11, further comprising:
removing the first film after the first heat treatment;
performing second heat treatment; and
forming a second film covering at least the oxide, the first insulator, the conductor, and the second insulator.
